(19) United States
(12) Patent Application Publication
(10) Pub. No.: US 2014/0338960 A1
(43) Pub. Date: Nov. 20, 2014

(54) TRANSPARENT CONDUCTIVE ELEMENT, METHOD FOR MANUFACTURING THE SAME, INPUT DEVICE, ELECTRONIC APPARATUS, AND METHOD FOR MACHINING TRANSPARENT CONDUCTIVE LAYER

(71) Applicant: DEXERIALS CORPORATION, Tokyo (JP)

(72) Inventors: Junichi Inoue, Utsunomiya-shi (JP); Mikihisa Mizuno, Sendai-shi (JP)

(21) Appl. No.: 14/372,281

(22) PCT Filed: Jan. 24, 2013
(86) PCT No.: PCT/JP2013/051410

§ 371 Date: Jul. 15, 2014

(30) Foreign Application Priority Data
Jan. 24, 2012 (JP) 2012-012528
Aug. 21, 2012 (JP) 2012-182786

(51) Int. Cl. H05K 3/00; G06F 3/044; G06F 3/041; H05K 1/02; G03F 7/20

(52) U.S. Cl. CPC H05K 3/0082; H05K 1/0274; H05K 1/0298; G03F 7/20; G06F 3/0412; G06F 3/044; G06F 2203/04103; G06F 2203/04112
USPC 174/253; 430/322

(57) ABSTRACT

A large-area transparent conductive element easy to form a fine pattern includes a substrate having a surface, and transparent conductive portions and transparent insulating portions that are alternately provided on the surface in a planar manner. At least one type of unit section including a random pattern is repeated in at least either the transparent conductive portions or the transparent insulating portions.

### TECHNICAL FIELD

The present technique relates to a transparent conductive element, a method for manufacturing the same, an input device, an electronic apparatus, and a method for machining a transparent conductive layer. In particular, the present technique relates to a transparent conductive element in which transparent conductive portions and transparent insulating portions are alternately provided on a substrate surface in a planar manner.

### BACKGROUND ART

More and more mobile devices such as mobile phones and portable music terminals have been incorporating capacitive touch panels in recent years. Capacitive touch panels use a transparent conductive film in which a patterned transparent conductive layer is provided on the surface of a substrate film.

Patent Literature 1 proposes a transparent conductive sheet having the following configuration. The transparent conductive sheet includes a conductive pattern layer that is formed on a base sheet, and an insulating pattern layer that is formed on portions of the base sheet where the conductive pattern layer is not formed. The conductive pattern layer includes a plurality of fine pinholes. The insulating pattern layer is formed like a plurality of islands by means of narrow grooves.

### CITATION LIST

### Patent Literature

Patent Document 1: Japanese Patent Application Laid-Open No. 2010-157400

### SUMMARY OF INVENTION

### Technical Problem

Recently, a large-area transparent conductive layer having a fine pattern like the foregoing has been desired to be produced. To meet such a demand, the fine pattern is also desirably made easy to form over a large area.

It is thus an object of the present technique to provide a large-area transparent conductive element easy to form a fine pattern, a method for manufacturing the same, an input device, an electronic apparatus, and a method for machining a transparent conductive layer.

### Solution to Problem

To solve the foregoing problem, a first technique is a transparent conductive element including:

a substrate having a surface; and

transparent conductive portions and transparent insulating portions that are alternately provided on the surface in a planar manner,

at least one type of unit section including a random pattern being repeated in at least either the transparent conductive portions or the transparent insulating portions.

A second technique is an input device including:

a substrate having a first surface and a second surface; and

transparent conductive portions and transparent insulating portions that are alternately provided in a planar manner on the first surface and the second surface,

at least one type of unit section including a random pattern being repeated in at least either the transparent conductive portions or the transparent insulating portions.

A third technique is an input device including:

a first transparent conductive element; and

a second transparent conductive element that is provided on a surface of the first transparent conductive element,

the first transparent conductive element and the second transparent conductive element including

a substrate having a surface, and

transparent conductive portions and transparent insulating portions that are alternately provided on the surface in a planar manner,

at least one type of unit section including a random pattern being repeated in at least either the transparent conductive portions or the transparent insulating portions.

A fourth technique is an electronic apparatus including a transparent conductive element that includes: a substrate having a first surface and a second surface; and transparent conductive portions and transparent insulating portions that are alternately provided in a planar manner on the first surface and the second surface,

at least one type of unit section including a random pattern being repeated in at least either the transparent conductive portions or the transparent insulating portions.

A fifth technique is an electronic apparatus including:

a first transparent conductive element; and

a second transparent conductive element that is provided on a surface of the first transparent conductive element,

the first transparent conductive element and the second transparent conductive element including

a substrate having a first surface and a second surface, and

transparent conductive portions and transparent insulating portions that are alternately provided in a planar manner on the first surface and the second surface,

at least one type of unit section including a random pattern being repeated in at least either the transparent conductive portions or the transparent insulating portions.

A sixth technique is a method for manufacturing a transparent conductive element, the method including irradiating a transparent conductive layer on a substrate surface with light via at least one type of mask including a random pattern to repeatedly form a unit section, whereby transparent conductive portions and transparent insulating portions are alternately formed on the substrate surface in a planar manner.

A seventh technique is a method for machining a transparent conductive layer, the method including irradiating a transparent conductive layer on a substrate surface with light via at least one type of mask including a pattern to repeatedly form a unit section, whereby transparent conductive portions and transparent insulating portions are alternately formed on the substrate surface in a planar manner.

According to the present technique, at least one type of unit section including a random pattern is repeated in at least either the transparent conductive portions or the transparent insulating portions. The random pattern can thus be easily formed over a large area.

According to the present technique, the transparent conductive portions and the transparent insulating portions are alternately provided on the substrate surface in a planar manner. This can reduce a difference in reflectance between the regions where the transparent conductive portions are provided and the regions where the transparent conductive portions are not provided. Visual recognition of the pattern of the transparent conductive portions can thus be suppressed.

### Advantageous Effects of Invention

As descried above, according to the present technique, a large-area transparent conductive element easy to form a fine pattern can be provided.

### BRIEF DESCRIPTION OF DRAWINGS

FIG. 1 is a cross-sectional view showing a configuration example of an information input device according to a first embodiment of the present technique.

FIG. 2A is a plan view showing a configuration example of a first transparent conductive element according to the first embodiment of the present technique.

FIG. 2B is a cross-sectional view taken along line A-A shown in FIG. 2A.

FIG. 3A is a plan view showing a configuration example of a transparent electrode portion of the first transparent conductive element. FIG. 3B is a plan view showing a configuration example of a transparent insulating portion of the first transparent conductive element.

FIG. 4A is a plan view showing a configuration example of a unit section of the transparent electrode portions of the first transparent conductive element. FIG. 4B is a cross-sectional view taken along line A-A shown in FIG. 4A. FIG. 4C is a plan view showing a configuration example of a unit section of the transparent insulating portions of the first transparent conductive element. FIG. 4D is a cross-sectional view taken along line A-A shown in FIG. 4C.

FIG. 5 is a plan view showing an example of a shape pattern of a boundary portion.

FIG. 6A is a plan view showing a configuration example of a second transparent conductive element according to the first embodiment of the present technique. FIG. 6B is a cross-sectional view taken along line A-A shown in FIG. 6A.

FIG. 7 is a schematic diagram showing a configuration example of a laser machining apparatus for producing the transparent electrode portions and the transparent insulating portions.

FIG. 8A is a plan view showing a configuration example of a first mask for producing transparent electrode portions 13. FIG. 8B is a plan view showing a configuration example of a second mask for producing transparent insulating portions 14.

FIGS. 9A to 9C are process diagrams for describing an example of a method for manufacturing the first transparent conductive element according to the first embodiment of the present technique.

FIG. 10A is a plan view showing a modification of the unit section of the transparent electrode portions. FIG. 10B is a cross-sectional view taken along line A-A shown in FIG. 10A. FIG. 10C is a plan view showing a modification of the unit section of the transparent insulating portions. FIG. 10D is a cross-sectional view taken along line A-A shown in FIG. 10C.

FIGS. 11A to 11D are cross-sectional views showing modifications of the first transparent conductive element according to the first embodiment of the present technique.

FIGS. 12A and 12B are cross-sectional views showing modifications of the first transparent conductive element according to the first embodiment of the present technique.

FIG. 13A is a plan view showing a configuration example of a first transparent conductive element according to a second embodiment of the present technique. FIG. 13B is a plan view showing a configuration example of a third mask for producing a boundary pattern in boundary portions between transparent electrode portions and transparent insulating portions.

FIG. 14A is a plan view showing a configuration example of a transparent electrode portion of a first transparent conductive element according to a third embodiment of the present technique. FIG. 14B is a plan view showing a configuration example of a transparent insulating portion of the first transparent conductive element according to the third embodiment of the present technique.

FIG. 15A is a plan view showing a configuration example of a unit section of the transparent electrode portion. FIG. 15B is a cross-sectional view taken along line A-A shown in FIG. 15A. FIG. 15C is a plan view showing a configuration example of a unit section of the transparent insulating portion. FIG. 15D is a cross-sectional view taken along line A-A shown in FIG. 15C.

FIG. 16 is a plan view showing an example of a shape pattern of a boundary portion.

FIG. 17A is a plan view showing a configuration example of a first transparent conductive element according to a fourth embodiment of the present technique. FIG. 17B is a plan view showing a configuration example of a third mask for producing a boundary pattern in boundary portions between transparent electrode portions and transparent insulating portions.

FIG. 18 is a plan view showing a configuration example of a first transparent conductive element according to a fifth embodiment of the present technique.

FIG. 19A is a plan view showing a configuration example of a first transparent conductive element according to a sixth embodiment of the present technique. FIG. 19B is a plan view showing a configuration example of a third mask for producing a boundary pattern in boundary portions between transparent electrode portions and transparent insulating portions.

FIG. 20A is a plan view showing a configuration example of a first transparent conductive element according to a seventh embodiment of the present technique. FIG. 20B is a plan view showing a modification of the first transparent conductive element according to the seventh embodiment of the present technique.

FIG. 21A is a plan view showing a configuration example of a first transparent conductive element according to an eighth embodiment of the present technique. FIG. 21B is a plan view showing a modification of the first transparent conductive element according to the eighth embodiment of the present technique.

FIG. 22A is a plan view showing a configuration example of a first transparent conductive element according to a ninth embodiment of the present technique. FIG. 22B is a plan view showing a configuration example of a second transparent conductive element according to the ninth embodiment of the present technique.

FIG. 23 is a cross-sectional view showing a configuration example of an information input device according to a tenth embodiment of the present technique.

FIG. 24A is a plan view showing a configuration example of an information input device according to an eleventh embodiment of the present technique. FIG. 24B is a cross-sectional view taken along line A-A shown in FIG. 24A.

FIG. 25A is an enlarged plan view showing a vicinity of the intersection C shown in FIG. 24A. FIG. 25B is a cross-sectional view taken along line A-A shown in FIG. 25A.

FIG. 26 is an appearance diagram showing an example of a television set as an electronic apparatus.

FIGS. 27A and 27B are appearance diagrams showing an example of a digital camera as an electronic apparatus.

FIG. 28 is an appearance diagram showing an example of a notebook personal computer as an electronic apparatus.

FIG. 29 is an appearance diagram showing an example of a video camera as an electronic apparatus.

FIG. 30 is an appearance diagram showing an example of a portable terminal apparatus as an electronic apparatus.

FIG. 31A is a diagram showing the result of observation of the surface of a transparent conductive sheet according to example 1-5 under a microscope. FIG. 31B is a diagram showing the result of observation of the surface of a transparent conductive sheet according to example 2-1 under a microscope.

FIG. 32 is a schematic diagram showing a modification of the laser machining apparatus for producing transparent electrode portions and transparent insulating portions.

FIG. 33 is a diagram showing a machining depth d when a transparent conductive sheet is irradiated with laser light.

FIG. 34A is a diagram showing the result of observation of the surface of a transparent conductive sheet according to example 5-4 under a microscope. FIG. 34B is a diagram showing the result of observation of the surface of a transparent conductive sheet according to example 5-5 under a microscope. FIG. 34C is a diagram showing the result of observation of the surface of a transparent conductive sheet according to example 5-6 under a microscope.

FIG. 35A is a diagram showing the result of observation of the surface of a transparent conductive sheet according to example 5-7 under a microscope. FIG. 35B is a diagram showing the result of observation of the surface of a transparent conductive sheet according to example 5-8 under a microscope.

FIG. 36 is a chart showing the resulting resistance ratios of transparent conductive sheets according to examples 5-1 to 5-3.

FIG. 37 is a chart showing the resulting resistance ratios of the transparent conductive sheets according to examples 5-4 to 5-8.

FIG. 38A is a diagram showing the result of observation of the surface of a transparent conductive sheet according to example 7-1 under a microscope. FIG. 38B is a diagram showing the result of observation of the surface of a transparent conductive sheet according to example 7-2 under a microscope. FIG. 38C is a diagram showing the result of observation of the surface of a transparent conductive sheet according to example 7-3 under a microscope.

FIG. 39 is a chart showing the resulting resistance ratios of the transparent conductive sheets according to examples 7-1 to 7-3.

FIG. 40A is a diagram showing the result of observation of the surface of a transparent conductive sheet according to example 8-1 under a microscope. FIG. 40B is a diagram showing the result of observation of the surface of a transparent conductive sheet according to example 8-2 under a microscope.

FIG. 41A is a diagram showing the result of observation of the surface of a transparent conductive sheet according to example 8-3 under a microscope. FIG. 41B is a diagram showing the result of observation of the surface of a transparent conductive sheet according to example 8-4 under a microscope.

FIG. 42 is a chart showing the resulting resistance ratios of the transparent conductive sheets according to examples 8-1 to 8-4.

FIG. 43 is a chart showing the resulting sheet resistances of transparent conductive sheets according to comparative examples 8-1 to 8-4 and the transparent conductive sheets according to examples 8-1 to 8-4.

FIG. 44 is a chart showing the resulting resistance ratios of the transparent conductive sheets according to comparative examples 8-1 to 8-4 and the transparent conductive sheets according to examples 8-1 to 8-4.

FIG. 45A is a diagram showing variations of the moving speed of a typical stage. FIG. 45B is a diagram showing variations of the moving speed of high-speed stages.

### DESCRIPTION OF EMBODIMENTS

Referring to the drawings, embodiments of the present technique will be described in the following order.

1. First Embodiment (an example where transparent electrode portions and transparent insulating portions are constituted by unit sections including random patterns)
2. Second Embodiment (an example where boundary portions are constituted by unit sections including a random boundary pattern)
3. Third Embodiment (an example where transparent electrode portions and transparent insulating portions are constituted by unit sections including regular patterns)
4. Fourth Embodiment (an example where boundary portions are constituted by unit sections including a regular boundary pattern)
5. Fifth Embodiment (an example where transparent electrode portions are formed as a continuous film)
6. Sixth Embodiment (an example where boundary portions are constituted by unit sections including a random pattern)
7. Seventh Embodiment (an example where transparent electrode portions are constituted by unit sections including a random pattern and transparent insulating portions are constituted by unit sections including a regular pattern)
8. Eighth Embodiment (an example where transparent electrode portions are constituted by unit sections including a regular pattern and transparent insulating portions are constituted by unit sections including a random pattern)
9. Ninth Embodiment (an example where transparent electrode portions having the shape of connected pad portions are provided)
10. Tenth Embodiment (an example where transparent electrode portions are provided on both sides of a substrate)
11. Eleventh Embodiment (an example where transparent electrode portions are provided to intersect on one principal surface of a substrate)
12. Twelfth Embodiment (examples of application to electronic apparatuses)

### 1. First Embodiment

### [Configuration of Information Input Device]

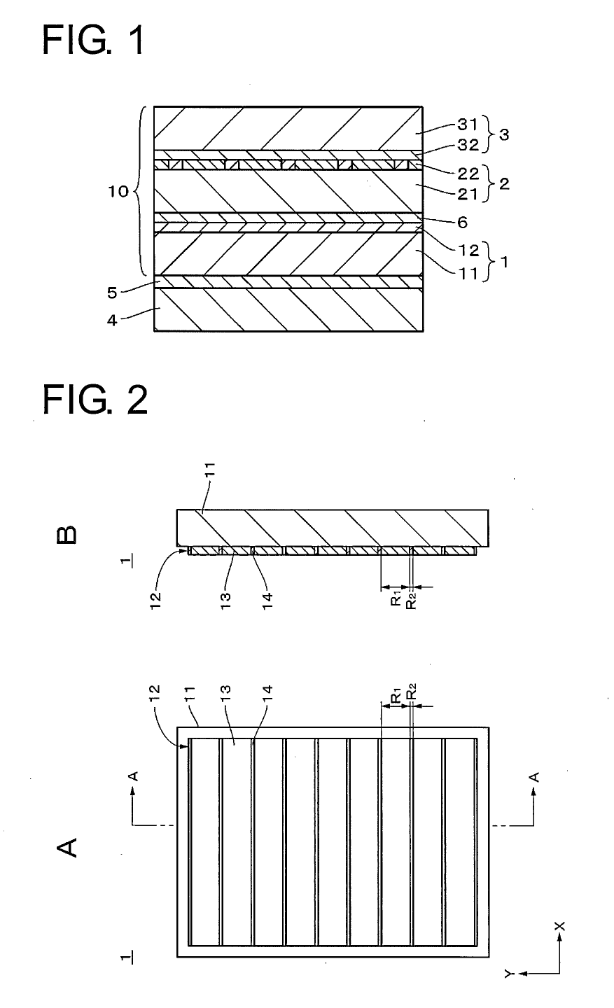

FIG. 1 is a cross-sectional view showing a configuration example of an information input device according to a first embodiment of the present technique. As shown in FIG. 1, the information input device 10 is provided on a display surface of a display device 4. For example, the information input device 10 is bonded to the display surface of the display device 4 by a bonding layer 5.

### (Display Device)

The display device 4 to which the information input device 10 is applied is not limited in particular. Examples thereof may include various types of display devices such as a liquid crystal display, a CRT (Cathode Ray Tube) display, a plasma display (Plasma Display Panel: PDP), an electroluminescence (Electro Luminescence: EL) display, and a surface-conduction electron-emitter display (Surface-conduction Electron-emitter Display: SED).

### (Information Input Device)

The information input device 10 is a so-called projection type capacitive touch panel, and includes a first transparent conductive element 1 and a second transparent conductive element 2 provided on the surface of the first transparent conductive element 1. The first transparent conductive element 1 and the second transparent conductive element 2 are bonded via a bonding layer 6. An optical layer 3 may be further provided on the surface of the second transparent conductive element 2 if needed.

### (Optical Layer)

For example, the optical layer 3 includes a substrate 31 and a bonding layer 32 provided between the substrate 31 and the second transparent conductive element 2. The substrate 31 is bonded to the surface of the second transparent conductive element 2 via the bonding layer 32. The optical layer 3 is not limited to such an example, and may be a ceramic coating (overcoat) of SiO₂ or the like.

### (First Transparent Conductive Element)

FIG. 2A is a plan view showing a configuration example of the first transparent conductive element according to the first embodiment of the present technique. FIG. 2B is a cross-sectional view taken along line A-A shown in FIG. 2A. As shown in FIGS. 2A and 2B, the first transparent conductive element 1 includes a substrate 11 having a surface and a transparent conductive layer 12 provided on the surface. As employed herein, two directions intersecting orthogonally within the plane of the substrate 11 are defined as an X-axis direction (first direction) and a Y-axis direction (second direction).

The transparent conductive layer 12 includes transparent electrode portions (transparent conductive portions) 13 and transparent insulating portions 14. The transparent electrode portions 13 are X electrode portions extended in the X-axis direction. The transparent insulating portions 14 are so-called dummy electrode portions. The transparent insulating portions 14 are insulating portions that are extended in the X-axis direction and interposed between the transparent electrode portions 13 to insulate the adjacent transparent electrode portions 13 from each other. Such transparent electrode portions 13 and transparent insulating portions 14 are alternately and adjacently provided on the surface of the substrate 11 in a planar manner in the Y-axis direction.

In FIGS. 2A and 2B, a first region R₁ represents a region where a transparent electrode portion 13 is formed. A second region R₂ represents a region where a transparent insulating portion 14 is formed.

### (Transparent Electrode Portions and Transparent Insulating Portions)

The shapes of the transparent electrode portions 13 and the transparent insulating portions 14 are preferably selected as appropriate according to a screen shape, a drive circuit, and the like. Examples thereof may include, but are not limited to, a straight shape and a shape obtained by linearly connecting a plurality of rhombic shapes (diamond shapes). FIGS. 2A and 2B show an example of a configuration where the transparent electrode portions 13 and the transparent insulating portions 14 have straight shapes.

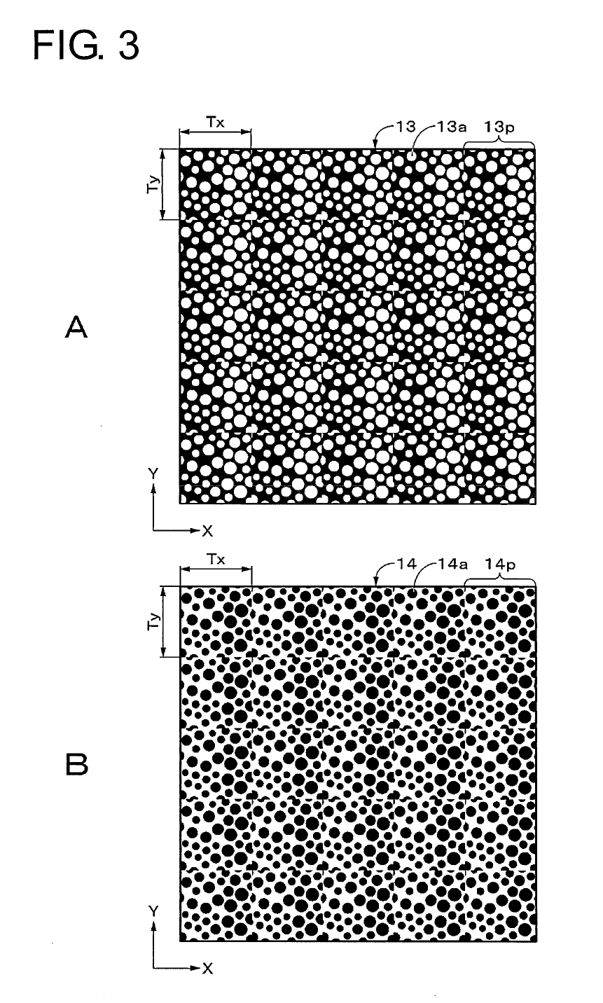

FIG. 3A is a plan view showing a configuration example of a transparent electrode portion of the first transparent conductive element. As shown in FIG. 3A, a transparent electrode portion 13 is a transparent conductive layer 12 in which a unit section 13p including a random pattern of hole portions 13a is repeatedly provided. For example, the unit section 13p is repeatedly provided at periods Tx in the X-axis direction and repeatedly provided at periods Ty in the Y-axis direction. In other words, the unit sections 13p are two-dimensionally arranged in the X-axis direction and the Y-axis direction. For example, the periods Tx and the periods Ty are set independently of each other, for example, within the range of micrometer order to nanometer order.

FIG. 3B is a plan view showing a configuration example of a transparent insulating portion of the first transparent conductive element. As shown in FIG. 3B, a transparent insulating portion 14 is a transparent conductive layer 12 in which a unit section 14p including a random pattern of island portions 14a is repeatedly provided. For example, the unit section 14p is repeatedly provided at periods Tx in the X-axis direction and repeatedly provided at periods Ty in the Y-axis direction. In other words, the unit sections 14p are two-dimensionally arranged in the X-axis direction and the Y-axis direction. The periods Tx and the periods Ty are set independently of each other, for example, within the range of micrometer order to nanometer order.

FIGS. 3A and 3B show an example where the unit sections 13p and the unit sections 14p are of one type each. However, two or more types of unit sections 13p and unit sections 14p may be used. In such a case, unit sections 13p and unit sections 14p of the same types may be periodically or randomly repeated in the X-axis direction and the Y-axis direction.

The shapes of the unit sections 13p and the unit sections 14p are not limited in particular as long as the shapes can be repeatedly provided in the X-axis direction and the Y-axis direction with little space therebetween. Examples thereof may include polygonal shapes such as triangular, rectangular, hexagonal, and octagonal shapes, and irregular shapes.

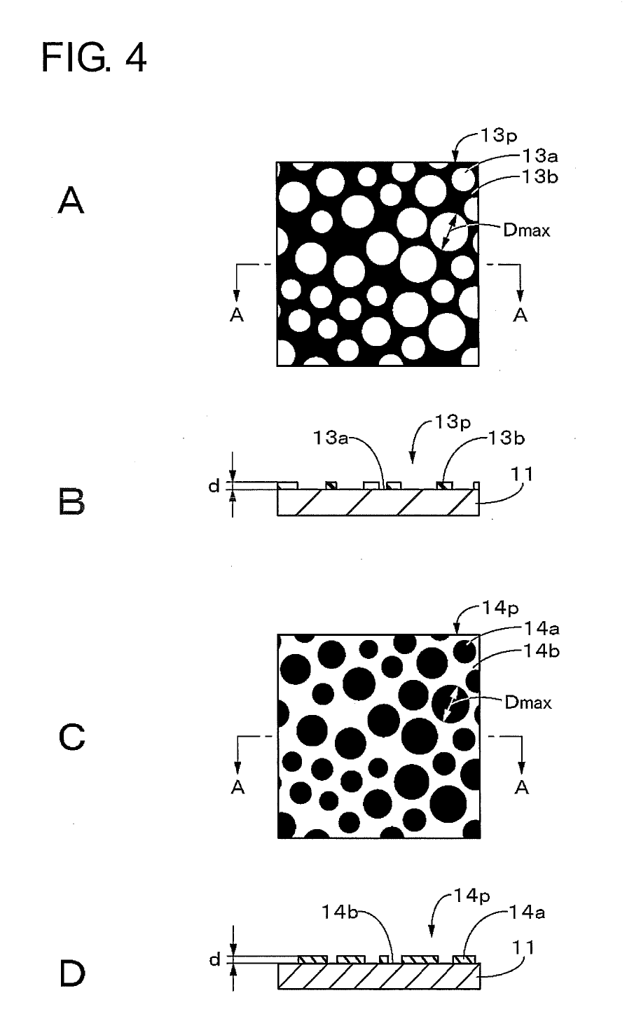

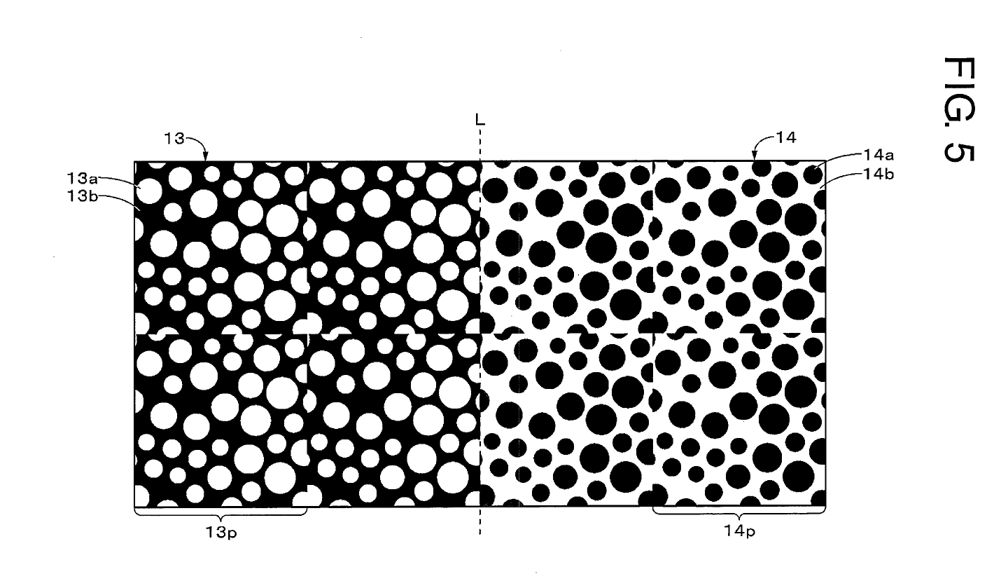

FIG. 4A is a plan view showing a configuration example of the unit section of the transparent electrode portions of the first transparent conductive element. FIG. 4B is a cross-sectional view taken along line A-A shown in FIG. 4A. FIG. 4C is a plan view showing a configuration example of the unit section of the transparent insulating portions of the first transparent conductive element. FIG. 4D is a cross-sectional view taken along line A-A shown in FIG. 4C. As shown in FIGS. 4A and 4B, the unit section 13p of the transparent electrode portions 13 is a transparent conductive layer 12 including a plurality of hole portions (insulating elements) 13a which are provided apart from each other in a random pattern. A transparent conductive portion 13b is interposed between adjacent hole portions 13a. As shown in FIGS. 4C and 4D, the unit section 14p of the transparent insulating portions 14 is a transparent conductive layer 12 including a plurality of island portions (conductive elements) 14a which are provided apart from each other in a random pattern. A gap portion 14b serving as an insulating portion is interposed between adjacent island portions 14a. For example, the island portions 14a are an island-like transparent conductive layer 12 mainly made of a transparent conductive material. Here, the transparent conductive layer 12 is preferably completely removed from the gap portion 14b. As long as the gap portion 14b functions as an insulating portion, part of the transparent conductive layer 12 may be left in an island-like or thin film form.

The unit section 13p preferably has a side which a hole portion or portions 13a serving as pattern elements of the random pattern is/are in contact with or cut by. All the sides constituting the unit section 13p preferably have such a relationship with the pattern elements. Note that a configuration in which the hole portions 13a serving as the pattern elements of the random pattern are separated from all the sides may also be employed.

The unit section 14p preferably has a side which an island portion or portions 14a serving as pattern elements of the random pattern is/are in contact with or cut by. All the sides constituting the unit section 14p preferably have such a relationship with the pattern elements. Note that a configuration in which the island portions 14a serving as the pattern elements of the random pattern are separated from all the sides may also be employed.

For example, the hole portion 13a and the island portions 14a may have dot shapes. For example, one or more types of shapes selected from the group consisting of a circular shape, an elliptical shape, a shape obtained by cutting off part of a circular shape, a shape obtained by cutting off part of an elliptical shape, a polygonal shape, a chamfered polygonal shape, and an irregular shape may be used as the dot shapes. Examples of the polygonal shape may include, but are not limited to, triangular, rectangular (such as rhombic), hexagonal, and octagonal shapes. The hole portions 13a and the island portions 14a may use different shapes. As employed herein, circular shapes include not only mathematically-defined perfect circles but somewhat distorted, near circular shapes as well. Elliptical shapes include not only mathematically-defined perfect ellipses but somewhat distorted, near elliptical shapes (such as ovals and egg-like shapes) as well. Polygonal shapes include not only mathematically-defined perfect polygonal shapes but also near polygonal shapes with distorted sides, near polygonal shapes with rounded corners, and near polygonal shapes with distorted sides and rounded corners. Examples of the distortion of a side may include convex and concave curves.

The hole portions 13a and the island portions 14a preferably have a visually recognizable size. Specifically, the hole portions 13a and the island portions 14a preferably have a size of 100 μm or less, preferably 60 μm or less. If a hole portion 13a or an island portion 14a is not circular in shape, the size (diameter Dmax) refers to the maximum length across the portion. If circular, the diameter Dmax coincides with the diameter. If the hole portions 13a and the island portions 14a have a diameter Dmax of 100 μm or less, the visual recognition of the hole portions 13a and the island portions 14a can be suppressed. Specifically, for example, if the hole portions 13a and the island portions 14a have a circular shape, their diameters are preferably 100 μm or less. In FIG. 4, the reference symbol d denotes the distance of the depth of the hole portions as a random pattern between the top (topmost surface) and the bottom (the bottoms of the laser-machined portions (the surface of the substrate 11 ablated by laser light irradiation. Hereinafter, if ablation occurs even inside the substrate 11, the exposed surface is referred to as the surface of the substrate 11)) of the transparent conductive sheet. More specifically, FIG. 4 shows an average depth d from the surface of the transparent conductive portion 13b to the bottoms of the hole portions 13a (the surface of the substrate 11) and an average depth d from the surfaces of the island portions 14a to the bottom of the gap portion 14b (the surface of the substrate 11).

In the first regions R₁, for example, a plurality of hole portions 13a constitute an exposed area of the substrate surface. The transparent conductive portion 13b interposed between adjacent hole portions 13a constitutes a covered area of the substrate surface. On the other hand, in the second regions R₂, a plurality of island portions 14a constitute the covered area of the substrate surface. The gap portion 14b interposed between adjacent island portions 14a constitutes the exposed area of the substrate surface. It is preferable that the first regions R₁ and the second regions R₂ have a difference of 60% or less in the coverage ratio, preferably 40% or less, more preferably 30% or less, and the hole portions 13a and the island portions 14a be formed in a visually unrecognizable size. When the transparent electrode portions 13 and the transparent insulating portions 14 are compared by visual observation, the transparent conductive layer 12 looks as if the first regions R₁ and the second regions R₂ are similarly covered. This can suppress the visual recognition of the transparent electrode portions 13 and the transparent insulating portion 14.

In the first regions R₁, the ratio of the area covered by the transparent conductive portions 13b is preferably high. The reason is that the lower the coverage ratio, the thicker the initial deposition on the entire surface needs to be to increase the thickness of the transparent conductive portions 13b if the same conductivity is intended. The cost increases in inverse proportion to the coverage ratio. For example, if the coverage ratio is 50%, the material cost becomes twice. If the coverage ratio is 10%, the material cost becomes ten times. The large thickness of the transparent conductive portions 13b can cause other problems such as deterioration of optical characteristics. Too low a coverage ratio increases the possibility of insulation. In view of the foregoing, the coverage ratio is preferably at least 10% or higher. The upper limit value of the coverage ratio is not limited in particular.

In the second regions R₂, if the coverage ratio of the island portions 14a is too high, the generation of the random pattern itself becomes difficult. The island portions 14a can also approach each other to cause a short circuit. The coverage ratio of the island portions 14a is therefore preferably lower than or equal to 95%.

A difference between the reflection L values of the transparent electrode portions 13 and the transparent insulating portions 14 is preferably less than 0.3 in absolute value. The reason is that the visual recognition of the transparent electrode portions 13 and the transparent insulating portions 14 can be suppressed. As employed herein, the absolute value of the difference in the reflection L value refers to a value evaluated according to JIS 28722.

An average boundary line length La of the transparent electrode portions 13 provided in the first regions (electrode regions) R₁ and an average boundary line length Lb of the transparent insulating portions 14 provided in the second regions (insulating regions) R₂ preferably fall within a range of 0<La, Lb≦20 mm/mm². The average boundary line length La refers to the length of an average boundary line among the boundary lines between the hole portions 13a and the transparent conductive portion 13b provided in the transparent electrode portions 13. The average boundary line length Lb refers to the length of an average boundary line among the boundary lines between the island portions 14a and the gap portion 14b provided in the transparent insulating portions 14.

Adjusting the average boundary line lengths La and Lb within the foregoing range can reduce boundaries between the areas where the transparent conductive layer 12 is formed on the surface of the substrate 11 and the areas where the transparent conductive layer 12 is not formed, whereby the amount of light scattered at the boundaries can be reduced. The absolute value of the difference in the foregoing reflection L value can thus be set to below 0.3 regardless of the ratio of the average boundary line lengths (La/Lb) to be described later. In other words, the visual recognition of the transparent electrode portions 13 and the transparent insulating portions 14 can be suppressed.

Now, a method for determining the average boundary line length La of the transparent electrode portions 13 and the average boundary line length Lb of the transparent insulating portions 14 will be described.

The average boundary line length La of the transparent electrode portions 13 is determined in the following manner. Initially, the transparent electrode portions 13 is observed under a digital microscope (manufactured by Keyence Corporation, trade name: VHX-900) with an observation magnification in the range of 100 to 500 times, and the observation image is stored. Next, a boundary line (ΣCᵢ=C₁+ . . . +Cₙ) is measured from the stored observation image by using image analysis to obtain a boundary line length L₁ [mm/mm²]. Such a measurement in ten fields of view chosen from the transparent electrode portions 13 at random is performed to obtain boundary line lengths L₁, . . . , L₁₀. Next, an average (arithmetic mean) of the obtained boundary line lengths L₁, . . . , L₁₀ is simply calculated to determine the average boundary line length La of the transparent electrode portions 13.

The average boundary line length Lb of the transparent insulating portions 14 is determined in the following manner. Initially, the transparent insulating portions 14 are observed under the digital microscope (manufactured by Keyence Corporation, trade name: VHX-900) with an observation magnification in the range of 100 to 500 times, and the observation image is stored. Next, a boundary line (ΣCᵢ=C₁+ . . . +Cₙ) is measured from the stored observation image by using image analysis to obtain a boundary line length L₁ [mm/mm²]. Such a measurement in ten fields of view chosen from the transparent insulating portions 14 at random is performed to obtain boundary line lengths L₁, . . . , L₁₀. Next, an average (arithmetic mean) of the obtained boundary line lengths L₁, . . . , L₁₀ is simply calculated to determine the average boundary line length Lb of the transparent insulating portions 14.

An average boundary line length ratio (La/Lb) between the average boundary line length La of the transparent electrode portions 13 provided in the first regions (electrode regions) R₁ and the average boundary line length Lb of the transparent insulating portions 14 provided in the second regions (insulating regions) R₂ preferably falls within the range of 0.75 or more and 1.25 or less. Suppose that the average boundary line length ratio (La/Lb) falls outside the foregoing range and the average boundary line length La of the transparent electrode portions 13 and the average boundary line length Lb of the transparent insulating portions 14 are not set to 20 mm/mm² or less. In such a case, the transparent electrode portions 13 and the transparent insulating portions 14 can be visually recognized even if the transparent electrode portions 13 and the transparent insulating portions 14 have similar coverage ratios. The reason is that, for example, the refractive index at the surface of the substrate 11 is different between the areas where the transparent conductive layer 12 is present and the areas where the transparent conductive layer 12 is not present. If the areas where the transparent conductive layer 12 is present and the areas where the transparent conductive layer 12 is not present have a large difference in the refractive index, light scattering occurs at the boundaries between the areas where the transparent conductive layer 12 is present and the areas where the transparent conductive layer 12 is not present. As a result, the regions of the transparent electrode portions 13 or the transparent insulating portions 14 that have greater boundary lengths look whiter. The electrode pattern of the transparent electrode portions 13 are visually recognized regardless of the difference in the coverage ratio. Quantitatively, the difference between the reflection L values of the transparent electrode portions 13 and the transparent insulating portions 14 becomes greater than or equal to 0.3 in absolute value.

### (Boundary Portions)

FIG. 5 is a plan view showing an example of a shape pattern of a boundary portion. A random shape pattern is provided in the boundary portions between the transparent electrode portions 13 and the transparent insulating portions 14. The provision of a random shape pattern in the boundary portions can suppress the visual recognition of the boundary portions. As employed herein, a boundary portion refers to a region between a transparent electrode portion 13 and a transparent insulating portion 14. A boundary L refers to a boundary line that divides the transparent electrode portion 13 and the transparent insulating portion 14. Depending on the shape pattern of the boundary portions, the boundary L may be a virtual line instead of a solid line.

The shape pattern of the boundary portion preferably includes the entire and/or part of the pattern elements of at least either one of the random patterns of the transparent electrode portion 13 and the transparent insulating portion 14. More specifically, the shape pattern of the boundary portion preferably includes one or more types of shapes selected from the group consisting of the entire hole portions 13a, part of the hole portions 13a, the entire island portions 14a, and part of the island portions 14a.

For example, the entire hole portions 13a included in the shape pattern of the boundary portion are provided in contact with or almost in contact with the boundary L on the side of the transparent electrode portion 13. For example, the entire island portions 14a included in the shape pattern of the boundary portion are provided in contact with or almost in contact with the boundary L on the side of the transparent insulating portion 14.

For example, part of the hole portions 13a included in the shape pattern of the boundary portion have the shape of the hole portions 13a partly cut by the boundary L, and are provided with the cut sides in contact with or almost in contact with the boundary L on the side of the transparent electrode portion 13. For example, part of the island portions 14a included in the shape pattern of the boundary portion have the shape of the island portions 14a partly cut by the boundary L, and are provided with the cut sides in contact with or almost in contact with the boundary L on the side of the transparent insulating portion 14.

The unit section 13p preferably includes a side which a hole portion or portions 13a serving as pattern elements of the random pattern is/are in contact with or cut by. The unit section 13p is preferably provided with the side in contact with or almost in contact with the boundary L between the transparent electrode portion 13 and the transparent insulating portion 14.

The unit section 14p preferably includes a side which an island portion or portions 14a serving as pattern elements of the random pattern is/are in contact with or cut by. The unit section 14p is preferably provided with the side in contact with or almost in contact with the boundary L between the transparent electrode portion 13 and the transparent insulating portion 14.

Note that FIG. 5 shows an example where the shape pattern of the boundary portion includes part of the pattern elements of the random patterns of both the transparent electrode portion 13 and the transparent insulating portion 14. More specifically, FIG. 5 shows an example where the shape pattern of the boundary portion includes part of both the hole portions 13a and the island portions 14a. In such an example, part of the hole portions 13a included in the boundary portion have the shape of the hole portions 13a partly cut by the boundary L, and are provided with the cut sides in contact with the boundary L on the side of the transparent electrode portion 13. Meanwhile, part of the island portions 14a included in the boundary portion have the shape of the island portions 14a partly cut by the boundary L, and are provided with the cut sides in contact with the boundary L on the side of the transparent insulating portion 14.

### (Substrate)

The substrate 11 may be made of a material such as a glass and a plastic. For example, publicly-known glasses may be used as the glass. Specific examples of the publicly-known glasses may include a soda lime glass, a lead glass, a hard glass, a quartz glass, and a crystallized glass. For example, publicly-known macromolecular materials may be used as the plastic. Specific examples of the publicly-known macromolecular materials may include triacetylcellulose (TAC), polyester, polyethylene terephthalate (PET), polyethylene naphthalate (PEN), polyimide (PI), polyamide (PA), aramid, polyethylene (PE), polyacrylate, polyethersulfone, polysulfone, polypropylene (PP), diacetylcellulose, polyvinyl chloride, acrylic resin (PMMA), polycarbonate (PC), epoxy resins, urea resins, urethane resins, melamine resins, cyclic olefin polymers (COP), and norbornene-based thermoplastic resins.

The glass substrate preferably has a thickness of 20 μm to 10 mm, but is not particularly limited to such a range. The plastic substrate preferably has a thickness of 20 μm to 500 μm, but is not particularly limited to such a range.

### (Transparent Conductive Layer)

For example, one or more types of materials selected from the group consisting of electrically-conductive metal oxide materials, metal materials, carbon materials, and conductive polymers may be used as the material of the transparent conductive layer 12. Examples of the metal oxide materials may include indium tin oxide (ITO), zinc oxide, indium oxide, antimony-doped tin oxide, fluorine-doped tin oxide, aluminum-doped zinc oxide, gallium-doped zinc oxide, silicon-doped lead oxide, zinc oxide-tin oxide series, indium oxide-tin oxide series, and zinc oxide-indium oxide-magnesium oxide series. Examples of the metal materials may include metal nanoparticles and metal wires. Examples of specific materials thereof may include metals such as copper, silver, gold, platinum, palladium, nickel, tin, cobalt, rhodium, iridium, iron, ruthenium, osmium, manganese, molybdenum, tungsten, niobium, tantalum, titanium, bismuth, antimony, and lead, and alloys thereof. Examples of the carbon materials may include carbon black, carbon fibers, fullerene, graphene, carbon nanotubes, carbon microcoils, and nanohorns. Examples of the conductive polymers may include substituted or non-substituted polyaniline, polypyrrole, polythiophene, and (co)polymers made of one or two types selected from these.

The transparent conductive layer 12 may be formed, for example, by using a PVD method such as sputtering, vacuum deposition, and ion plating, a CVD method, an application method, a printing method, or the like. The thickness of the transparent conductive layer 12 is preferably selected as appropriate so that the surface resistance in a pre-patterning state (in a state where the transparent conductive layer 12 is formed on the entire surface of the substrate 11) is 1000Ω/□ or less.

### (Second Transparent Conductive Element)

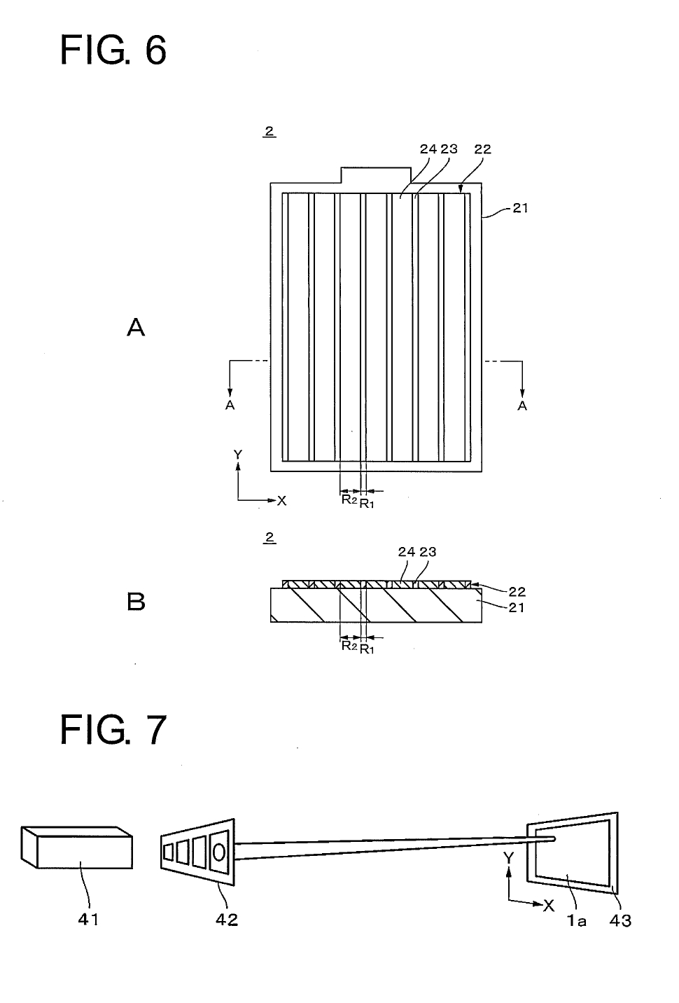

FIG. 6A is a plan view showing a configuration example of the second transparent conductive element according to the first embodiment of the present technique. FIG. 6B is a cross-sectional view taken along line A-A shown in FIG. 6A. As shown in FIGS. 6A and 6B, the second transparent conductive element 2 includes a substrate 21 having a surface and a transparent conductive layer 22 provided on the surface. As employed herein, two directions intersecting orthogonally within the plane of the substrate 21 are defined as an X-axis direction (first direction) and a Y-axis direction (second direction).

The transparent conductive layer 22 includes transparent electrode portions (transparent conductive portions) 23 and transparent insulating portions 24. The transparent electrode portions 23 are Y electrode portions extended in the Y-axis direction. The transparent insulating portions 24 are so-called dummy electrode portions. The transparent insulating portions 24 are insulating portions which are extended in the Y-axis direction and interposed between the transparent electrode portions 23 to insulate adjacent transparent electrode portions 23 from each other. Such transparent electrode portions 23 and transparent insulating portions 24 are alternately and adjacently provided on the surface of the substrate 21 in the X-axis direction. The transparent electrode portions 13 and the transparent insulating portions 14 included in the first transparent conductive element 1 and the transparent electrode portions 23 and the transparent insulating portions 24 included in the second transparent conductive element 2 have a mutually orthogonal relationship, for example. In FIGS. 6A and 6B, a first region R₁ represents a region where a transparent electrode portion 23 is formed. A second region R₂ represents a region where a transparent insulating portion 24 is formed.

In other respects than the foregoing, the second transparent conductive element 2 is the same as the first transparent conductive element 1.

### [Laser Machining Apparatus]

Next, a configuration example of a laser machining apparatus for producing the transparent electrode portions 13 and the transparent insulating portions 14 will be described with reference to FIG. 7. The laser machining apparatus is a machining apparatus for patterning a transparent conductive layer by using a laser ablation process. As shown in FIG. 7, the laser machining apparatus includes a laser 41, a mask unit 42, and a stage 43. The mask unit 42 is provided between the laser 41 and the stage 43. Laser light emitted from the laser 41 reaches a transparent conductive substrate 1a fixed to the stage 43 via the mask unit 42.

The laser machining apparatus is configured so that the machining magnification can be adjusted. For example, the machining magnification can be adjusted to a machining magnification of 1/4 or a machining magnification of 1/8. Examples of the relationship between the laser light irradiation range of the mask unit 42 and the machining range of the transparent conductive substrate la fixed to the stage at the machining magnification of 1/4 and the machining magnification of 1/8 are described below.

Machining magnification of 1/4: laser light irradiation range of 8 mm×8 mm, machining range of 2 mm×2 mm

Machining magnification of 1/8: laser light irradiation range of 8 mm×8 mm, machining range of 1 mm×1 mm

The laser 41 is not limited in particular as long as the laser 41 can pattern a transparent conductive layer, for example, by using a laser ablation process. Examples thereof may include UV lasers such as a KrF excimer laser having a wavelength of 248 nm, a third harmonic femtosecond laser having a wavelength of 266 nm, and a third harmonic YAG laser having a wavelength of 355 nm.

The mask unit 42 includes a first mask for producing the transparent electrode portions 13 and a second mask for producing the transparent insulating portions 14. The mask unit 42 has a configuration such that the first mask and the second mask can be switched by a control apparatus (not shown) or the like. The laser machining apparatus can thus form the transparent electrode portions 13 and the transparent insulating portions 14 repeatedly in a continuous manner.

If there are two or more types of unit sections 13p serving as the unit sections 13p of the transparent electrode portions 13, the mask unit 42 includes two or more types of first masks. Similarly, if there are two or more types of unit sections 14p serving as the unit sections 14p of the transparent insulating portions 14, the mask unit 42 includes two or more types of second masks.

The stage 43 has a fixing surface for fixing the transparent conductive substrate 1a which is the workpiece to be machined. The transparent conductive substrate 1a includes a substrate 11 and a transparent conductive layer 12, and is fixed to the stage 43 so that the surface on the side of the substrate 11 is opposed to the fixing surface.

The orientation of the stage 43 is adjusted so that the laser light emitted from the laser 41 is perpendicularly incident on the fixing surface of the stage 43 via the mask unit 42. The stage 43 has a configuration capable of moving in an X-axis direction (horizontal direction) and a Y-axis direction (vertical direction) while maintaining the incident angle of the laser light constant.

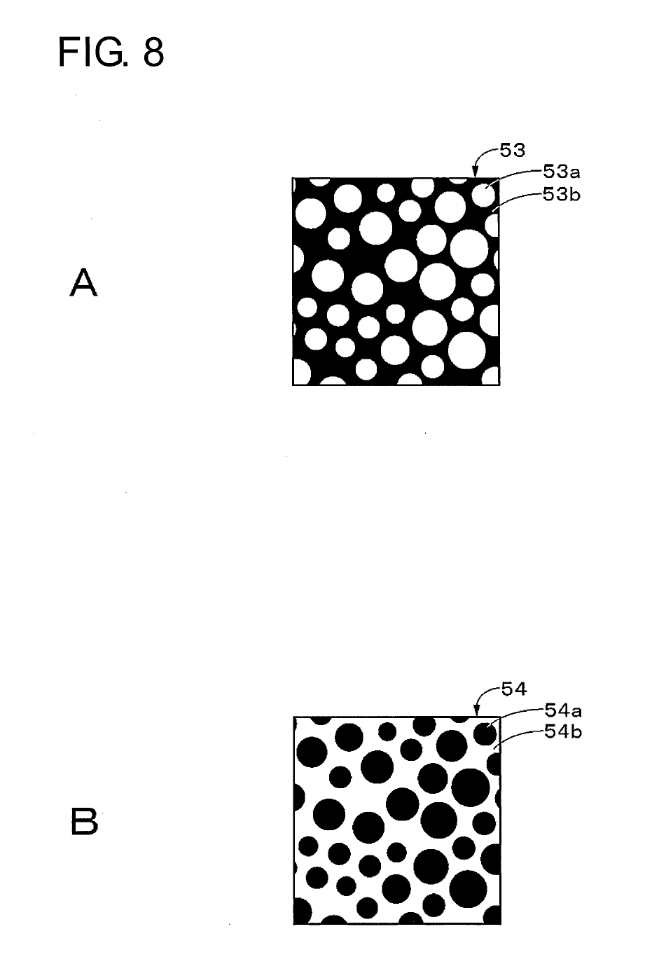

FIG. 8A is a plan view showing a configuration example of the first mask for producing the transparent electrode portions 13. As shown in FIG. 8A, the first mask 53 is a glass mask such that a plurality of hole portions (light transmitting elements) 53a are provided apart from each other in a random pattern in a light-shielding layer on the surface of the glass or inside the glass. A light-shielding portion 53b is interposed between adjacent hole portions 53a.

FIG. 8B is a plan view showing a configuration example of the second mask for producing the transparent insulating portions 14. As shown in FIG. 8B, the second mask 54 is a glass mask such that a plurality of light-shielding portions (light-shielding elements) 54a are provided apart from each other in a random pattern on the surface of the glass or inside the glass. A gap portion (light transmitting portion) 54b that can transmit laser light lies between adjacent light-shielding portions 54a.

The material of the light-shielding portion 53b and the light-shielding portions 54a is not limited in particular as long as the laser light emitted from the laser 41 can be shielded. Examples thereof may include chromium (Cr).

The first mask 53 preferably has a side which a hole portion or portions 53a serving as pattern elements of the random pattern is/are in contact with or cut by. All the sides constituting the first mask 53 preferably have such a relationship with the pattern elements. Note that a configuration in which the hole portions 53a serving as the pattern elements of the random pattern are separated from all the sides may be employed.

The second mask 54 preferably has a side which a light-shielding portion or portions 54a serving as pattern elements of the random pattern is/are in contact with or cut by. All the sides constituting the second mask 54 preferably have such a relationship with the pattern elements. Note that a configuration in which the light-shielding portions 54a serving as the pattern elements of the random pattern are separated from all the sides may be employed. The shapes and sizes of the hole portions 53a and the light-shielding portions 54a are selected as appropriate according to the shapes and sizes of the foregoing hole portions 13a and island portions 14a, respectively.

### [Method for Manufacturing Transparent Conductive Elements]

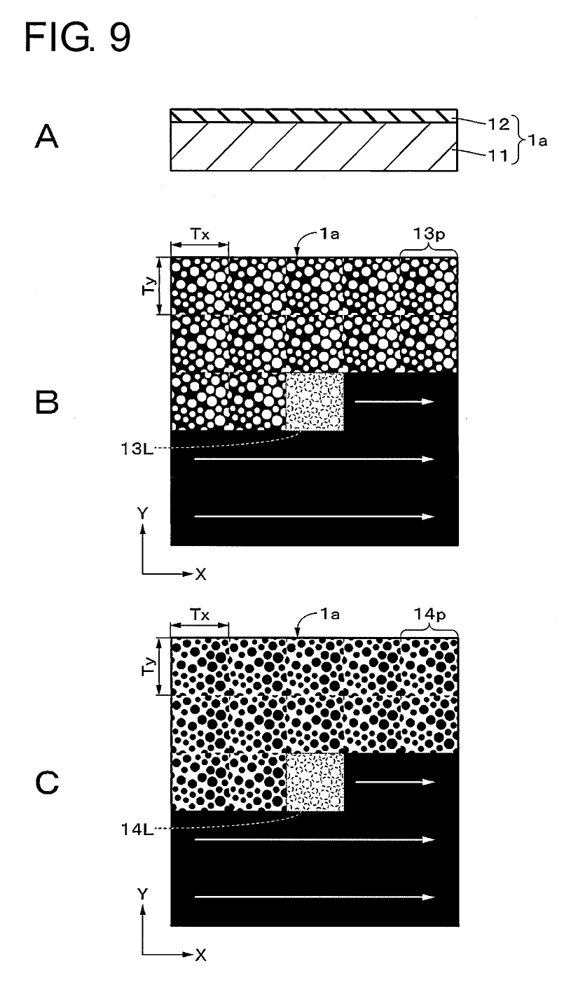

Next, an example of a method for manufacturing the first transparent conductive element 1 having the foregoing configuration will be described with reference to FIGS. 9A to 9C. Since the second transparent conductive element 2 can be manufactured in almost the same manner as that for the first transparent conductive element 1, a description of a method for manufacturing the second transparent conductive element 2 will be omitted.

### (Step of Depositing Transparent Conductive Layer)

As shown in FIG. 9A, a transparent conductive layer 12 is initially deposited on the surface of a substrate 11 to produce a transparent conductive substrate 1a. Both dry and wet deposition methods may be used as a method for depositing the transparent conductive layer 12.

Examples of the dry deposition method may include

CVD methods (Chemical Vapor Deposition: a technique for precipitating a thin film from a vapor phase by using a chemical reaction) such as thermal CVD, plasma CVD, optical CVD, and ALD (Atomic Layer Deposition), as well as PVD methods (Physical Vapor Deposition: a technique for forming a thin film by aggregating a material physically vaporized in a vacuum onto a substrate) such as vacuum deposition, plasma-enhanced deposition, sputtering, and ion plating.

When a dry deposition method is used, firing processing (annealing processing) may be applied to the transparent conductive layer 12, if needed, after the deposition of the transparent conductive layer 12. This brings the transparent conductive layer 12, for example, into an amorphous-and-polycrystalline mixed state or a polycrystalline state, whereby the conductivity of the transparent conductive layer 12 is improved.

Examples of the wet deposition method may include methods for applying or printing a transparent conductive coating material onto the surface of the substrate 11 to form a coating film on the surface of the substrate 11, followed by drying and/or firing. Examples of the application method may include, but are not limited to, a micro gravure coating method, a wire bar coating method, a direct gravure coating method, a die coating method, a dipping method, a spray coating method, a reverse roll coating method, a curtain coating method, a comma coating method, a knife coating method, and a spin coating method. Examples of the printing method may include, but are not limited to, a letterpress printing method, an offset printing method, a gravure printing method, a plate printing method, a rubber plate printing method, and a screen printing method. Commercially available substrates may be used as the transparent conductive substrate 1a.

### (Step of Forming Transparent Electrode Portions and Transparent Insulating Portions)

Next, a first laser machining step and a second laser machining step are alternately repeated by using the foregoing laser machining apparatus, whereby the transparent conductive layer 12 of the transparent conductive substrate 1a is patterned. Here, dust produced by the laser machining may be removed by suction processing or the like. Next, air blowing processing, rinse cleaning processing, and/or the like is/are applied to the transparent conductive substrate 1a if needed. As a result, the transparent electrode portions 13 and the transparent insulating portions 14 are alternately and adjacently formed in a planar manner in one direction. The first laser machining step is a step performed by irradiating the transparent conductive layer 12 of the transparent conductive substrate 1a with the laser light via the first mask 53. The second laser machining step is a step performed by irradiating the transparent conductive layer 12 of the transparent conductive substrate 1a with the laser light via the second mask 54. The first laser machining step and the second laser machining step will be descried in detail below.

### (First Laser Machining Step)

As shown in FIG. 9B, the transparent conductive layer 12 of the transparent conductive substrate 1a is irradiated with the laser light via the first mask 53 to form an irradiated portion 13L on the surface of the transparent conductive layer 12. This forms the unit section 13p of the transparent electrode portion 13. Such an operation is performed on the entire first region (formation region of the transparent electrode portion 13) R₁ of the transparent conductive layer 12 while moving the irradiated portion 13L at periods Tx and periods Ty in the X-axis direction and the Y-axis direction, respectively. As a result, the unit section 13p is repeatedly and periodically formed in the X-axis direction and the Y-axis direction, whereby the transparent electrode portion 13 is obtained.

### (Second Laser Machining Step)

As shown in FIG. 9C, the transparent conductive layer 12 of the transparent conductive substrate 1a is irradiated with the laser light via the second mask 54 to form an irradiated portion 14L on the surface of the transparent conductive layer 12. This forms the unit section 14p of the transparent insulating portion 14. Such an operation is performed on the entire second region (formation region of the transparent insulating portion 14) R₂ of the transparent conductive layer 12 while moving the irradiated portion 14L at periods Tx and periods Ty in the X-axis direction and the Y-axis direction, respectively. As a result, the unit section 14p is repeatedly and periodically formed in the X-axis direction and the Y-axis direction, whereby the transparent insulating portion 14 is obtained.

In such a manner, the intended first transparent conductive element 1 is obtained.

### (Machining Depth by Laser Machining)

FIG. 33 schematically shows an average depth d of machining when a transparent conductive sheet is irradiated with laser light. FIG. 33 shows the transparent conductive substrate 1a obtained by depositing the transparent conductive layer 12 on the surface of the substrate 11. For the sake of simplicity, FIG. 33 shows the transparent conductive substrate 1a in which hole portions are machined in a regular pattern.

As shown in FIG. 33, if laser machining is used to form (pattern) the hole portions in the transparent conductive substrate 1a by laser machining, not only the transparent conductive layer 12 but also the substrate 11 is machined by ablation. On the other hand, if wet etching is used to process the transparent conductive substrate 1a, no hole portion is typically formed in the substrate 11, although depending on the type of the substrate 11. Whether the patterning has been performed by using laser machining can thus be determined by evaluating the state of the laser-machined portions of the substrate 11 (for example, shape such as the average depth d) under an optical microscope or the like. If the machined hole portions function as insulating portions, the machining may be performed to cause ablation to the substrate 11.

### [Effect]

According to the first embodiment, the first transparent conductive element 1 includes the transparent electrode portions 13 and the transparent insulating portions 14 which are alternately and adjacently provided on the surface of the substrate 11 in a planar manner. The transparent electrode portions 13 have the configuration that the unit section 13p including a random pattern is repeated. The transparent insulating portions 14 have the configuration that the unit section 14p including a random pattern is repeated. The random patterns can thus be easily formed over a large area.

The hole portions 13a of the unit section 13p and the island portions 14a of the unit section 14p are provided in random patterns. This can suppress the occurrence of moiré.

The first transparent conductive element 1 includes the transparent electrode portions 13 and the transparent insulating portions 14 which are alternately and adjacently provided on the surface of the substrate 11 in a planar manner. This can reduce a difference in reflectance between the transparent electrode portions 13 and the transparent insulating portions 14. Consequently, the visual recognition of the transparent electrode portions 13 can be suppressed.

If a shape pattern is further provided in the boundary portions between the transparent electrode portions 13 and the transparent insulating portions 14, the visual recognition of the boundary portions can be further suppressed. As a result, the visual recognition of the transparent electrode portions 13 can be further suppressed.

The second transparent conductive element 2 includes the transparent electrode portions 23 and the transparent insulating portions 24 which are alternately and adjacently provided on the surface of the substrate 21 in a planar manner. The transparent electrode portions 23 and the transparent insulating portions 24 have the same configuration as that of the transparent electrode portions 13 and the transparent insulating portions 14 of the first transparent conductive element 1. The second transparent conductive element 2 can thus provide the same effects as those of the first transparent conductive element 1.

If the information input device 10 includes the first transparent conductive element 1 and the second transparent conductive element 2 stacked on each other, the visual recognition of the transparent electrode portions 13 and the transparent electrode portions 23 can be suppressed. As a result, an information input device 10 having excellent visibility can be achieved. If such an information input device 10 is provided on the display surface of the display device 4, the visual recognition of the information input device 10 can be suppressed.

As compared to other processes, laser machining has advantages in terms of micromachining such as the following. Wet processes such as screen printing have a pattern accuracy of approximately L/S=30 μm. Laser machining processes can achieve a pattern accuracy of L/S<10 μm. Here, L is the pattern line width, and S is the line spacing.

If laser machining is performed by using UV laser, the damage of the substrates 11 and 21 made of a PET film or the like from an etchant or the like can be suppressed. Consequently, the transparent conductive layers including metal nanowires and/or indium tin oxide (ITO) can be selectively ablated.

### (Modifications)

Modifications of the first embodiment will be described below.

### (Transparent Electrode Portions)

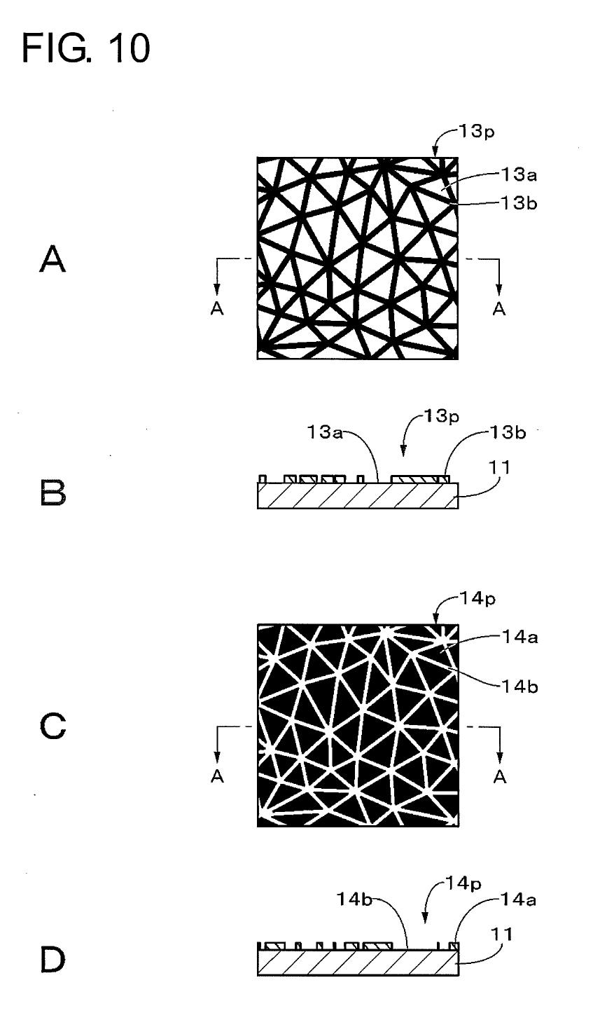

FIG. 10A is a plan view illustrating a modification of the unit section of the transparent electrode portions. FIG. 10B is a cross-sectional view taken along line A-A shown in FIG. 10A. As shown in FIGS. 10A and 10B, the unit section 13p of the transparent electrode portions 13 is a transparent conductive layer 12 including transparent conductive portions 13b which are provided in a random mesh-like configuration. The transparent conductive portions 13b are extended in random directions, and the extended transparent conductive portions 13b form independent hole portions 13a. As a result, a plurality of hole portions 13a are provided at random in the unit section 13p of the transparent electrode portions 13. When the transparent conductive element 1 is seen, there is a random linear shape.

### (Transparent Insulating Portions)

FIG. 10C is a plan view showing a modification of the unit section of the transparent insulating portions. FIG. 10D is a cross-sectional view taken along line A-A shown in FIG. 10C. As shown in FIGS. 10C and 10D, the unit section 14p of the transparent insulating portions 14 is a transparent conductive layer 12 including a gap portion 14b provided in a random mesh-like configuration. Specifically, the transparent conductive layer 12 arranged in the unit section 14p is divided into independent island portions 14a by the gap portions 14b extended in random directions. In other words, the unit section 14p is configured by using the transparent conductive layer 12. The island portions 14b formed by dividing the transparent conductive layer 12 by the gap portion 14b extended in random directions are arranged in a random pattern. For example, the pattern (i.e., random pattern) of the island portions 14a is such that random polygonal shapes are divided by the gap portion 14b extended in random directions. Note that the gap portion 14b extended in random directions themselves also form a random pattern. For example, when the first transparent conductive element 1 is seen from the surface on the side where the transparent conductive layer 12 is provided, the gap portion 14b have a random linear shape. For example, the gap portion 14b are grooves formed between the island portions 14a.

Here, each gap portion 14b formed in the unit section 14p is extended in a random direction in the unit section 14p. For example, the width (referred to as a line width) in a direction perpendicular to the direction of extension is selected to be an identical width. In the unit section 14p, the coverage ratio of the transparent conductive layer 12 is adjusted by means of the line width of the gap portion 14b. The coverage ratio of the transparent conductive layer 12 in the unit section 14p is preferably set to be equivalent to that of the transparent conductive layer 12 in the transparent electrode portions 13. As employed herein, being equivalent refers to an extent such that the transparent electrode portions 13 and the transparent insulating portions 14 are visually unrecognizable as a pattern.

### (Hard Coat Layer)

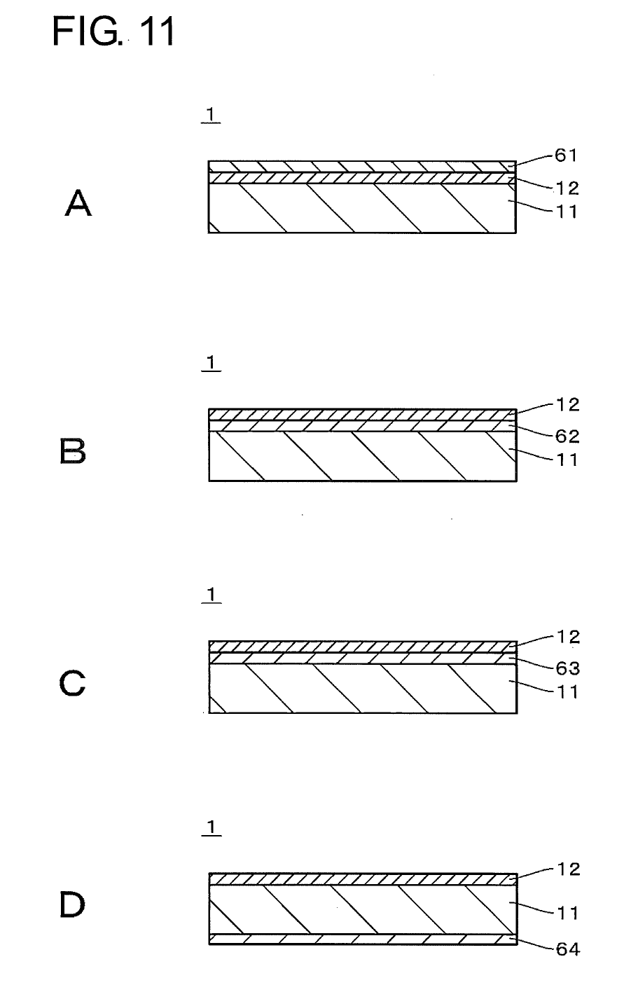

As shown in FIG. 11A, a hard coat layer 61 may be provided on at least either one of the two surfaces of the first transparent conductive element 1. If a plastic substrate is used as the substrate 11, this can prevent damage to the substrate 11 during processes, provide resistance to chemicals, and suppress precipitation of low molecular weight substances such as oligomers. Ionizing radiation curable resins which cure with light, electron beams, or the like, or thermosetting resins which cure with heat are preferably used as the hard coat material. Photosensitive resins that cure with ultraviolet rays are most preferred. Examples of such photosensitive resins may include acrylate resins such as urethane acrylate, epoxy acrylate, polyester acrylate, polyol acrylate, polyester acrylate, and melamine acrylate. For example, urethane acrylate resin is obtained by making polyester polyol react with isocyanate monomer or prepolymer and making the resulting product react with acrylate or methacrylate monomer having a hydroxyl group. The hard coat layer 61 preferably has a thickness of 1 μm to 20 μm, but is not particularly limited to such a range.

The hard coat layer 61 is formed in the following manner. Initially, a hard coating material is applied to the surface of the substrate 11. The application method is not limited in particular, and a publicly-known application method may be used. Examples of the publicly-known application method may include a micro gravure coating method, a wire bar coating method, a direct gravure coating method, a die coating method, a dipping method, a spray coating method, a reverse roll coating method, a curtain coating method, a comma coating method, a knife coating method, and a spin coating method. For example, the hard coating material contains a resin material such as a bifunctional or higher functionality monomer and/or oligomer, a photopolymerization initiator, and a solvent. Next, the hard coating material applied to the surface of the substrate 11 is dried, if needed, to evaporate the solvent. Next, the hard coating material on the surface of the substrate 11 is cured, for example, by ionizing radiation irradiation or by heating. Like the first transparent conductive element 1 described above, a hard coat layer 61 may be provided on at least either one of the two surfaces of the second transparent conductive element 2.

### (Optical Adjustment Layer)

As shown in FIG. 11B, an optical adjustment layer 62 is preferably interposed between the substrate 11 and the transparent conductive layer 12 of the first transparent conductive element 1. This can assist non-visibility of the pattern shape of the transparent electrode portions 13. For example, the optical adjustment layer 62 includes two or more layers of laminates having different refractive indexes. The transparent conductive layer 12 is formed on the low refractive index layer side. More specifically, for example, a publicly-known conventional optical adjustment layer may be used as the optical adjustment layer 62. Examples of such an optical adjustment layer may include ones described in Japanese Patent Application Laid-Open Nos. 2008-98169, 2010-15861, 2010-23282, and 2010-27294. Like the first transparent conductive element 1 described above, an optical adjustment layer 62 may be interposed between the substrate 21 and the transparent conductive layer 22 of the second transparent conductive element 2.

### (Adhesion Auxiliary Layer)

As shown in FIG. 11C, an adhesion auxiliary layer 63 is preferably provided as an underlayer of the transparent conductive layer 12 of the first transparent conductive element 1. This can improve the adhesion of the transparent conductive layer 12 to the substrate 11. Examples of the material of the adhesion auxiliary layer 63 may include polyacryl-based resins, polyamide-based resins, polyamide-imide-based resins, polyester-based resins, chlorides and peroxides of metal elements, and hydrolysates and dehydration condensation products of alkoxides.

Instead of using the adhesive auxiliary layer 63, a discharge treatment of irradiating with a glow discharge or corona discharge may be applied to the surface where the transparent conductive layer 12 is formed. A chemical treatment method for treating with an acid or alkali may be applied to the surface where the transparent conductive layer 12 is formed. After the provision of the transparent conductive layer 12, calendaring processing may be performed to improve adhesion. Like the first transparent conductive element 1 described above, the second transparent conductive element 2 may be provided with an adhesion auxiliary layer 63. The foregoing treatment or processing for improving adhesion may be applied.

### (Shield Layer)

As shown in FIG. 11D, a shield layer 64 is preferably provided on the first transparent conductive element 1. For example, a film on which the shield layer 64 is provided may be bonded to the first transparent conductive element 1 via a transparent adhesive layer. If X electrodes and Y electrodes are formed on the same side of a single substrate 11, the shield layer 64 may be directly formed on the other side. The shield layer 64 may be made of the same material as that of the transparent conductive layer 12. The shield layer 64 may be formed by using the same method as that of the transparent conductive layer 12. Note that the shield layer 64 is formed over the entire surface of the substrate 11 and used without being patterned. The formation of the shield layer 64 on the first transparent conductive element 1 can reduce noise resulting from electromagnetic waves and the like occurring from the display device 4 and improve the accuracy of position detection by the information input device 10. Like the first transparent conductive element 1 described above, a shield layer 64 may be provided on the second transparent conductive element 2.

### (Antireflection Layer)

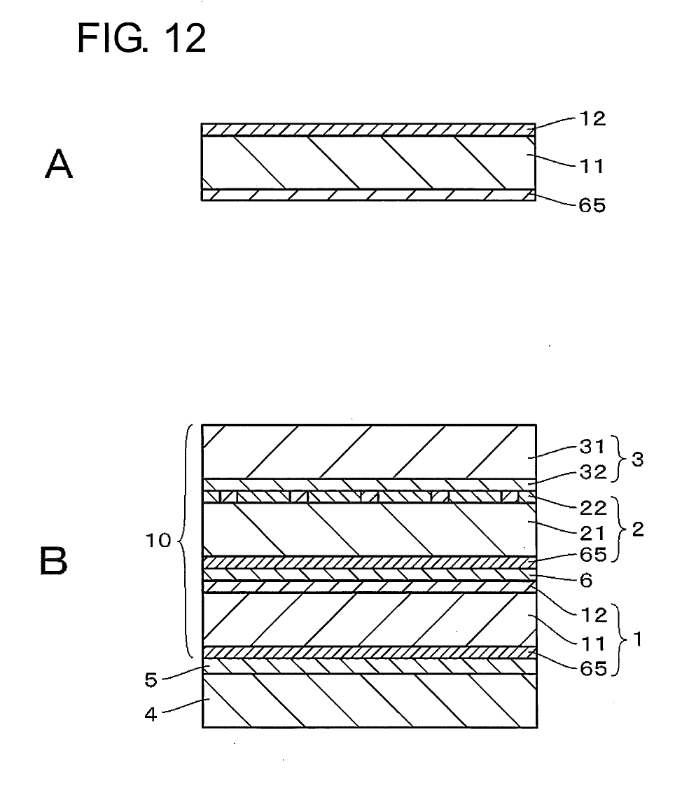

As shown in FIG. 12A, an antireflection layer 65 is preferably further provided on the first transparent conductive element 1. For example, the antireflection layer 65 is provided on one of the two principal surfaces of the first transparent conductive element 1 on the side opposite to the side where the transparent conductive layer 12 is provided.

For example, a low refractive index layer, a moth-eye structure, or the like may be used as the antireflection layer 65. If a low refractive index layer is used as the antireflection layer 65, a hard coat layer may be further provided between the substrate 11 and the antireflection layer 65. Like the first transparent conductive element 1 described above, an antireflection layer 65 may be further provided on the second transparent conductive element 2.

FIG. 12B is a cross-sectional view showing an application example of the first transparent conductive element and the second transparent conductive element provided with antireflection layers 65. As shown in FIG. 12B, the first transparent conductive element 1 and the second transparent conductive element 2 are each arranged on the display device 4 so that one of their two principal surfaces on the side where an antireflection layer 65 is provided is opposed to the display surface of the display device 4. Such a configuration can be employed to improve the transmittance of the light from the display surface of the display device 4 and improve the display performance of the display device 4.

### (Laser Machining Apparatus)

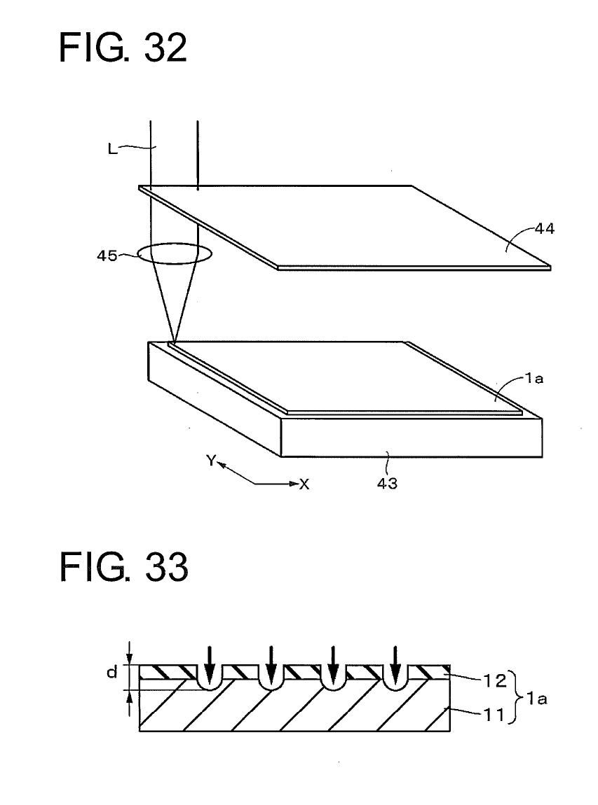

FIG. 32 is a schematic diagram showing a modification of the laser machining apparatus. The laser machining apparatus includes a stage 43, a mask 44, a lens 45, and a laser (not shown). The mask 44 has a size greater than that of the transparent conductive substrate 1a to be machined. The mask 44 is configured to be movable in the X-axis direction and the Y-axis direction in synchronization with the stage 43. The transparent conductive layer of the transparent conductive substrate 1a is irradiated with laser light L via the mask 44 and the lens 45.

An operation of the laser machining apparatus having the foregoing configuration will be described below.

The transparent conductive layer of the transparent conductive substrate 1a serving as the workpiece to be machined is initially irradiated with the laser light via the mask having a pattern. Next, the mask 44 and the stage 43 are synchronously moved in the X-axis direction and/or the Y-axis direction to move the irradiation position of the mask with the laser light. Almost the entire transparent conductive layer of the transparent conductive substrate 1a is machined in such a manner, whereby the transparent electrode portions 13 and the transparent insulating portions 14 are alternately and adjacently formed in a planar manner in one direction.

The laser machining apparatus of this modification will not produce overlapping of the patterns of the unit sections 13p and 14p and the like, or an unprocessed area between the patterns. This provides the advantage that the characteristics of the first transparent conductive element 1 and the like can be improved.

### 2. Second Embodiment

### [Configuration of Transparent Conductive Element]

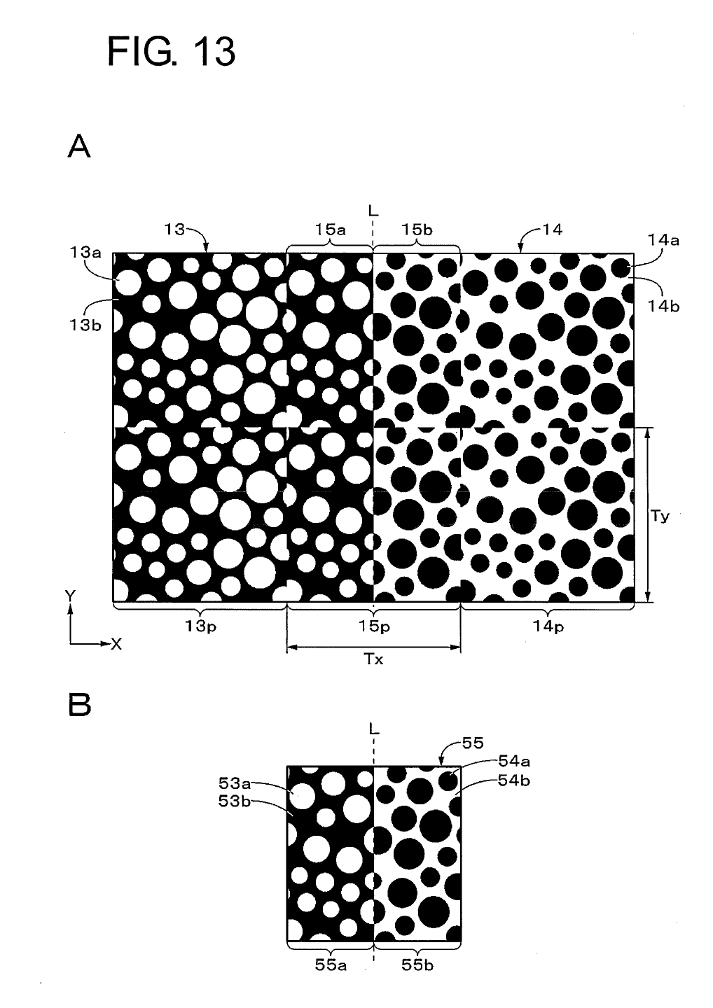

FIG. 13A is a plan view showing a configuration example of a first transparent conductive element according to a second embodiment of the present technique. The first transparent conductive element 1 according to the second embodiment is different from the first transparent conductive element 1 according to the first embodiment in that unit sections 15p including a boundary pattern are further provided in the boundary portions between the transparent electrode portions 13 and the transparent insulating portions 14.

For example, the unit section 15p is repeatedly provided in the Y-axis direction (i.e., in the extending direction of the boundary portions) at periods Ty. FIG. 13A shows an example where one type of unit section 15p is used. However, two or more types of unit sections 15p may be used. In such a case, the same type of unit section 15p may be repeated in the Y-axis direction periodically or at random.

The unit section 15p is not limited to any particular shape as long as the unit section 15p can be repeatedly provided in the boundary portions without a gap. Examples thereof may include polygonal shapes such as triangular, rectangular, hexagonal, and octagonal shapes, and irregular shapes.

As shown in FIG. 13A, the unit section 15p has a boundary portion where a random shape pattern is provided. The provision of the random shape pattern in the boundary portion can suppress visual recognition of the boundary portion. The same pattern as that of the first embodiment may be used as the shape pattern of the boundary portion. Shapes other than those of the pattern elements of the random patterns of the transparent electrode portions 13 and the transparent insulating portions 14 may be used.

The unit section 15p includes a first section 15a and a second section 15b. The two sections are joined at a boundary L. For example, the first section 15a is part of the unit section 13p of the transparent electrode portions 13. For example, the second section 15b is part of the unit section 14p of the transparent insulating portions 14. Specifically, the first section 15a is a section obtained by partly cutting the unit section 13p by the boundary L. The first section 15a is provided with the cut side in contact with the boundary L on the side of the transparent electrode portion 13. Meanwhile, the second section 15b is a section obtained by partly cutting the unit section 14p by the boundary L. The second section 15b is provided with the cut side in contact with the boundary L on the side of the transparent insulating portion 14.

Note that FIG. 13A shows an example where the first section 15a and the second section 15b of the unit section 15p are constituted by halves of the unit section 13p and the unit section 14p, respectively. The sizes of the unit section 13p and the unit section 14p to constitute the first section 15a and the second section 15b, respectively, are not limited thereto. The sizes of the two may be arbitrarily selected. Random patterns different from those of the unit section 13p and the unit section 14p may be used as the random patterns of the first section 15a and the second section 15b. Regular patterns may be used instead of the random patterns of the first section 15a and the second section 15b.

### [Laser Machining Apparatus]

In addition to the first mask 53 and the second mask 54 according to the foregoing first embodiment, the mask unit 42 of the laser machining apparatus further includes a third mask for producing the boundary pattern in the boundary portions between the transparent electrode portions 13 and the transparent insulating portions 14.

The mask unit 42 has a configuration such that the first mask 53, the second mask 54, and the third mask can be switched by a control apparatus (not shown). The laser machining apparatus can thus form the transparent electrode portions 13, the transparent insulating portions 14, and the boundary portions thereof repeatedly in a continuous manner. If there are two or more types of unit sections 15p serving as the unit sections 15p, the mask unit 42 includes two or more types of third masks.

FIG. 13B is a plan view showing a configuration example of the third mask for producing the boundary pattern in the boundary portions between the transparent electrode portions 13 and the transparent insulating portions 14. As shown in FIG. 13B, the third mask 55 includes a first section 55a and a second section 55b. The two sections are joined at a boundary L. For example, the first section 55a is part of the first mask 53. For example, the second section 55b is part of the second mask 54. Specifically, the first section 55a is a section obtained by partly cutting the first mask 53 by the boundary L. The first section 55a is provided with the cut side in contact with one side of the boundary L. The second section 55b is a section obtained by partly cutting the second mask 54 by the boundary L. The second section 55b is provided with the cut side in contact with the other side of the boundary L.

Note that FIG. 13B shows an example where the first section 55a and the second section 55b of the third mask 55 are constituted by halves of the first mask 53 and the second mask 54, respectively. The sizes of the first mask 53 and the second mask 54 to constitute the first section 55a and the second section 55b, respectively, are not limited thereto. The sizes of the two may be arbitrarily selected. Random patterns different from those of the first mask 53 and the second mask 54 may be used as the random patterns of the first section 55a and the second section 55b. Regular patterns may be used instead of the random patterns of the first mask 53 and the second mask 54.

### [Method for Manufacturing Transparent Conductive Element]

A method for manufacturing the first transparent conductive element according to the second embodiment is different from the method for manufacturing the first transparent conductive element according to the first embodiment in that the step of forming the transparent electrode portions and the transparent insulating portions further includes a third laser machining step between the first laser machining step and the second laser machining step. The third laser machining step is a step for producing the boundary pattern in the boundary portions between the transparent electrode portions 13 and the transparent insulating portions 14. The third laser machining step will be described below.

### (Third Laser Machining Step)

The transparent conductive layer 12 of the transparent conductive substrate 1a is irradiated with laser light via the third mask 55, whereby an irradiated portion is formed on the surface of the transparent conductive layer 12. This forms the unit section 15p of the boundary portion. Such an operation is successively repeated while moving the irradiated portion in the Y-axis direction (i.e., the extending direction of the boundary portion) at periods Ty. As a result, the unit sections 15p are repeatedly and periodically formed in the Y-axis direction, whereby a boundary portion having a random shape pattern is obtained.

In other respects, the second embodiment is the same as the first embodiment.

### 3. Third Embodiment

### [Configuration of Transparent Conductive Element]

### (Transparent Electrode Portions and Transparent Insulating Portions)

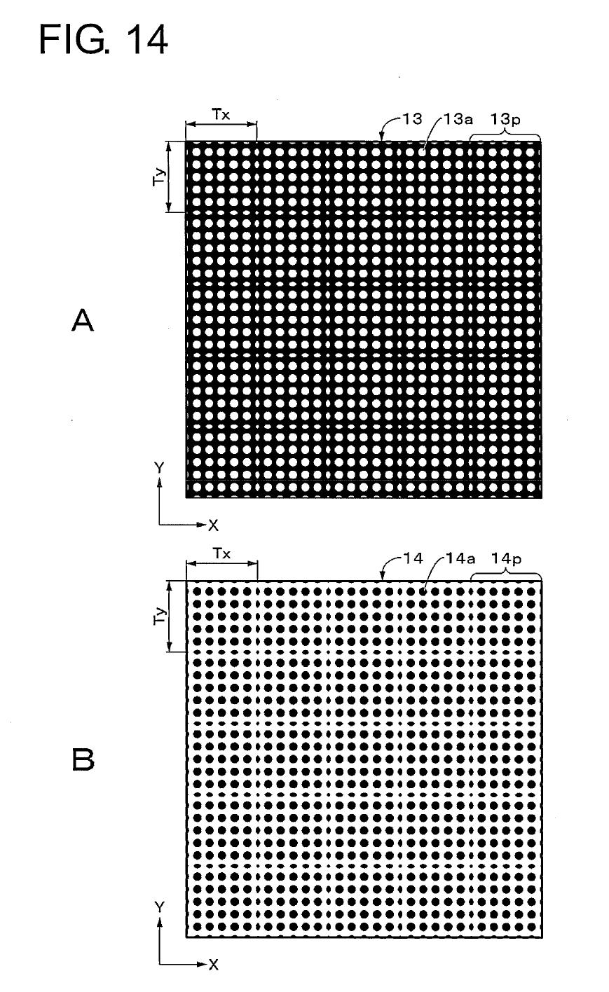

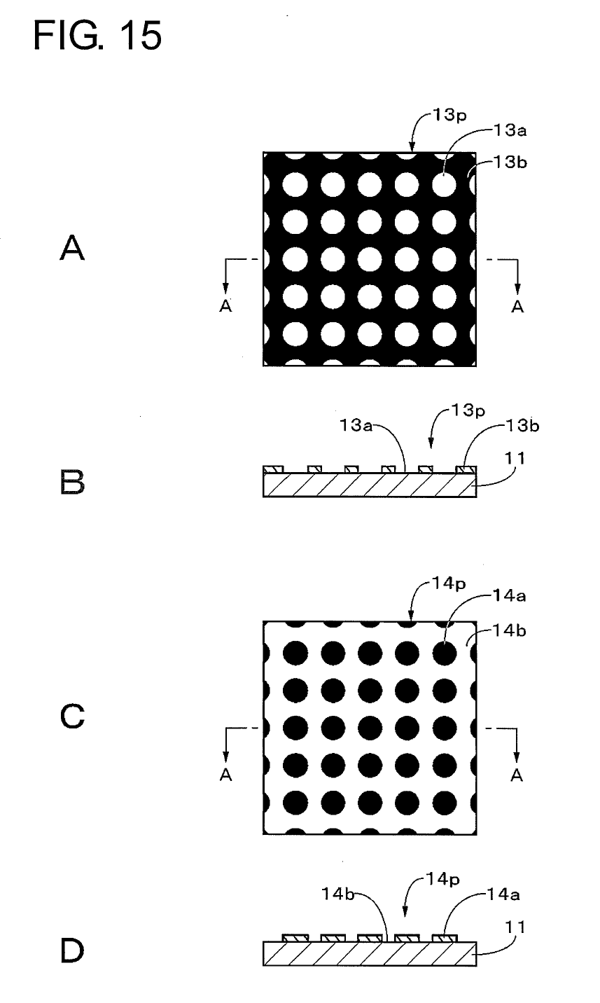

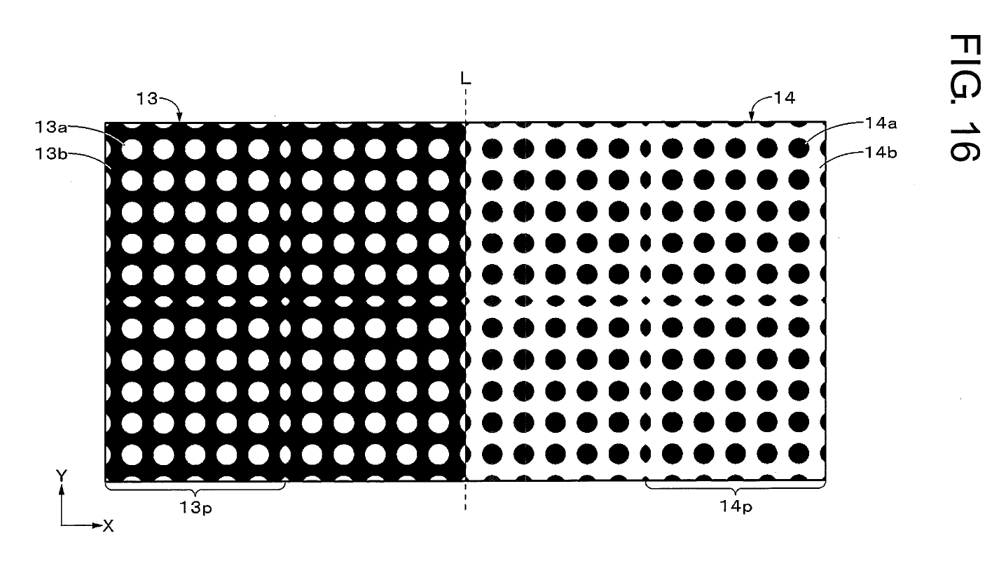

FIG. 14A is a plan view showing a configuration example of a transparent electrode portion of the first transparent conductive element. FIG. 15A is a plan view showing a configuration example of a unit section of the transparent electrode portion. FIG. 15B is a cross-sectional view taken along line A-A shown in FIG. 15A. The transparent electrode portion 13 is a transparent conductive layer 12 in which a unit section 13p including a regular pattern of hole portions 13a is repeatedly provided.

FIG. 14B is a plan view showing a configuration example of a transparent insulating portion of the first transparent conductive element. FIG. 15C is a plan view showing a configuration example of a unit section of the transparent insulating portion. FIG. 15D is a cross-sectional view taken along line A-A shown in FIG. 15C. The transparent insulating portion 14 is a transparent conductive layer 12 in which a unit section 14p including a regular pattern of island portions 14a is repeatedly provided.

### (Boundary Portions)

A regular shape pattern is provided in boundary portions between the transparent electrode portions 13 and the transparent insulating portions 14. The provision of a regular shape pattern in the boundary portions can suppress visual recognition of the boundary portions.

FIG. 16 is a plan view showing an example of the shape pattern of the boundary portion. The shape pattern of the boundary portion preferably includes the entire and/or part of the pattern elements of the regular pattern(s) of at least either one of the transparent electrode portion 13 and the transparent insulating portion 14. More specifically, the shape pattern of the boundary portion preferably includes one or more shapes selected from the group consisting of the entire hole portions 13a, part of the hole portions 13a, the entire island portions 14a, and part of the island portions 14a.

The unit section 13p preferably has a side which a hole portion or portions 13a serving as pattern elements of the regular pattern is/are in contact with or cut by, and is provided with the side in contact with or almost in contact with the boundary L between the transparent electrode portion 13 and the transparent insulating portion 14.

The unit section 14p preferably has a side which an island portion or portions 14a serving as pattern elements of the regular pattern is/are in contact with or cut by, and is provided with the side in contact with or almost in contact with the boundary L between the transparent electrode portion 13 and the transparent insulating portion 14.

Note that FIG. 16 shows an example where the shape pattern of the boundary portion includes part of the regular patterns of both the transparent electrode portion 13 and the transparent insulating portion 14. More specifically, FIG. 16 shows an example where the shape pattern of the boundary portion includes part of both the hole portions 13a and the island portions 14a. In such an example, part of the hole portions 13a included in the boundary portion have the shape of the hole portions 13a partly cut by the boundary L, and are provided with the cut sides in contact with the boundary L on the side of the transparent electrode portion 13. Part of the island portions 14a included in the boundary portion have the shape of the island portions 14a partly cut by the boundary L, and are provided with the cut sides in contact with the boundary L on the side of the transparent insulating portion 14.

### [Method for Manufacturing Transparent Conductive Element]

A method for manufacturing the first transparent conductive element according to the third embodiment uses a first mask 53 including a plurality of hole portions (light transmission elements) 53a which are provided apart from each other in a regular pattern. The method uses a second mask 54 including a plurality of light-shielding portions (light-shielding elements) 54a which are provided apart from each other in a regular pattern.

In other respects, the third embodiment is the same as the first embodiment.

### 4. Fourth Embodiment

### [Configuration of Transparent Conductive Element]

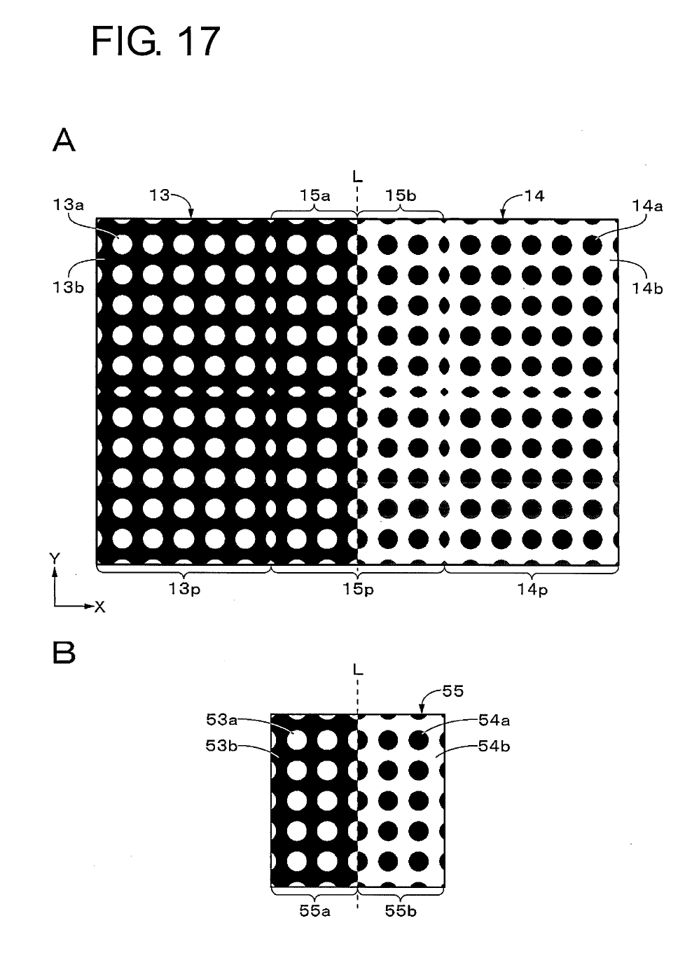

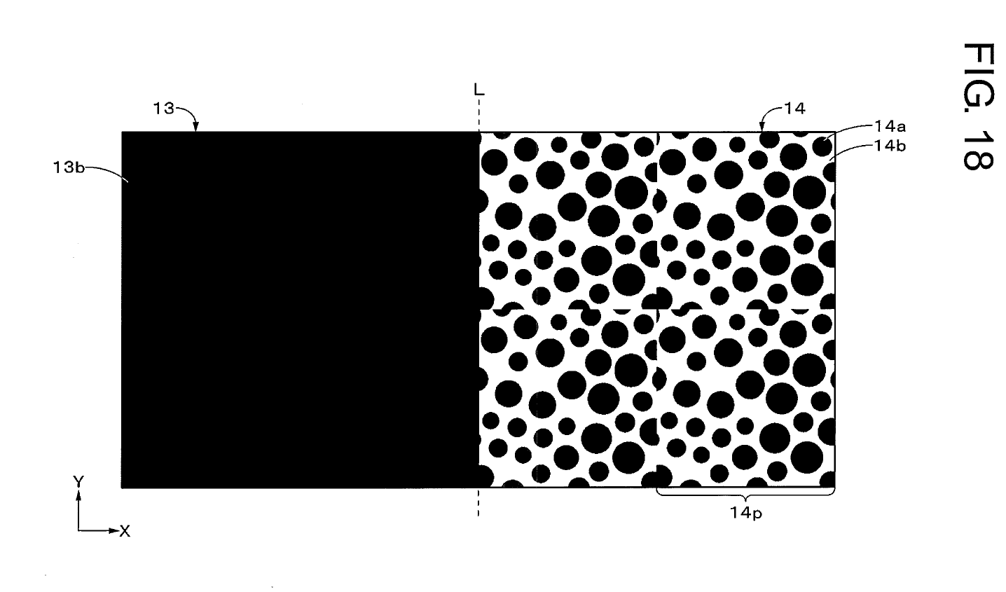

FIG. 17A is a plan view showing a configuration example of a first transparent conductive element according to a fourth embodiment of the present technique. The first transparent conductive element 1 according to the fourth embodiment is different from the first transparent conductive element 1 according to the third embodiment in that unit sections 15p including a boundary pattern are further provided in the boundary portions between the transparent electrode portions 13 and the transparent insulating portions 14.

As shown in FIG. 17A, the unit section 15p has a boundary portion where a regular shape pattern is provided. The provision of a regular shape pattern in the boundary portion can suppress visual recognition of the boundary portion. The same pattern as that of the foregoing third embodiment may be used as the shape pattern of the boundary portion. Shapes other than the pattern elements of the regular patterns of the transparent electrode portions 13 and the transparent insulating portions 14 may be used.

FIG. 17A shows an example where a first section 15a and a second section 15b of the unit section 15p are constituted by halves of the unit section 13p and the unit section 14p, respectively. The sizes of the unit section 13p and the unit section 14p to constitute the first section 15a and the second section 15b, respectively, are not limited thereto. The sizes of the two may be arbitrarily set. Regular patterns different from those of the unit section 13p and the unit section 14p may be used as the regular patterns of the first section 15a and the second section 15b. Random patterns may be used instead of the regular patterns of the first section 15a and the second section 15b.

### [Laser Machining Apparatus]

In addition to the first mask 53 and the second mask 54 according to the foregoing third embodiment, the mask unit 42 of the laser machining apparatus further includes a third mask for producing the boundary pattern in the boundary portions between the transparent electrode portions 13 and the transparent insulating portions 14.

FIG. 17B is a plan view showing a configuration example of the third mask for producing the boundary pattern in the boundary portions between the transparent electrode portions 13 and the transparent insulating portions 14. As shown in FIG. 17B, the third mask 55 includes a first section 55a and a second section 55b. The two sections are joined at a boundary L.

Note that FIG. 17B shows an example where the first section 55a and the second section 55b of the third mask 55 are constituted by halves of the first mask 53 and the second mask 54, respectively. The sizes of the first mask 53 and the second mask 54 to constitute the first section 55a and the second section 55b, respectively, are not limited thereto. The sizes of the two may be arbitrarily set. Regular patterns different from those of the first mask 53 and the second mask 54 may be used as the regular patterns of the first section 55a and the second section 55b. Random patterns may be used instead of the regular patterns of the first mask 53 and the second mask 54.

### [Method for Manufacturing Transparent Conductive Element]

A method for manufacturing the first transparent conductive element according to the fourth embodiment is the same as the method for manufacturing the first transparent conductive element according to the second embodiment except that the foregoing laser machining apparatus is used.

In other respects, the fourth embodiment is the same as the second embodiment.

### 5. Fifth Embodiment

### [Configuration of Transparent Conductive Element]

### (Transparent Electrode Portions and Transparent Insulating Portions)

FIG. 18 is a plan view showing a configuration example of a first transparent conductive element according to a fifth embodiment of the present technique. As shown in FIG. 18, the first transparent conductive element 1 according to the fifth embodiment is different from the first transparent conductive element according to the first embodiment in that a continuously-formed transparent conductive layer 12 is provided as the transparent electrode portions 13.

The transparent electrode portions 13 are a transparent conductive layer (continuous film) 12 continuously formed without exposing the surface of the substrate 11 in hole portions 13a in the first regions (electrode regions) R₁. Note that the boundary portions between the first regions (electrode regions) R₁ and the second regions (insulating regions) R₂ are excluded. The transparent conductive layer 12, being the continuous film, preferably has a near uniform thickness.

### (Boundary Portions)

A random shape pattern is provided in the boundary portions between the transparent electrode portions 13 and the transparent insulating portions 14. The provision of a random shape pattern in the boundary portions can suppress visual recognition of the boundary portions.

The shape pattern of the boundary portions include one or more types of shapes selected from the group consisting of the entire island portions 14a and part of the island portions 14a. Specifically, for example, the shape pattern of the boundary portions includes the entire island portions 14a, part of the island portions 14a, or both the entire island portions 14a and part of the island portions 14a.

FIG. 18 shows an example where the shape pattern of the boundary portion includes part of the island portions 14a. In this example, the part of the island portions 14a included in the boundary portion have, for example, the shapes of the island portions 14a partly cut by the boundary L, and are provided with the cut sides in contact with the boundary L on the side of the transparent insulating portion 14.

### [Method for Manufacturing Transparent Conductive Element]

A method for manufacturing the first transparent conductive element 1 according to the fifth embodiment is different from the method for manufacturing the first transparent conductive element 1 according to the first embodiment in that the first laser machining step is omitted and only the second laser machining step is repeated. By repeating only the second laser machining step, the second regions (the formation regions of the transparent insulating portions 14) R₂ of the transparent conductive layer 12 are patterned. The first regions (the formation regions of the transparent electrode portions 13) R₁ of the transparent conductive layer 12 are not patterned, and the transparent conductive layer 12 remains as a continuous film.

In other respects, the fifth embodiment is the same as the first embodiment.

### 6. Sixth Embodiment

### [Configuration of Transparent Conductive Element]

### (Transparent Electrode Portions and Transparent Insulating Portions)

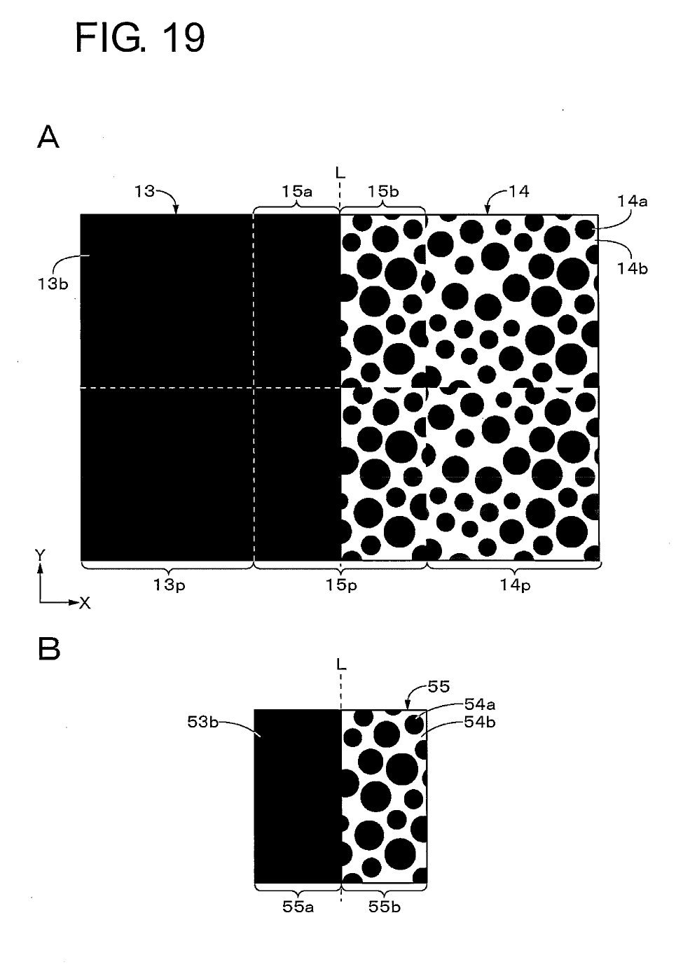

FIG. 19A is a plan view showing a configuration example of a first transparent conductive element according to a sixth embodiment of the present technique. The first transparent conductive element 1 according to the sixth embodiment is different from the first transparent conductive element 1 according to the fifth embodiment in that unit sections 15p including a boundary pattern are further provided in the boundary portions between the transparent electrode portions 13 and the transparent insulating portions 14.

As shown in FIG. 19A, the unit section 15p has a boundary portion where a random shape pattern is provided. The provision of a random shape pattern in the boundary portion can suppress visual recognition of the boundary portion. The same pattern as that of the foregoing fifth embodiment may be used as the shape pattern of the boundary portion. Shapes other than the pattern elements of the regular patterns of the transparent electrode portions 13 and the transparent insulating portions 14 may be used.

Note that FIG. 19A shows an example where a first section 15a and a second section 15b of the unit section 15p are constituted by part of the unit section 13p (a virtual unit section because of the continuous film) and the unit section 14p, respectively. The sizes of the unit section 13p and the unit section 14p to constitute the first section 15a and the second section 15b, respectively, are not limited thereto. The sizes of the two may be arbitrarily selected. A random pattern different from that of the unit section 14p may be used as the random pattern of the second section 15b. A regular pattern may be used instead of the random pattern of the second section 15b.

### [Laser Machining Apparatus]

In addition to the first mask 53 and the second mask 54 according to the foregoing fifth embodiment, the mask unit 42 of the laser machining apparatus further includes a third mask for producing the boundary pattern in the boundary portions between the transparent electrode portions 13 and the transparent insulating portions 14.

FIG. 19B is a plan view showing a configuration example of the third mask for producing the boundary pattern in the boundary portions between the transparent electrode portions 13 and the transparent insulating portions 14. As shown in FIG. 19B, the third mask 55 includes a first section 55a and a second section 55b. The two sections are joined at a boundary L.

Note that FIG. 19B shows an example where the first section 55a and the second section 55b of the third mask 55 are constituted by halves of the first mask 53 and the second mask 54, respectively. The sizes of the first mask 53 and the second mask 54 to constitute the first section 55a and the second section 55b, respectively, are not limited thereto. The sizes of the two may be arbitrarily selected. A random pattern different from that of the second mask 54 may be used as the random pattern of the second section 55b. A regular pattern may be used instead of the random pattern of the second mask 54.

### [Method for Manufacturing Transparent Conductive Element]

A method for manufacturing the first transparent conductive element according to the sixth embodiment is the same as the method for manufacturing the first transparent conductive element according to the fifth embodiment except that the foregoing laser machining apparatus is used.

In other respects, the sixth embodiment is the same as the fifth embodiment.

### 7. Seventh Embodiment

### [Configuration of Transparent Conductive Element]

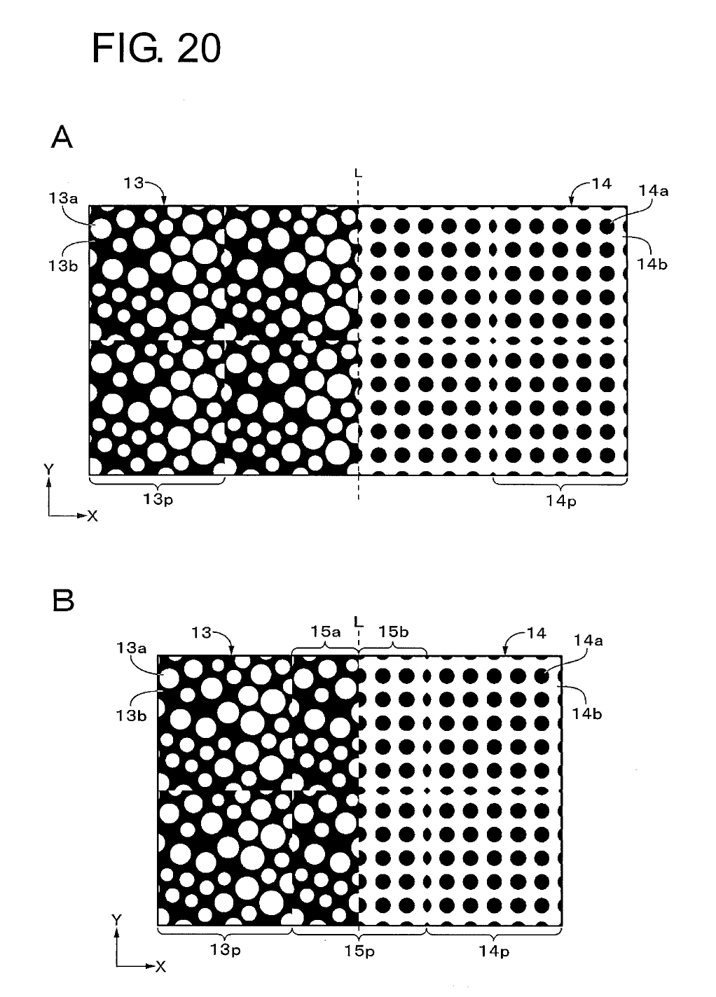

FIG. 20A is a plan view showing a configuration example of a first transparent conductive element according to a seventh embodiment of the present technique. Transparent electrode portions 13 are a transparent conductive layer 12 in which a unit section 13p including a random pattern of hole portions 13a is repeatedly provided. Specifically, the transparent electrode portions 13 have the same configuration as that of the transparent electrode portions 13 according to the first embodiment. Transparent insulating portions 14 are a transparent conductive layer 12 in which a unit section 14p including a regular pattern of island portions 14a is repeatedly provided. Specifically, the transparent insulating portions 14 have the same configuration as that of the transparent insulating portions 14 according to the third embodiment.

As shown in FIG. 20B, unit sections 15p including a boundary pattern may be further provided between the transparent electrode portions 13 and the transparent insulating portions 14.

In other respects, the seventh embodiment is the same as the first embodiment.

### 8. Eighth Embodiment

### [Configuration of Transparent Conductive Element]

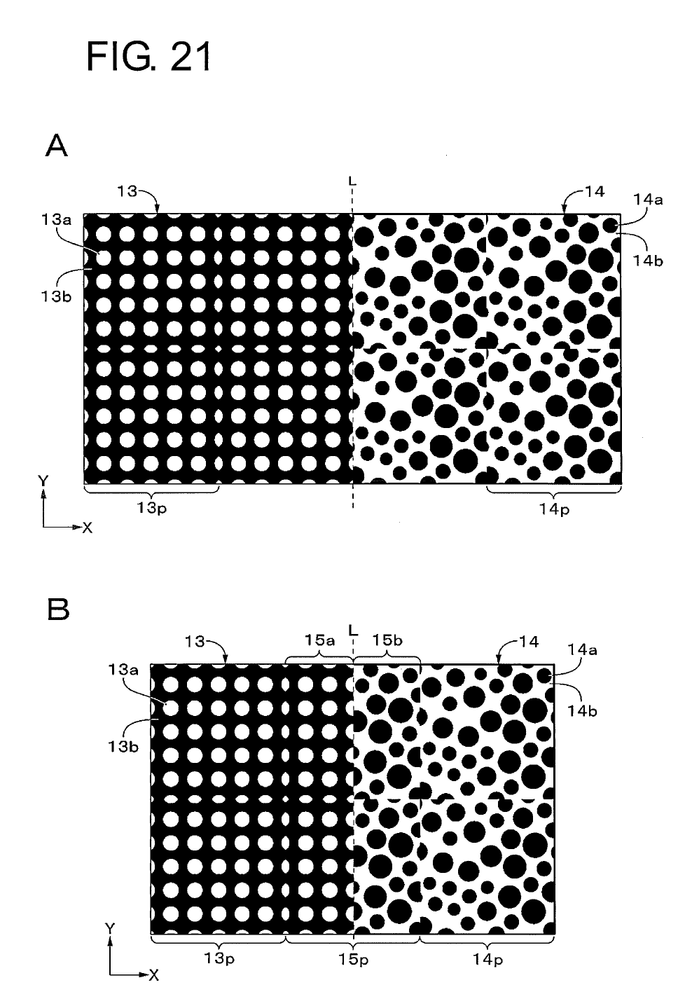

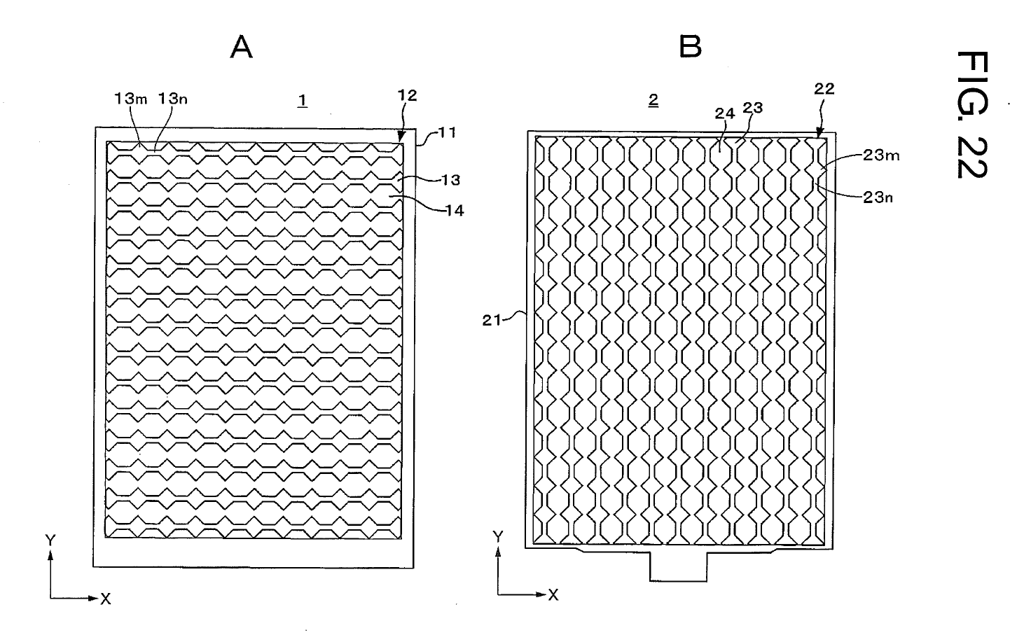

FIG. 21A is a plan view showing a configuration example of a first transparent conductive element according to an eighth embodiment of the present technique. Transparent electrode portions 13 are a transparent conductive layer 12 in which a unit section 13p including a regular pattern of hole portions 13a is repeatedly provided. Specifically, the transparent electrode portions 13 have the same configuration as that of the transparent electrode portions 13 according to the third embodiment. Transparent insulating portions 14 are a transparent conductive layer 12 in which a unit section 14p including a random pattern of island portions 14a is repeatedly provided. Specifically, the transparent insulating portions 14 have the same configuration as that of the transparent insulating portions 14 according to the first embodiment.

As shown in FIG. 21B, unit sections 15p including a boundary pattern may be further provided between the transparent electrode portions 13 and the transparent insulating portions 14.

In other respects, the eighth embodiment is the same as the first embodiment.

### 9. Ninth Embodiment

### [Configuration of Transparent Conductive Elements]

FIG. 22A is a plan view showing a configuration example of a first transparent conductive element according to a ninth embodiment of the present technique. FIG. 22B is a plan view showing a configuration example of a second transparent conductive element according to the ninth embodiment of the present technique. The ninth embodiment is the same as the first embodiment except the configuration of the transparent electrode portions 13, the transparent insulating portions 14, the transparent electrode portions 23, and the transparent insulating portions 24.

The transparent electrode portions 13 include a plurality of pad portions (unit electrode bodies) 13m and a plurality of connecting portions 13n which connect the plurality of pad portions 13m to each other. The connecting portions 13n are extended in the X-axis direction and connect the ends of adjacent pad portions 13m to each other. The pad portions 13m and the connecting portions 13n are integrally formed.

The transparent electrode portions 23 include a plurality of pad portions (unit electrode bodies) 23m and a plurality of connecting portions 23n which connect the plurality of pad portions 23m to each other. The connecting portions 23n are extended in the Y-axis direction and connect the ends of adjacent pad portions 23m to each other. The pad portions 23m and the connecting portions 23n are integrally formed.

For example, the pad portions 13m and the pad portions 23m may have, but are not limited to, a polygonal shape such as a rhombic shape (diamond shape) and a rectangular shape, a star shape, a cross shape, and the like.

The connecting portions 13n and the connecting portions 23n may have a rectangular shape. The connecting portions 13n and the connecting portions 23n are not limited to a rectangular shape in particular, and may have any shape that can connect adjacent pad portions 13m and pad portions 23m to each other. Examples of the shape other than a rectangular shape may include linear, oval, triangular, and irregular shapes.

To further improve non-visibility, the relationship between the coverage ratios of the first transparent conductive element (X electrodes) 1 and the second transparent conductive element (Y electrodes) 2 is preferably set with both the elements stacked on each other.

In other respects, the ninth embodiment is the same as the first embodiment.

### [Effect]

According to the ninth embodiment, the same effects as those of the first embodiment can be obtained.

### 10. Tenth Embodiment

### [Configuration of Information Input Device]

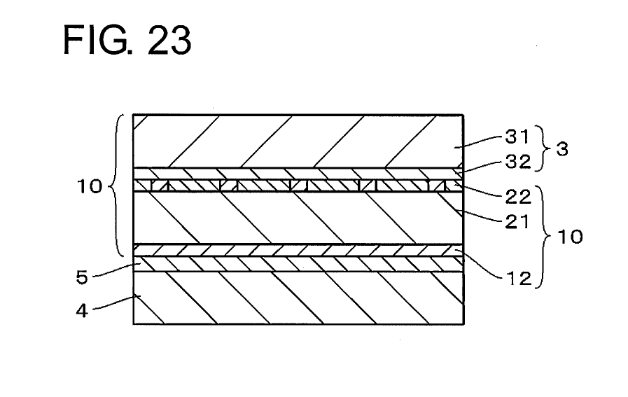

FIG. 23 is a cross-sectional view showing a configuration example of an information input device according to a tenth embodiment of the present technique. The information input device 10 according to the tenth embodiment is different from the information input device 10 according to the first embodiment in that a transparent conductive layer 12 is provided on one principal surface (first principal surface) of a substrate 21 and a transparent conductive layer 22 is provided on the other principal surface (second principal surface). The transparent conductive layer 12 includes transparent electrode portions and transparent insulating portions. The transparent conductive layer 22 includes transparent electrode portions and transparent insulating portions. The transparent electrode portions of the transparent conductive layer 12 are X electrode portions extended in the X-axis direction. The transparent electrode portions of the transparent conductive layer 22 are Y electrode portions extended in the Y-axis direction. That is, the transparent electrode portions of the transparent conductive layer 12 and the transparent conductive layer 22 are orthogonal to each other.

In other respects, the tenth embodiment is the same as the first embodiment.

### [Effect]

In addition to the effects of the first embodiment, the tenth embodiment can provide the following effect. That is, since the transparent conductive layer 12 is provided on one principal surface of the substrate 21 and the transparent conductive layer 22 is provided on the other principal surface, the substrate 11 (FIG. 1) according to the first embodiment can be omitted. The information input device 10 can thus be made even thinner.

### 11. Eleventh Embodiment

### [Configuration of Information Input Device]

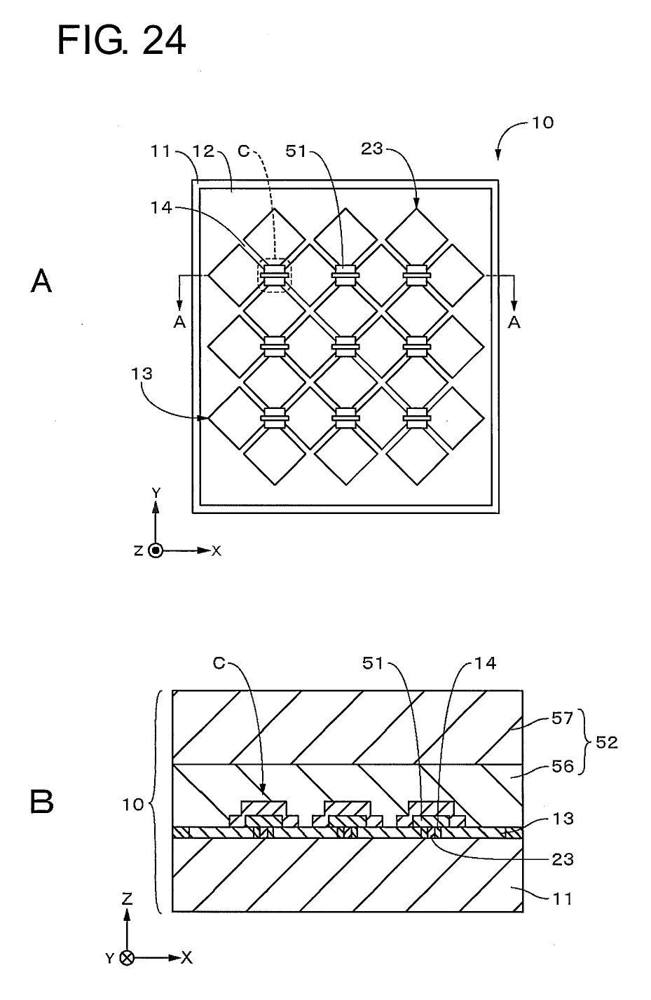

FIG. 24A is a plan view showing a configuration example of an information input device according to an eleventh embodiment of the present technique. FIG. 24B is a cross-sectional view taken along line A-A shown in FIG. 24A. The information input device 10 is a so-called projection type capacitive touch panel. As shown in FIGS. 24A and 24B, the information input device 10 includes a substrate 11, a plurality of transparent electrode portions 13 and transparent electrode portions 23, a transparent insulating portion 14, and a transparent insulating layer 51. The plurality of transparent electrode portions 13 and transparent electrode portions 23 are provided on the same surface of the substrate 11. The transparent insulating portion 14 is provided between the transparent electrode portions 13 and the transparent electrode portions 23 in in-plane directions of the substrate 11. The transparent insulating layer 51 is interposed in intersections of the transparent electrode portions 13 and the transparent electrode portions 23.

As shown in FIG. 24B, an optical layer 52 may be further provided, if needed, on the surface of the substrate 11 on which the transparent electrode portions 13 and the transparent electrode portions 23 are formed. In FIG. 24A, the illustration of the optical layer 52 is omitted. The optical layer 52 includes a bonding layer 56 and a base 57. The base 57 is bonded to the surface of the substrate 11 via the bonding layer 56. The information input device 10 is suitably applicable to the surface of a display device. For example, the substrate 11 and the optical layer 52 have transparency to visible light, with a refractive index n in the preferable range of 1.2 or more and 1.7 or less. In the following description, two directions orthogonal to each other within the plane of the surface of the information input device 10 will be referred to as an X-axis direction and a Y-axis direction. A direction perpendicular to the surface will be referred to as a Z-axis direction.

### (Transparent Electrode Portions)

The transparent electrode portions 13 are extended over the surface of the substrate 11 in the X-axis direction (first direction). The transparent electrode portions 23 are extended over the surface of the substrate 11 in the Y-axis direction (second direction). That is, the transparent electrode portions 13 and the transparent electrode portions 23 orthogonally intersect each other. The transparent insulating layer 51 for insulating both the electrodes is interposed in intersections C where the transparent electrode portions 13 and the transparent electrode portions 23 intersect. The transparent electrode portions 13 and the transparent electrode portions 23 are electrically connected with lead electrodes at one end each. The lead electrodes and a drive circuit are connected via an FPC (Flexible Printed Circuit).

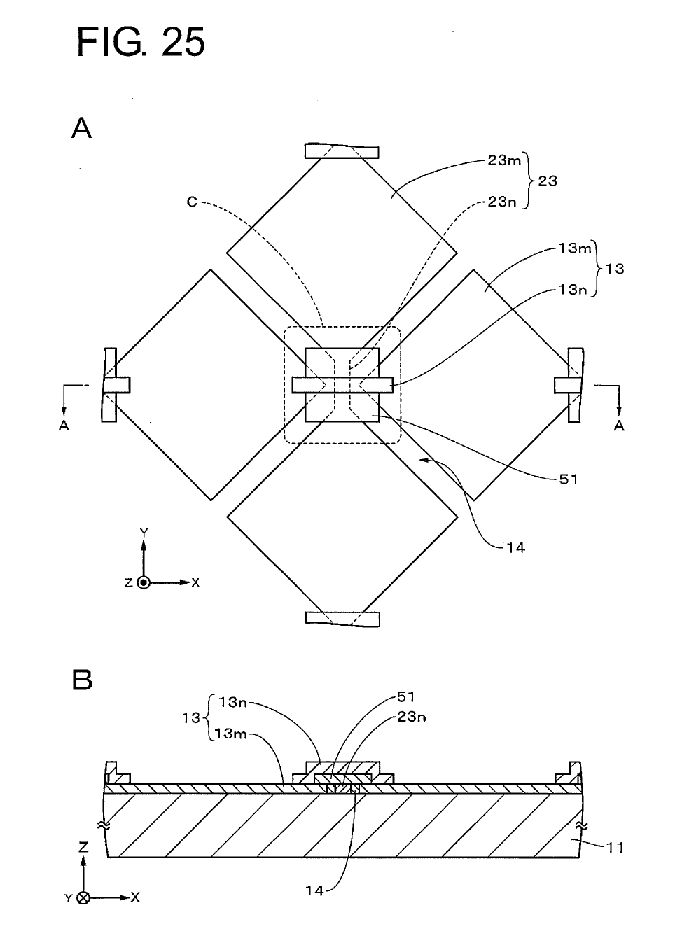

FIG. 25A is an enlarged plan view showing a vicinity of the intersection C shown in FIG. 24A. FIG. 25B is a cross-sectional view taken along line A-A shown in FIG. 25A. A transparent electrode portion 13 includes a plurality of pad portions (unit electrode bodies) 13m and a plurality of connecting portions 13n which connect the plurality of pad portions 13m to each other. The connecting portions 13n are extended in the X-axis direction and connect the ends of adjacent pad portions 13m to each other. A transparent electrode portion 23 includes a plurality of pad portions (unit electrode portions) 23m and a plurality of connecting portions 23n which connect the plurality of pad portions 23m to each other. The connecting portions 23n are extended in the Y-axis direction and connect the ends of adjacent pad portions 23m to each other.

In the intersection C, a connecting portion 23n, a transparent insulating layer 51, and a connecting portion 13n are stacked on the surface of the substrate 11 in such order. The connecting portion 13n is formed across and over the transparent insulating layer 51. One end of the connecting portion 13n over the transparent insulating layer 51 is electrically connected to either one of the adjacent pad portions 13m. The other end of the connecting portion 13n over the transparent insulating layer 51 is electrically connected to the other of the adjacent pad portions 13m.

While the pad portions 23m and the connecting portion 23n are integrally formed, the pad portions 13m and the connecting portion 13n are separately formed. For example, the pad portions 13m, the pad portions 23m, the connecting portion 23n, and the transparent insulating portion 14 are constituted by one transparent conductive layer 12 provided on the surface of the substrate 11. For example, the connecting portion 13n is made of a conductive layer.

For example, the pad portions 13m and the pad portions 23m may have, but are not limited to, a polygonal shape such as a rhombic shape (diamond shape) and a rectangular shape, a star shape, a cross shape, and the like.

For example, a metal layer or a transparent conductive layer may be used as the conductive layer constituting the connecting portion 13n. The metal layer contains metal as its main component. A highly-conductive metal is preferably used as the metal. Examples of such a material may include Ag, Al, Cu, Ti, Nb, and impurity-doped Si. Ag is preferable in terms of high conductivity, film formability, and printability. A highly-conductive metal is preferably used as the material of the metal layer to reduce the width, thickness, and length of the connecting portion 13n. This can improve visibility.

The connecting portion 13n and the connecting portion 23n may have a rectangular shape. The connecting portion 13n and the connecting portion 23n are not limited to a rectangular shape in particular, and may have any shape that can connect adjacent pad portions 13m and pad portions 23m to each other. Examples of the shape other than a rectangular shape may include linear, oval, triangular, and irregular shapes.

### (Transparent Insulating Layer)

The transparent insulating layer 51 preferably has an area greater than the crossing part of the connecting portion 13n and the connecting portion 23n. For example, the transparent insulating layer 51 has a size such as to cover the extremities of the pad portions 13m and the pad portions 23m positioned at the intersections C.

The transparent insulating layer 51 contains a transparent insulating material as its main component. A macromolecular material having transparency is preferably used as the transparent insulating material. Examples of such a material may include: (meth)acrylic resins such as poly(methyl methacrylate), and copolymers of methyl methacrylate with other alkyl(meth)acrylates and vinyl monomers such as styrene; polycarbonate resins such as polycarbonate and diethylene glycol bis(allyl carbonate) (CR-39); thermosetting (meth)acrylic resins such as homopolymers and copolymers of (brominated) bisphenol A type di(meth)acrylate, and polymer and copolymers of a urethane modified monomer of (brominated) bisphenol A mono(meth)acrylate; and polyesters, namely, polyethylene terephthalate, polyethylene naphthalate, and unsaturated polyester, acrylonitrile-styrene copolymers, polyvinyl chloride, polyurethane, epoxy resins, polyarylate, polyether sulfone, polyether ketone, cycloolefin polymers (product names: Arton and Zeonor), and cycloolefin copolymers. In view of heat resistance, aramid-based resins may be used. As employed herein, (meth)acrylate refers to acrylate or methacrylate.

The shape of the transparent insulating layer 51 is not limited in particular, and may be any shape as long as the transparent insulating layer 51 can be interposed between the transparent electrode portion 13 and the transparent electrode portion 23 at the intersection C and prevent electrical contact between the two electrodes. Examples thereof may include polygonal shapes such as a quadrangle shape, as well as elliptical and circular shapes. Examples of the quadrangle shape may include rectangular, square, rhombic, trapezoidal, and parallelogrammic shapes, and rectangles having a corner or corners rounded to a curvature R.

In other respects, the eleventh embodiment is the same as the first embodiment.

### [Effect]

In addition to the effects of the first embodiment, the eleventh embodiment can provide the following effect. That is, since the transparent electrode portions 13 and 23 are provided on one principal surface of the substrate 11, the substrate 21 (FIG. 1) according to the first embodiment can be omitted. As a result, the information input device 10 can be made even thinner.

### 12. Twelfth Embodiment

An electronic apparatus according to a twelfth embodiment includes any of the information input devices 10 according to the first to eleventh embodiments in its display unit. Examples of the electronic apparatus according to the twelfth embodiment of the present technique will be described below.

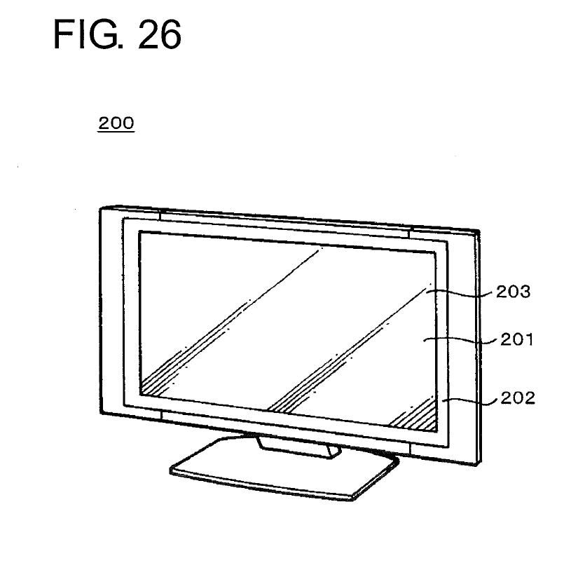

FIG. 26 is an appearance diagram showing an example of a television set 200 as the electronic apparatus. The television set 200 includes a display unit 201 including a front panel 202 and a filter glass 203. The display unit 201 further includes any of the information input devices 10 according to the first to eleventh embodiments.

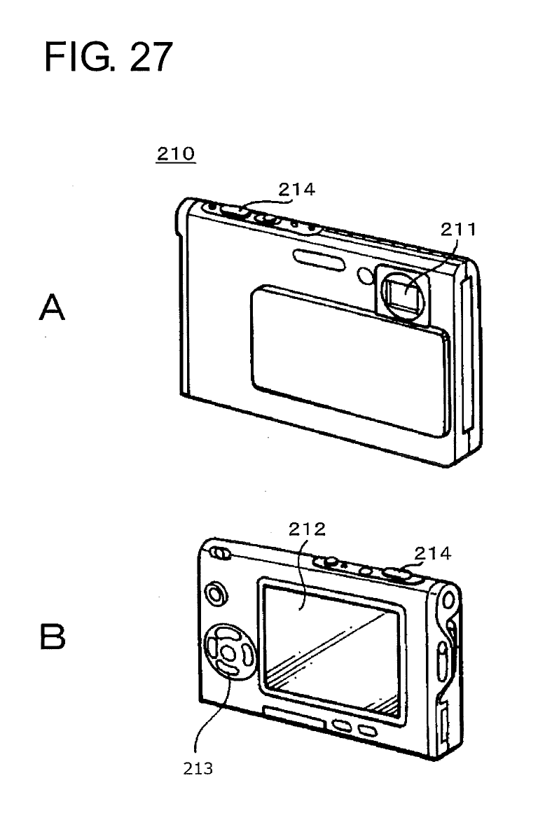

FIGS. 27A and 27B are appearance diagrams showing an example of a digital camera 210 as the electronic apparatus. FIG. 27A is an appearance diagram of the digital camera seen from the front side. FIG. 27B is an appearance diagram of the digital camera seen from the rear side. The digital camera 210 includes a light emitting unit 211 intended for a flash, a display unit 212, menu switches 213, and a shutter button 214. The display unit 212 includes any of the information input devices 10 according to the first to eleventh embodiments.

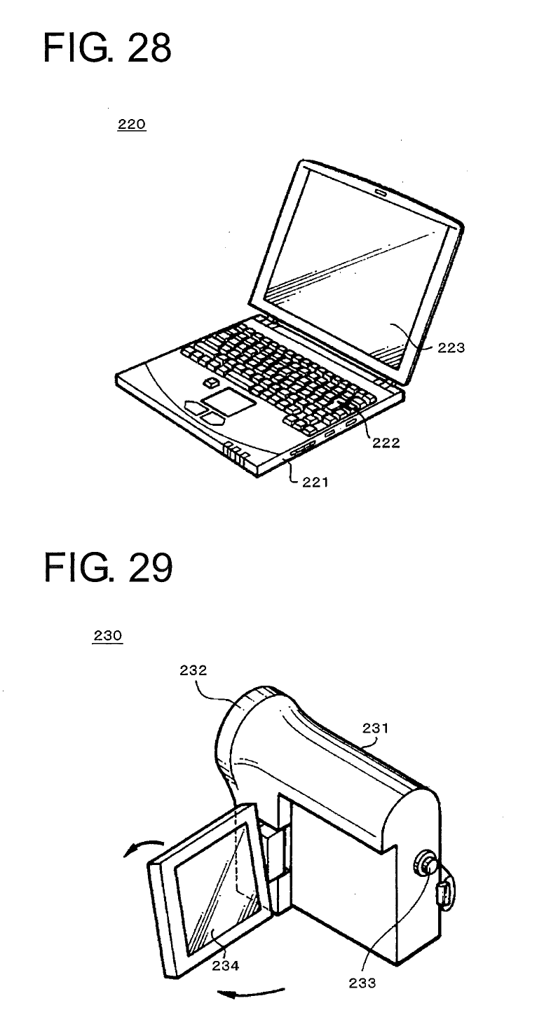

FIG. 28 is an appearance diagram showing an example of a notebook personal computer 220 as the electronic apparatus. The notebook personal computer 220 includes a main body 221, a keyboard 222 which is operated when inputting characters and the like, and a display unit 223 which displays an image. The display unit 223 includes any of the information input devices 10 according to the first to eleventh embodiments.

FIG. 29 is an appearance diagram showing an example of a video camera 230 as the electronic apparatus. The video camera 230 includes a main body unit 231, a lens 232 intended for object shooting on a side surface facing forward, a start/stop switch 233 for shooting, and a display unit 234. The display unit 234 includes any of the information input devices 10 according to the first to eleventh embodiments.

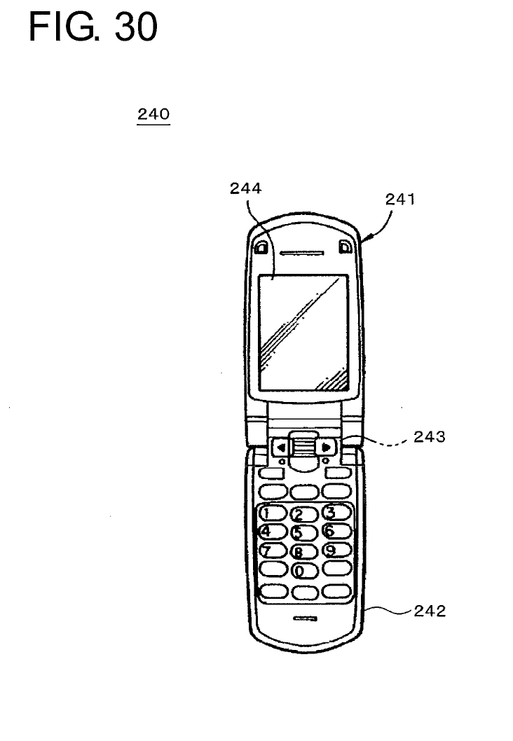

FIG. 30 is an appearance diagram showing an example of a portable terminal apparatus 240 as the electronic apparatus. For example, the portable terminal apparatus 240 is a mobile phone, and includes an upper casing 241, a lower casing 242, a coupling unit (here, hinge unit) 243, and a display unit 244. The display unit 244 includes any of the information input devices 10 according to the first to eleventh embodiments.

### [Effect]

Since the electronic apparatus according to the twelfth embodiment described above includes any of the information input devices 10 according to the first to eleventh embodiments, the visual recognition of the information input device 10 in the display unit can be suppressed.

### EXAMPLES

The present technique will be concretely described below by using examples, whereas the present technique is not limited to such examples. Referring to the drawings, the examples of the present technique will be described in the following order.

1. Examples 1 (examples where a laser light irradiation area was small)
2. Examples 2 (examples where the laser light irradiation area was large)
3. Examples 3 (examples where the number of shots of laser light was changed)
4. Examples 4 (examples where the energy density of the laser light was changed)
5. Examples 5 (examples where the number of shots or the energy density of the laser light was changed)
6. Examples 6 (examples where non-conducting portions were patterned)
7. Examples 7 (examples where nearest neighbor distance was a constant value)
8. Examples 8 (examples where the coverage ratio of conductive material was a constant value)
9. Comparative examples 8 (examples of machining by wet etching where the coverage ratio of the conductive material was a constant value)
10. Examples 9 (an example of speedup of laser patterning)

### 1. Examples 1

### Examples where Laser Light Irradiation Area was Small

### Examples 1-1 to 1-7

Initially, a transparent conductive layer including silver nanowires was formed on the surface of a 125-μm-thick PET sheet by an application method, whereby a transparent conductive sheet was obtained. Next, the transparent conductive sheet was measured for a sheet resistance by a four-terminal method. Loresta EP model MCP-T360 manufactured by Mitsubishi Chemical Analytech Co., Ltd., was used as the measurement apparatus. The resulting surface resistance was 200Ω/□.

Next, the transparent conductive layer of the transparent conductive sheet was patterned by the laser machining step (first laser machining step), using the laser machining apparatus shown in FIG. 7. Specifically, the transparent conductive layer of the transparent conductive sheet was irradiated with laser light via a mask (first mask) to form a laser light irradiation portion of square shape on the surface of the transparent conductive layer. The laser light irradiation portion was moved in the X-axis direction and the Y-axis direction.

A glass mask having a light-shielding layer on the glass surface, in which a plurality of hole portions having a dot shape (circular shape) were provided apart from each other in a random pattern, was used as the mask. The configuration of the mask and the machining magnification of the laser machining apparatus were adjusted so that the laser light irradiation area on the transparent conductive sheet, a maximum value of the diameters of the hole portions in the transparent conductive layer, a nearest neighbor distance between the hole portions of the transparent conductive layer, and the coverage ratio of the transparent conductive layer (transparent conductive material) had the values shown in Table 1. A UV laser (KrF excimer laser having a wavelength of 248 nm) was used as the laser. Four shots of laser light irradiation were performed in the same position. The laser light intensity was adjusted to 200 mJ/cm².

In such a manner, intended transparent conductive sheets were obtained.

### 2. Examples 2

### Examples where Laser Light Irradiation Area was Large

### Examples 2-1 to 2-6

Transparent conductive sheets were obtained in the same manner as in examples 1-1 to 1-7 except that the configuration of the mask and the machining magnification of the laser machining apparatus were adjusted so that the laser light irradiation area on the transparent conductive sheet, the maximum value of the diameters of the hole portions in the transparent conductive layer, the nearest neighbor distance between the hole portions of the transparent conductive layer, and the coverage ratio of the transparent conductive layer (transparent conductive material) had the values shown in Table 1.

### 3. Examples 3

### Examples where Number of Shots of Laser Light was Changed

### Examples 3-1 to 3-10

The configuration of the mask and the machining magnification of the laser machining apparatus were adjusted so that the laser light irradiation area on the transparent conductive sheet, the maximum value of the diameters of the hole portions in the transparent conductive layer, the nearest neighbor distance between the hole portions of the transparent conductive layer, and the coverage ratio of the transparent conductive layer (transparent conductive material) had the values shown in Table 1. The number of shots of the laser light in the same position was also changed sample by sample as shown in Table 1. In other respects, the transparent conductive sheets were obtained in the same manner as in examples 1-1 to 1-7.

### (Evaluation of Pattern Visibility)

The pattern visibility of dot shapes (hole portion shapes) and unit section shapes (grid shape) of the transparent conductive sheets obtained as described above was evaluated in the following manner. Initially, a transparent conductive sheet was bonded onto a 3.5-inch diagonal liquid crystal display via an adhesive sheet so that the surface of the transparent conductive sheet on the transparent conductive layer side was opposed to the screen. Next, an AR (Anti Reflect) film was bonded to the substrate (PET sheet) side of the transparent conductive sheet via an adhesive sheet. The liquid crystal display was then made to display black or green, and the display surface was visually observed to evaluate the pattern visibility of the dot shapes and unit section shapes. Table 1 shows the results.

Evaluation criteria of the pattern visibility of the dot shapes and unit section shapes are described below.

### <Visibility of Dot Shapes>

A: Dot shapes are invisible
B: Dot shapes are visible

### <Visibility of Unit Section Shapes>

A: Unit section shapes are invisible
B: Unit section shapes are visible

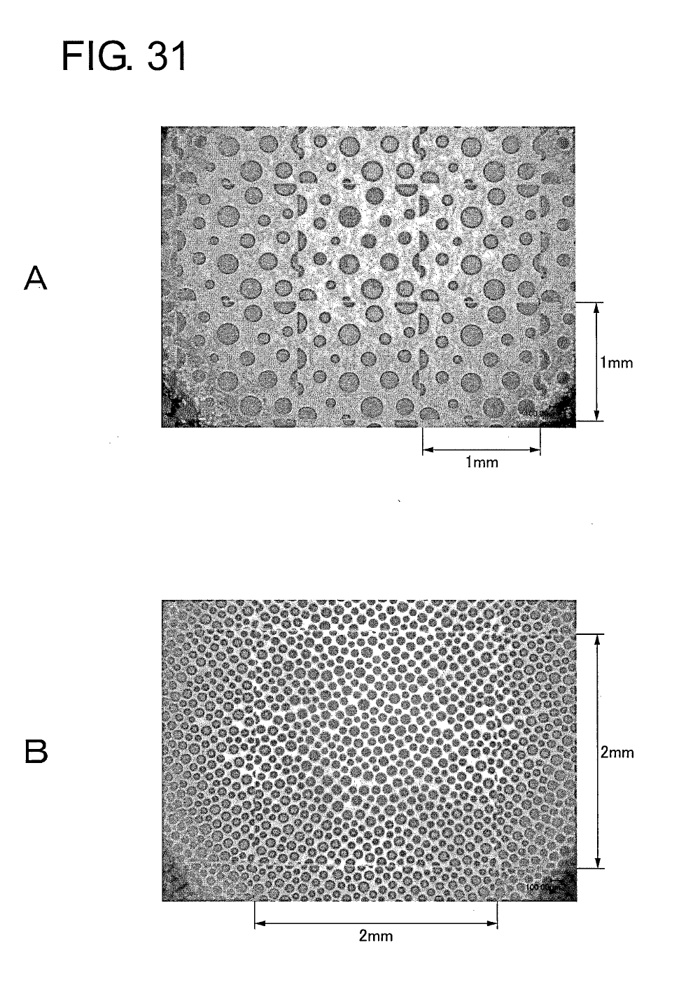

FIG. 31A shows the result of observation of the surface of the transparent conductive sheet according to example 1-5 under a microscope. FIG. 31B shows the result of observation of the surface of the transparent conductive sheet according to example 2-1 under a microscope.

TABLE 1

| | | | Laser Light | Dot Diameter | Nearest | | | | |
|---|---|---|---|---|---|---|---|---|---|
| | | | Irradiation | Maximum Value | Neighbor | Coverage Ratio | Laser Intensity | Pattern Visibility | |
| | Conductive | | Area | Dmax | Distance | of Conductive | (Number of | Dot | Grid |
| EXAMPLE | Material | Region | [mm] | [μm] | [μm] | Material [%] | Shots) [number] | Shape | Shape |
| EXAMPLE 1-1 | Ag nanowires | Conducting | 1 × 1 | 50 | 20 | 67 | 4 | A | B |
| EXAMPLE 1-2 | | Portion | | 46 | 26 | 76 | 4 | A | B |
| EXAMPLE 1-3 | | | | 30 | 28 | 86 | 4 | A | B |
| EXAMPLE 1-4 | | | | 190 | 105 | 74 | 4 | B | B |
| EXAMPLE 1-5 | | | | 269 | 95 | 65 | 4 | B | A |
| EXAMPLE 1-6 | | | | 245 | 85 | 60 | 4 | B | A |
| EXAMPLE 1-7 | | | | 316 | 70 | 50 | 4 | B | A |
| EXAMPLE 2-1 | Ag nanowires | Conducting | 2 × 2 | 108 | 20 | 50 | 4 | B | B |
| EXAMPLE 2-2 | | Portion | | 50 | 20 | 67 | 4 | A | B |
| EXAMPLE 2-3 | | | | 46 | 26 | 76 | 4 | A | B |
| EXAMPLE 2-4 | | | | 190 | 105 | 74 | 4 | B | B |
| EXAMPLE 2-5 | | | | 245 | 85 | 60 | 4 | B | B |
| EXAMPLE 2-6 | | | | 316 | 70 | 50 | 4 | B | B |
| EXAMPLE 3-1 | Ag nanowires | Conducting | 2 × 2 | 46 | 105 | 74 | 1 | A | A |
| EXAMPLE 3-2 | | Portion | | 46 | 105 | 74 | 2 | A | A |
| EXAMPLE 3-3 | | | | 46 | 105 | 74 | 4 | A | B |
| EXAMPLE 3-4 | | | | 46 | 105 | 74 | 6 | A | B |
| EXAMPLE 3-5 | | | | 46 | 105 | 74 | 10 | B | B |
| EXAMPLE 3-6 | | | | 316 | 70 | 50 | 1 | B | B |
| EXAMPLE 3-7 | | | | 316 | 70 | 50 | 2 | B | B |
| EXAMPLE 3-8 | | | | 316 | 70 | 50 | 4 | B | B |
| EXAMPLE 3-9 | | | | 316 | 70 | 50 | 6 | B | B |
| EXAMPLE 3-10 | | | | 316 | 70 | 50 | 10 | B | B |

Table 1 shows the following.

If the size of the dot shapes (hole portion shapes) formed in the transparent conductive layer is adjusted to 100 μm or less, the visual recognition of the dot shapes can be suppressed.

If the laser light intensity to irradiate the transparent conductive sheet is adjusted to 200 mJ/cm² or less, damage to the PET sheet serving as the substrate can be suppressed and the visual recognition of the unit section shapes can be suppressed.

### 4. Examples 4

### Examples where Energy Density of Laser Light was Changed

### Example 4-1

A transparent conductive sheet was obtained in the same manner as in example 1-1 except that the energy density of the laser light was changed to 80 mJ/cm².

### Example 4-2

A transparent conductive sheet was obtained in the same manner as in example 1-1 except that the energy density of the laser light was changed to 150 mJ/cm².

### Example 4-3

A transparent conductive sheet was obtained in the same manner as in example 1-1 except that the energy density of the laser light was changed to 220 mJ/cm².

### Example 4-4

A transparent conductive sheet was obtained in the same manner as in example 1-1 except that the energy density of the laser light was changed to 360 mJ/cm².

### Example 4-5

A transparent conductive sheet was obtained in the same manner as in example 1-1 except that the energy density of the laser light was changed to 420 mJ/cm².

### (Evaluation of Depth of Laser-Machined Portions)

Average depths of the laser-machined portions formed in the surfaces of the transparent conductive sheets by the laser machining were evaluated in the following manner. The distance between the top (outermost surface) and bottom (the bottom of the laser-machined portions) of each transparent conductive sheet was determined by a sectional profile measurement on a 3D image by using an optical microscope. Such a distance was regarded as an average depth of the laser-machined portions. The measurement magnification of the optical microscope was adjusted in the range of 10 to 1000 times. Table 2 shows the results.

### (Evaluation of Pattern Visibility)

The pattern visibility of the unit section shapes of the transparent conductive sheets obtained as describe above was evaluated in the same manner as in the foregoing examples 1-1 to 3-10. Table 2 shows the results.

Table 2 shows the evaluation results of the transparent conductive sheets according to examples 4-1 to 4-5.

TABLE 2

| | EXAM- | EXAM- | EXAM- | EXAM- | EXAM- |
|---|---|---|---|---|---|
| | PLE 4-1 | PLE 4-2 | PLE 4-3 | PLE 4-4 | PLE 4-5 |
| Energy Density | 80 | 150 | 220 | 360 | 420 |
| [mJ/cm²] | | | | | |
| Machining | 1 | 2 | 3 | 5 | 8 |
| Depth [μm] | | | | | |
| Visibility | A | A | A | B | B |

Table 2 shows the following.

If the energy density of the laser light is set to 220 mJ/cm² or less, the pattern visibility of the unit section shapes can be suppressed.

If the average depth of the grooves formed during the laser machining is adjusted to 0 nm or more and 3 μm or less, the pattern visibility of the unit section shapes can be suppressed.

### 5. Examples 5

### Examples where Number of Shots or Energy Density of Laser Light was Changed

### Examples 5-1 to 5-8

The configuration of the mask and the machining magnification of the laser machining apparatus were adjusted so that the laser light irradiation area on the transparent conductive sheet, a minimum value Dmin and a maximum value Dmax of the diameters of the hole portions (dots) in the transparent conductive layer, the nearest neighbor distance between the hole portions of the transparent conductive layer, and the coverage ratio of the transparent conductive layer (transparent conductive material) had the values shown in Table 3. The energy density of the laser light and the number of shots of the laser light in the same position were changed sample by sample as shown in Table 3. In other respects, the transparent conductive sheets were obtained in the same manner as in example 2-3. In examples 5-1 to 5-3, the energy density of the laser light was set to a constant value (200 [mJ/cm²]). In examples 5-4 to 5-8, the number of shots of the laser light was set to a constant value (one).

Table 3 shows the setting conditions of examples 5-1 to 5-8.

TABLE 3

| | | | | Dot Diameter [μm] | | Nearest | Coverage | Laser Light | |
|---|---|---|---|---|---|---|---|---|---|
| | | | Laser Light | Minimum | Maximum | Neighbor | Ratio of | Irradiation Condition | |
| | Conductive | | Irradiation Area | Value | Value | Distance | Conductive | Energy Density | Number of |
| EXAMPLE | Material | Region | [mm] | Dmin | Dmax | [μm] | Material [%] | [mJ/cm²] | Shots [number] |
| EXAMPLE 5-1 | Ag nanowires | Conducting | 2 × 2 | 16 | 46 | 26 | 76 | 200 | 1 |
| EXAMPLE 5-2 | | Portion | | | | | | | 4 |
| EXAMPLE 5-3 | | | | | | | | | 10 |
| EXAMPLE 5-4 | Ag nanowires | Conducting | 2 × 2 | 16 | 46 | 26 | 76 | 330 | 1 |
| EXAMPLE 5-5 | | Portion | | | | | | 200 | |
| EXAMPLE 5-6 | | | | | | | | 120 | |
| EXAMPLE 5-7 | | | | | | | | 64 | |
| EXAMPLE 5-8 | | | | | | | | 32 | |

- Examination of laser machining condition
* Machining area: 40 × 40 mm

### (Evaluation of Depth of Laser-Machined Portions)

Average depths d (hereinafter, referred to as machining depths d, if needed) of the laser-machined portions formed in the surfaces of the transparent conductive sheets by the laser machining were evaluated in the same manner as in the foregoing examples 4-1 to 4-5. In addition, the maximum values Dmax of the dot diameter were divided by the machining depths d to calculate values Dmax/d. Table 4 shows the results.

### (Evaluation of Pattern Visibility)

The pattern visibility of the dot shapes (hole portion shapes) and unit section shapes of the transparent conductive sheets obtained as described above was evaluated in the same manner as in the foregoing examples 1-1 to 3-10. Table 4 shows the results.

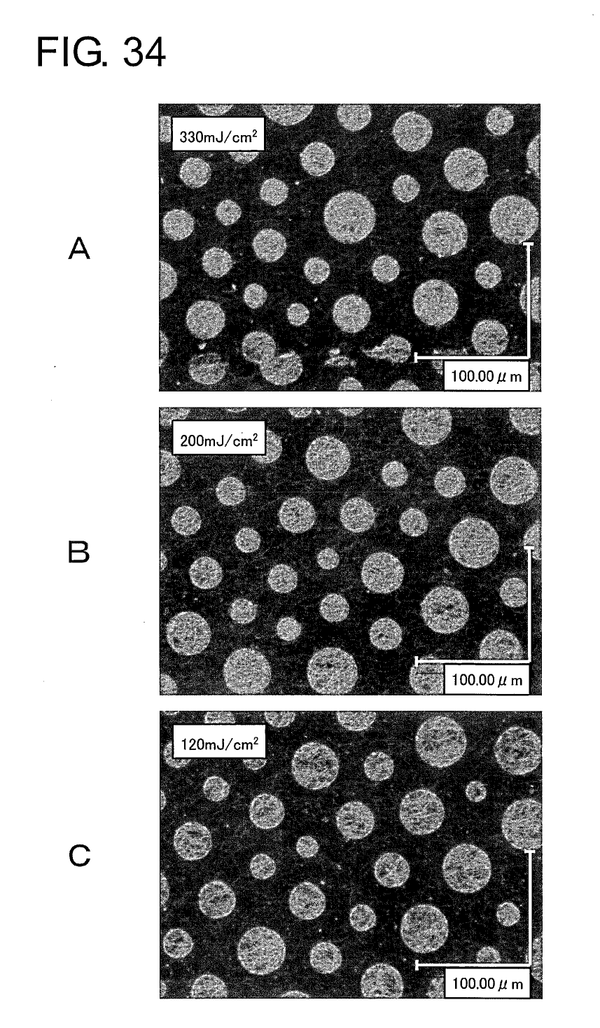

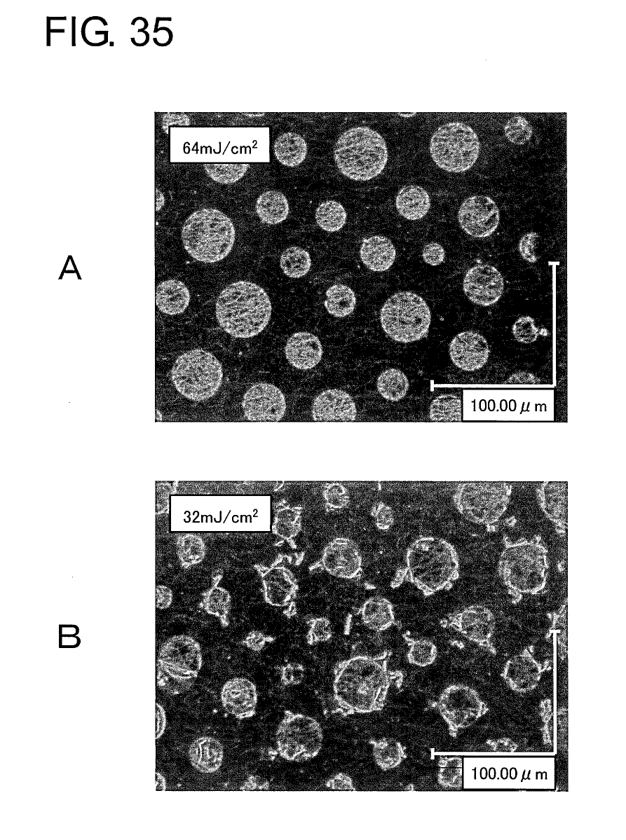

FIGS. 34A to 35B show the results of observation of the surfaces of the transparent conductive sheets according to examples 5-4 to 5-8 under a microscope, respectively.

### (Evaluation of Sheet Resistance)

The transparent conductive sheets obtained as described above were evaluated for the sheet resistance. Table 4 shows the results. In table 4, the values (Rb) in the “before machining” field are transparent conductive sheet resistance values [Ω/□] before machining. The values (Ra) in the “after machining” field are transparent conductive sheet resistance values [Ω/□] of the machined portions irradiated with the laser light (after machining). In Table 4, the values (Ra/Rb) in the “resistance ratio” field are resistance ratios [-] each calculated by (the sheet resistance value after machining)/(the sheet resistance value before machining).

Table 4 shows the evaluation results of examples 5-1 to 5-8.

TABLE 4

| | | Maximum Dot | Visible Pattern | | Sheet Resistance [Ω/□] | | | |
|---|---|---|---|---|---|---|---|---|
| | Machining Depth | Diameter Dmax/ | Dot | Grid | Before | After Machining | Resistance Ratio | |
| EXAMPLE | d [μm] | Machining Depth d | Shape | Shape | Machining Rb | Ra | Ra/Rb [—] | Remarks |
| EXAMPLE 5-1 | 3 | 15 | A | A | 113 | 237 | 2.1 | |
| EXAMPLE 5-2 | 12 | 4 | A | B | 117 | 260 | 2.2 | |
| EXAMPLE 5-3 | 26 | 2 | A | B | 115 | 261 | 2.3 | |
| EXAMPLE 5-4 | 9 | 5 | A | A | 108 | 234 | 2.2 | Sheet resistance |
| EXAMPLE 5-5 | 3 | 15 | A | A | 113 | 237 | 2.1 | varies greatly |
| EXAMPLE 5-6 | 2 | 23 | A | A | 109 | 216 | 2.0 | within plane. |
| EXAMPLE 5-7 | 2 | 23 | A | A | 109 | 201 | 1.8 | |
| EXAMPLE 5-8 | 2 | 23 | A | A | 105 | 180 | 1.7 | |

* A: Invisible, B: Visible
* Resistance Ratio (Ra/Rb) = Sheet resistance value (Ra) after machining/Sheet resistance value (Rb) before machining

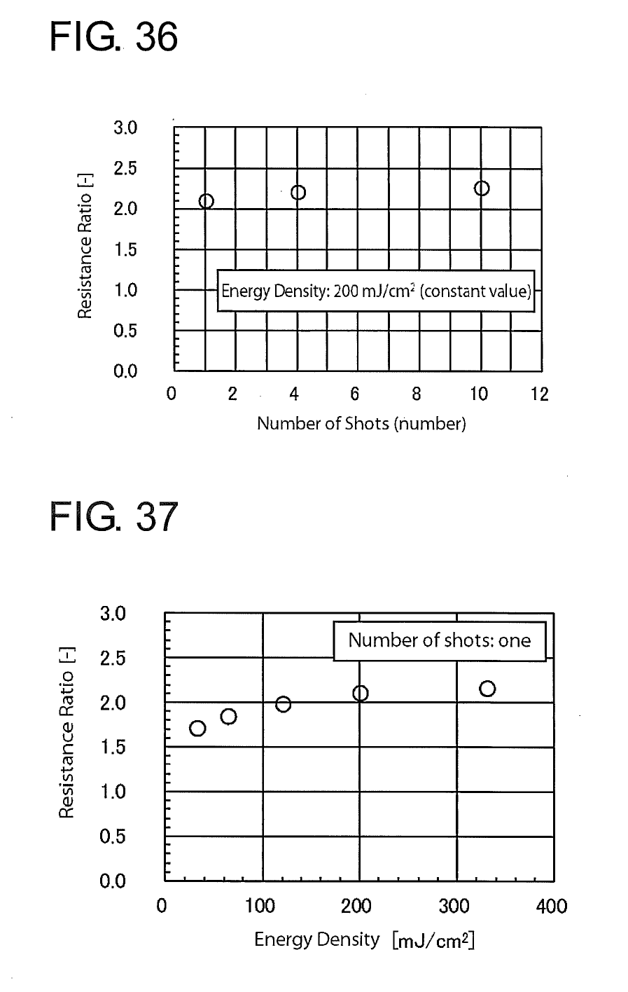

FIG. 36 shows the result of change of the resistance ratio [-] with respect to the number of shots [number] with an energy density of constant value (200 [mJ/cm²]). FIG. 37 shows the result of change of the resistance ratio [-] with respect to the energy density [mJ/cm²] with a constant number of shots (one).

Table 4 and FIGS. 34, 35, 36, and 37 show the following.

The pattern visibility varies depending on the laser light irradiation condition. More specifically, at an energy density of 200 [mJ/cm²], the pattern becomes visible as the number of shots increases. The number of shots is thus preferably smaller. The number of shots is preferably less than four. The number of shots is preferably one. This is also preferable in terms of the sheet machining speed. If the number of shots was one, energy densities in the range of 32 to 330 [mJ/cm²] provided favorable visibility (invisible). Machining depths d in the range of 2 to 9 [μm] provided favorable visibility. Visibility was favorable if the value Dmax/d obtained by dividing the maximum value Dmax of the dot diameter by the machining depth d was in the range of 5 to 23.

If the number of shots was one, the resistance ratio decreased when the amount of energy (energy density) was small. If the amount of energy was smaller than a threshold value, the shapes of the formed pattern elements varied within the plane of the sheet (see FIG. 35B). To avoid such variations and obtain a stable transparent conductive sheet, the machining is preferably performed under a laser light irradiation condition of 60 [mJ/cm²] or above. Note that such a condition also depends on the thickness of the transparent conductive layer including the silver nanowires applied to the surface of the sheet.

It should be noted that the amount of occurrence of machining traces (debris) increased as the amount of energy increased.

### 6. Examples 6

### Examples where Non-Conducting Portions were Patterned

### Examples 6-1 to 6-20

### Reverse Pattern (Non-Conducting Portions)

Next, the transparent insulating layer of a transparent conductive sheet was patterned by a laser machining step (second laser machining step), using the laser machining apparatus shown in FIG. 7. Specifically, the transparent conductive layer of the transparent conductive sheet was irradiated with laser light via a mask (second mask) to form a laser light irradiation portion of square shape on the surface of the transparent conductive layer. The laser light irradiation portion was moved in the X-axis direction and the Y-axis direction.

A glass mask having a glass surface on which a plurality of light-shielding portions having a dot shape (circular shape) were provided apart from each other in a random pattern was used as the mask. The configuration of the mask and the machining magnification of the laser machining apparatus were adjusted so that the laser light irradiation area on the transparent conductive sheet, the minimum value Dmin and the maximum value Dmax of the diameters of the light-shielding portions of the transparent conductive layer, the nearest neighbor distance between the light-shielding portions of the transparent conductive layer, and the coverage ratio of the transparent conductive layer (transparent conductive material) had the values shown in Table 5. A UV laser (KrF excimer laser having a wavelength of 248 nm) was used as the laser. In examples 6-1 to 6-7, one shot of irradiation was performed in the same position by using the laser light of which the energy density was adjusted to a constant value (64 [mJ/cm²]). In examples 6-8 to 6-10, four shots of irradiation were performed in the same position by using the laser light of which the energy density was adjusted to a constant value (200 [mJ/cm²]). In examples 6-11 to 6-15 and examples 6-16 to 6-20, one shot of irradiation was performed in the same position by using the laser light of which the energy density was adjusted to a constant value in the range of 330 [mJ/cm²] to 32 [mJ/cm²].

In such a manner, intended transparent conductive sheets were obtained.

Table 5 shows the setting conditions of examples 6-1 to 6-20.

TABLE 5

| | | | | | | | | Laser Light | |
|---|---|---|---|---|---|---|---|---|---|
| | | | | Dot Diameter [μm] | | Nearest | | Irradiation Condition | |
| | | | Laser Light | Minimum | Maximum | Neighbor | Coverage Ratio | Energy | Number |
| | Conductive | | Irradiation Area | Value | Value | Distance | of Conductive | Density | of Shots |
| EXAMPLE | Material | Region | [mm] | Dmin | Dmax | [μm ] | Material [%] | [mJ/cm²] | [number] |
| EXAMPLE 6-1 | Ag nanowires | Non-Conducting | 2 × 2 | 50 | 92 | 20 | 50 | 64 | 1 |
| EXAMPLE 6-2 | | Portion | | 20 | 50 | 20 | 67 | | |
| EXAMPLE 6-3 | | | | 16 | 46 | 26 | 76 | | |
| EXAMPLE 6-4 | | | | 70 | 190 | 105 | 74 | | |
| EXAMPLE 6-5 | | | | 87 | 269 | 95 | 65 | | |
| EXAMPLE 6-6 | | | | 155 | 245 | 85 | 60 | | |
| EXAMPLE 6-7 | | | | 190 | 316 | 70 | 50 | | |
| EXAMPLE 6-8 | Ag nanowires | Non-Conducting | 2 × 2 | 70 | 190 | 105 | 74 | 200 | 4 |
| EXAMPLE 6-9 | | Portion | | 155 | 245 | 85 | 60 | | |
| EXAMPLE 6-10 | | | | 190 | 316 | 70 | 50 | | |
| EXAMPLE 6-11 | Ag nanowires | Non-Conducting | 2 × 2 | 70 | 190 | 105 | 74 | 330 | 1 |
| EXAMPLE 6-12 | | Portion | | | | | | 200 | |
| EXAMPLE 6-13 | | | | | | | | 120 | |
| EXAMPLE 6-14 | | | | | | | | 64 | |
| EXAMPLE 6-15 | | | | | | | | 32 | |
| EXAMPLE 6-16 | Ag nanowires | Non-Conducting | 2 × 2 | 155 | 245 | 85 | 60 | 330 | 1 |
| EXAMPLE 6-17 | | Portion | | | | | | 200 | |
| EXAMPLE 6-18 | | | | | | | | 120 | |
| EXAMPLE 6-19 | | | | | | | | 64 | |
| EXAMPLE 6-20 | | | | | | | | 32 | |

- Reverse pattern (non-conducting portion)
* Machining area: 40 × 40 mm

### (Evaluation of Depth of Laser-Machined Portions)

Average depths d of the laser-machined portions formed in the surfaces of the transparent conductive sheets by the laser machining were evaluated in the same manner as in the foregoing examples 5. In addition, the maximum values Dmax of the dot diameter were divided by the machining depths d to calculate values Dmax/d. Table 6 shows the results.

### (Evaluation of Pattern Visibility)

The pattern visibility of the dot shapes (hole portion shapes) and unit section shapes of the transparent conductive sheets obtained as described above were evaluated in the same manner as in the foregoing examples 5. Table 6 shows the results.

Table 6 shows the evaluation results of examples 6-1 to 6-20.

TABLE 6

| | | Maximum Dot | | |
|---|---|---|---|---|
| | Machining | Diameter Dmax/ | Visible Pattern | |
| | Depth d | Machining | Dot | Grid |
| EXAMPLE | [μm] | Depth d | Shape | Shape |
| EXAMPLE 6-1 | 3 | 31 | A | A |
| EXAMPLE 6-2 | 3 | 17 | A | A |
| EXAMPLE 6-3 | 3 | 15 | A | A |
| EXAMPLE 6-4 | 3 | 63 | A | A |
| EXAMPLE 6-5 | 3 | 90 | A | A |
| EXAMPLE 6-6 | 3 | 82 | A | A |
| EXAMPLE 6-7 | 3 | 105 | B | A |
| EXAMPLE 6-8 | 12 | 16 | A | A |
| EXAMPLE 6-9 | 12 | 20 | B | A |
| EXAMPLE 6-10 | 12 | 26 | B | A |
| EXAMPLE 6-11 | 10 | 19 | A | A |
| EXAMPLE 6-12 | 3 | 63 | A | A |
| EXAMPLE 6-13 | 2 | 95 | A | A |
| EXAMPLE 6-14 | 2 | 95 | A | A |
| EXAMPLE 6-15 | 1 | 190 | A | A |
| EXAMPLE 6-16 | 11 | 22 | B | A |
| EXAMPLE 6-17 | 3 | 82 | B | A |
| EXAMPLE 6-18 | 2 | 123 | B | A |
| EXAMPLE 6-19 | 2 | 123 | B | A |
| EXAMPLE 6-20 | 2 | 123 | B | A |

* A: invisible, B: visible

Table 6 shows the following.

The visibility of the non-conducting portions varies depending on the laser light irradiation condition. The maximum value Dmax of the dot diameter appropriate for the dot shapes to be invisible depends on the machining depth d.

For example, the results of examples 6-1 to 6-7 show that dot diameters of 300 [μm] or less are preferable for the case with an energy density of 64 [mJ/cm²], one shot, and a machining depth d of 3 [μm]. The results of examples 6-8 to 6-10 show that dot diameters of 200 [μm] or less are preferable for the case with an energy density of 200 [mJ/cm²], four shots, and a machining depth d of 12 [μm].

From the viewpoint of dot diameters, machining depths d of 1 to 12 [μm] are preferable for maximum values Dmax of 200 [μm] or less. Machining depths d of 1 [μm] or more and 3 [μm] or less are more preferred.

If the maximum value Dmax of the dot diameter is 245 [μm] or more, the dot shapes can be visible even with a machining depth d of 2 [μm].

If the machining depth d is in the range of 1 [μm] or more and 10 [μm] or less, the value Dmax/d obtained by dividing the maximum value Dmax of the dot diameter by the machining depth d is preferably 80 or less. If the machining depth d is in the range of 1 [μm] or more and 12 [μm] or less, the value Dmax/d obtained by dividing the maximum value Dmax of the dot diameter by the machining depth d is preferably 19 or less.

### 7. Examples 7

### Examples where Nearest Neighbor Distance was Constant Value

### Examples 7-1 to 7-3

The configuration of the mask and the machining magnification of the laser machining apparatus were adjusted so that the nearest neighbor distance between the hole portions of the transparent conductive layer had a constant value (10 [μm]), and the laser light irradiation area on the transparent conductive sheet, the minimum value Dmin and the maximum value Dmax of the diameters of the hole portions in the transparent conductive layer, and the coverage ratio of the transparent conductive layer (transparent conductive material) had the values shown in Table 7. The number of shots of the laser light in the same position was set to one, and the energy density of the laser light was set to 64 [mJ/cm²].

In other respects, transparent conductive sheets were obtained in the same manner as in examples 5.

Table 7 shows the setting conditions of examples 7-1 to 7-3.

TABLE 7

| | | | | Dot Diameter | | | | Laser Light | |
|---|---|---|---|---|---|---|---|---|---|
| | | | Laser Light | [μm] | | Nearest | | Irradiation Condition | |
| | | | Irradiation | Minimum | | Neighbor | Coverage Ratio | | Number of |
| | Conductive | | Area | Value | Maximum Value | Distance | of Conductive | Energy Density | Shots |
| EXAMPLE | Material | Region | [mm] | Dmin | Dmax | [μm] | Material [%] | [mJ/cm²] | [number] |
| EXAMPLE 7-1 | Ag nanowires | Conducting | 2 × 2 | 10 | 38 | 10 | 65 | 64 | 1 |
| EXAMPLE 7-2 | | Portion | | 5 | 20 | | 75 | | |
| EXAMPLE 7-3 | | | | 5 | 10 | | 85 | | |

- Nearest neighbor distance: constant value 10 [μm]
* Machining area: 40 × 40 mm

### (Evaluation of Depth of Laser-Machined Portions)

Average depths d of the laser-machined portions formed in the surfaces of the transparent conductive sheets by the laser machining were evaluated in the same manner as in the foregoing examples 6. In addition, the maximum values Dmax of the dot diameter were divided by the machining depths d to calculate values Dmax/d. Table 8 shows the results.

### (Evaluation of Pattern Visibility)

The pattern visibility of the dot shapes (hole portion shapes) and unit section shapes of the transparent conductive sheets obtained as described above were evaluated in the same manner as in the foregoing examples 1-1 to 3-10. Table 8 shows the results.

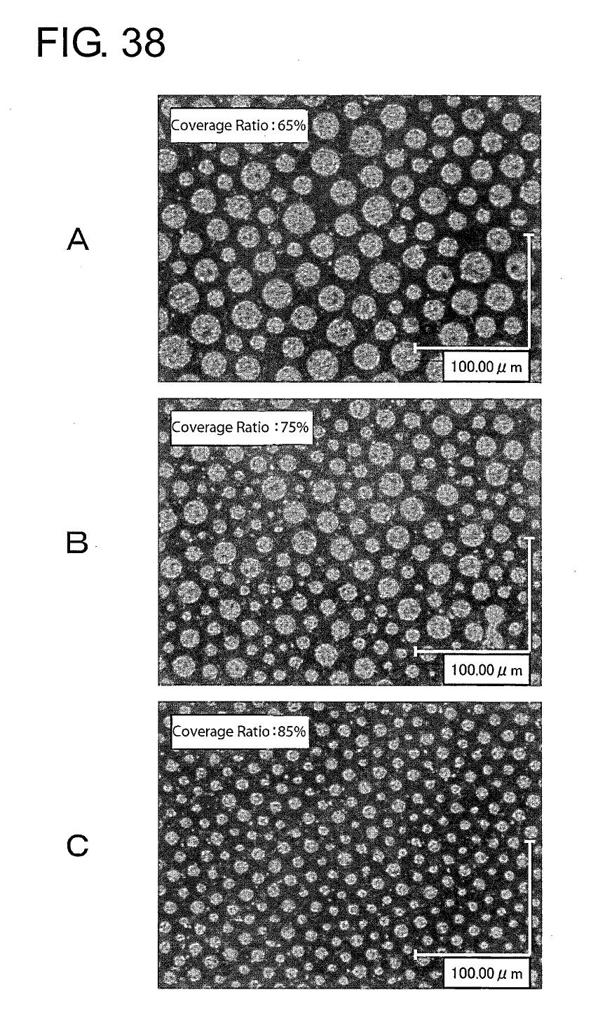

FIGS. 38A to 38C show the results of observation of the surfaces of the transparent conductive sheets according to examples 7-1 to 7-3 under a microscope, respectively.

### (Evaluation of Sheet Resistance)

The transparent conductive sheets obtained as described above were evaluated for the sheet resistance. Table 8 shows the results. The items in the respective fields of Table 8 are the same as those of examples 5.

Table 8 shows the evaluation results of examples 7-1 to 7-3.

TABLE 8

| | | Maximum Dot | | | Sheet Resistance [Ω/□] | | |
|---|---|---|---|---|---|---|---|
| | Machining Depth | Diameter Dmax/ | Visible Pattern | | Before | After Machining | Resistance Ratio |
| EXAMPLE | d [μm] | Machining Depth d | Dot Shape | Grid Shape | Machining Rb | Ra | Ra/Rb [—] |
| EXAMPLE 7-1 | 2 | 19 | A | A | 111 | 503 | 4.5 |
| EXAMPLE 7-2 | 2 | 10 | A | A | 112 | 359 | 3.2 |
| EXAMPLE 7-3 | 2 | 5 | A | A | 112 | 244 | 2.2 |

* A: Invisible, B: Visible
* Resistance Ratio (Ra/Rb) = Sheet resistance value (Ra) after machining/Sheet resistance value (Rb) before machining

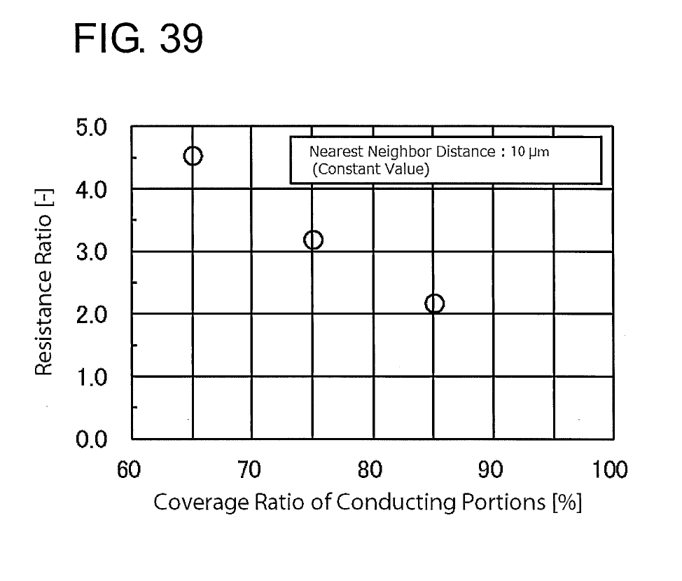

FIG. 39 shows the result of change of the resistance ratio [-] with respect to the coverage ratio [%] of the conductive material (conducting portions) when the nearest neighbor distance between the hole portions of the transparent conductive layer was set to the constant value (10 [μm]).

Table 8 and FIGS. 38 and 39 show the following.

Conventionally, the minimum resolution of wet etching processing has been 30 [μm]. In contrast, according to the present technique, the laser machining enables production of sheets with conducting portions having a nearest neighbor distance of 10 [μm]. Conducting portions having a nearest neighbor distance of 10 [μm] can thus be evaluated for the sheet resistance. An evaluation of the sheets with the conducting portions having a nearest neighbor distance of 10 [μm] provided the following findings.

With the nearest neighbor distance of 10 [μm], the sheet resistance varied more greatly with respect to a change in the coverage ratio of the conducting portions than with transparent conductive sheets of 30 [μm].

From the viewpoint of the resistance ratio, the coverage ratio of the conducting portions is preferably 85 [%] or higher.

In view of improving non-visibility, the maximum value Dmax of the dot diameter is preferably 40 [μm] or less. The maximum value Dmax of the dot diameter is preferably 10 [μm] or more and 38 [μm] or less. The value Dmax/d obtained by dividing the maximum value Dmax of the dot diameter by the machining depth d is preferably in the range of 5 or more and 19 or less.

### 8. Examples 8

### Examples where Coverage Ratio of Conductive Material was Constant Value

### Examples 8-1 to 8-4

The configuration of the mask and the machining magnification of the laser machining apparatus were adjusted so that the coverage ratio of the transparent conductive layer (transparent conductive material) had a constant value (80 [%]), and the laser light irradiation area on the transparent conductive sheet, the minimum value Dmin and the maximum value Dmax of the diameters of the hole portions in the transparent conductive layer, and the nearest neighbor distance between the hole portions of the transparent conductive layer had the values shown in Table 9. The energy density of the laser light was 64 [mJ/cm²]. The number of shots of the laser light in the same position was one. In other respects, transparent conductive sheets were obtained in the same manner as in examples 5.

Table 9 shows the setting conditions of examples 8-1 to 8-4.

TABLE 9

| | | | | | | | | Laser Light | |
|---|---|---|---|---|---|---|---|---|---|
| | | | | Dot Diameter [μm] | | Nearest | | Irradiation Condition | |
| | | | Laser Light | Minimum | Maximum | Neighbor | Coverage Ratio | Energy | |
| | Conductive | | Irradiation Area | Value | Value | Distance | of Conductive | Density | Number of Shots |
| EXAMPLE | Material | Region | [mm] | Dmin | Dmax | [μm] | Material [%] | [mJ/cm²] | [number] |
| EXAMPLE 8-1 | Ag nanowires | Conducting | 2 × 2 | 76 | 100 | 90 | 80 | 64 | 1 |
| EXAMPLE 8-2 | | Portion | | 40 | 95 | 70 | | | |
| EXAMPLE 8-3 | | | | 30 | 67 | 50 | | | |
| EXAMPLE 8-4 | | | | 10 | 48 | 30 | | | |

- Coverage ratio of conductive material: constant value 80 [%]
* Machining area: 40 × 40 mm

### 9. Comparative Examples 8

### Examples of Processing by Wet Etching where Coverage Ratio of Conductive Material was Constant Value

### Comparative Examples 8-1 to 8-4

Various conditions of transparent conductive layers (transparent conductive material) processed by wet etching are described below. XCF-468B manufactured by DIC Corporation was used as the film. Masks were configured so that the coverage ratio of conductive portions of the transparent conductive layer (transparent conductive material) was 80 [%] and the nearest neighbor distance between the hole portions of the transparent conductive layer had the values shown in Table 11. A mixed acid Al etchant (pH: 1.0, viscosity: 1.5 [mPa·s]) was used with an etching condition of 50 [° C.] for five minutes.

### (Evaluation of Depth of Laser-Machined Portions)

In examples 8-1 to 8-4, the depths d of the laser-machined portions formed in the surfaces of the transparent conductive sheets by the laser machining were evaluated in the same manner as in the foregoing examples 7. In addition, the maximum values Dmax of the dot diameter were divided by the machining depths d to calculate values Dmax/d. Table 10 shows the results.

### (Evaluation of Pattern Visibility)

The pattern visibility of the dot shapes (hole portion shapes) and unit section shapes of the transparent conductive sheets of examples 8-1 to 8-4 obtained as described above were evaluated in the same manner as in the foregoing examples 1-1 to 3-10. Table 10 shows the results.

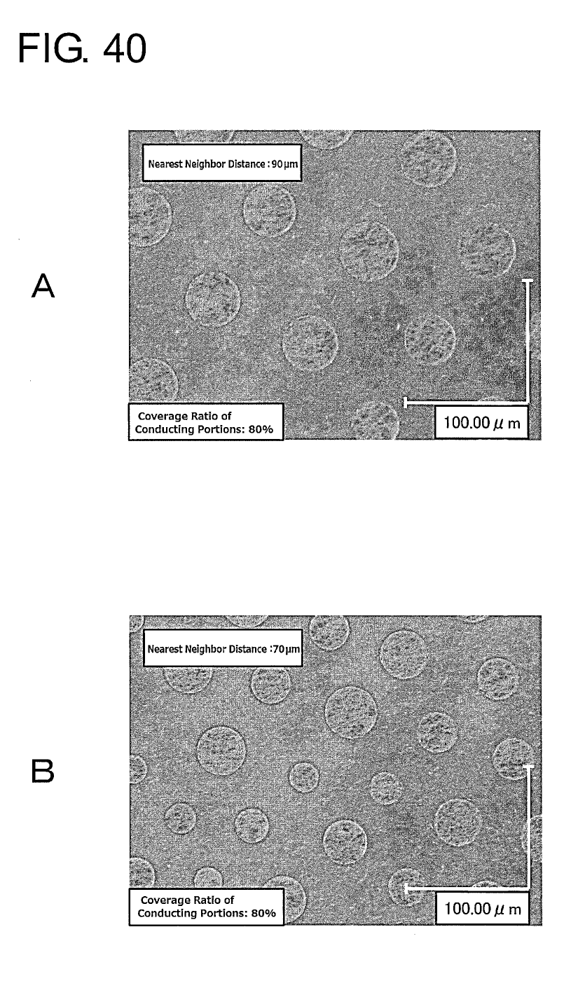

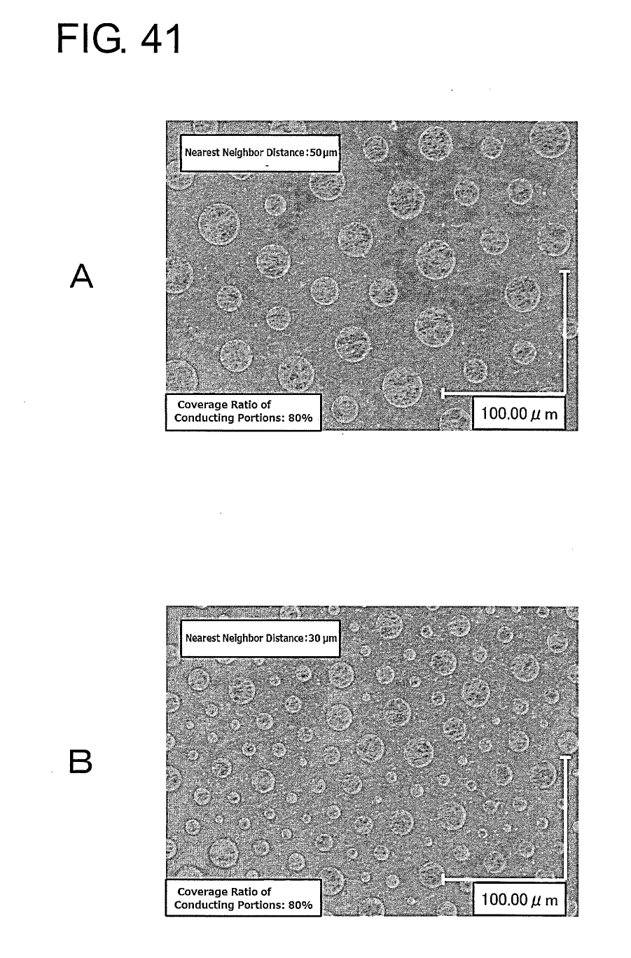

FIGS. 40A to 41B show the results of observation of the surfaces of the transparent conductive sheets according to examples 8-1 to 8-4 under a microscope, respectively.

### (Evaluation of Sheet Resistance)

The transparent conductive sheets obtained as described above were evaluated for the sheet resistance. Table 10 shows the results. The items in the respective fields of Table 10 are the same as those of examples 5 and 7.

Table 10 shows the evaluation results of examples 8-1 to 8-4.

TABLE 10

| | | Maximum Dot | | | Sheet Resistance [Ω/□] | | |
|---|---|---|---|---|---|---|---|
| | Machining Depth | Diameter Dmax/ | Visible Pattern | | Before | After Machining | Resistance Ratio |
| EXAMPLE | d [μm] | Machining Depth d | Dot Shape | Grid Shape | Machining Rb | Ra | Ra/Rb [—] |
| EXAMPLE 8-1 | 2 | 50 | A | A | 112 | 151 | 1.6 |
| EXAMPLE 8-2 | 2 | 48 | A | A | 115 | 171 | 1.6 |
| EXAMPLE 8-3 | 2 | 34 | A | A | 110 | 183 | 1.7 |
| EXAMPLE 8-4 | 2 | 24 | A | A | 108 | 201 | 1.9 |

* A: Invisible, B: Visible
* Resistance Ratio (Ra/Rb) = Sheet resistance value (Ra) after machining/Sheet resistance value (Rb) before machining

FIG. 42 shows the result of change of the resistance ratio [-] with respect to the nearest neighbor distance [μm] between the hole portions of the transparent conductive layer when the coverage ratio of the transparent conductive layer (transparent conductive material) was set to the constant value (80 [%]).

Table 10 and FIGS. 40, 41, and 42 show the following.

From the viewpoint of improving non-visibility, the maximum value Dmax of the dot diameter is preferably 48 [μm] or more and 100 [μm] or less. The value Dmax/d obtained by dividing the maximum value Dmax of the dot diameter by the machining depth d is preferably in the range of 24 or more and 50 or less.

If the coverage ratio of the transparent conductive layer (transparent conductive material) was set to a constant value (80 [%]), the resistance ratio tended to increase as the nearest neighbor distance between the hole portions of the transparent conductive layer decreased.

### (Comparison of Machining Processes)

To verify whether the tendency of the resistance ratio to increase with the decreasing nearest neighbor distance is unique to the laser machining, a comparison was made with transparent conductive layers (transparent conductive material) processed by wet etching. The comparison was made between [1] the transparent conductive layers (transparent conductive material) obtained by the wet etching machining process (comparative examples 8-1 to 8-4) and [2] the transparent conductive layers (transparent conductive material) obtained by the laser ablation (surface machining by laser light irradiation) (examples 8-1 to 8-4). The samples used in the wet etching processing had a sheet resistance value (sheet resistance value before machining: corresponding to the value (Rb) in the “before machining” field in examples 5, 7, and 8) of 87.5 [Ω/□]. Using this value, the resistance ratios Ra/Rb [-] of the transparent conductive layers (transparent conductive material) processed by the wet etching were calculated.

### (Evaluation of Sheet Resistance)

The transparent conductive sheets obtained as described above by the machining processes of [1] wet etching and [2] laser ablation were evaluated for the sheet resistance. Table 11 shows the results.

Table 11 shows the evaluation results of comparative examples 8-1 to 8-4 and examples 8-1 to 8-4.

TABLE 11

| | | |
|---|---|---|
| | Sheet | Resistance |
| Nearest Neighbor | Resistance [Ω/□] | Ratio [—] |

| Distance [μm] | [1] | [2] | [1] | [2] |
|---|---|---|---|---|
| 90 | 158 | 151 | 1.8 | 1.7 |
| 70 | 168 | 171 | 1.9 | 2.0 |
| 50 | 187 | 183 | 2.1 | 2.1 |
| 30 | 258 | 201 | 2.9 | 2.3 |

Comparison of resistance ratios obtained by different machining processes
Film: XCF-468B manufactured by DIC Corporation
Masks: with different nearest neighbor distances
Coverage ratio of conducting portions: 80%
Process: [1] wet etching (comparative examples 8-1 to 8-4)
[2] laser ablation (examples 8-1 to 8-4)
Etchant: mixed acid Al (pH: 1.0, viscosity: 1.5 [mPa · s])
Etching condition: 50° C., five minutes
[1] Sheet resistance (Rb) before wet etching processing [Ω/□]: 87.5

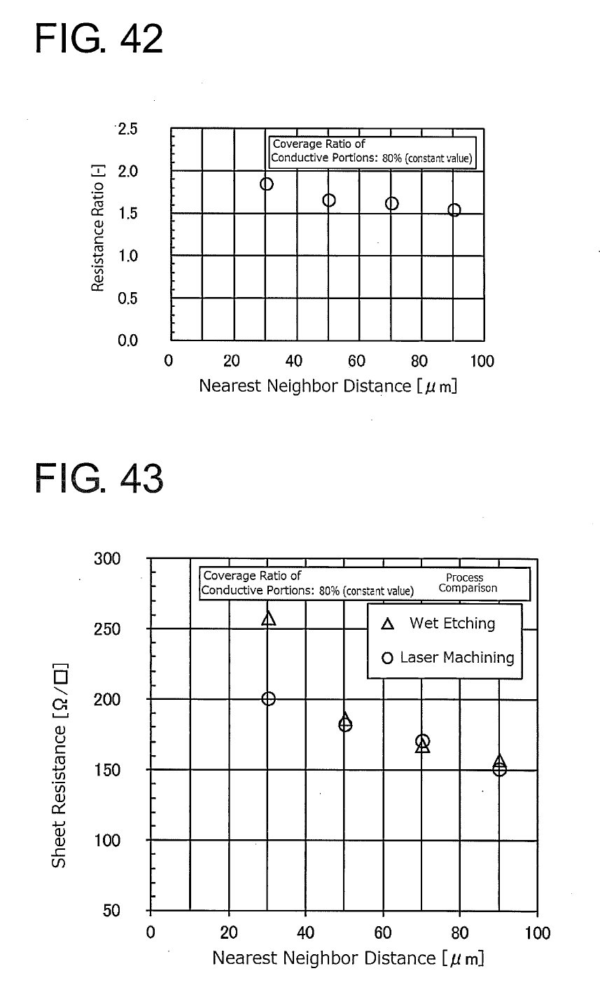

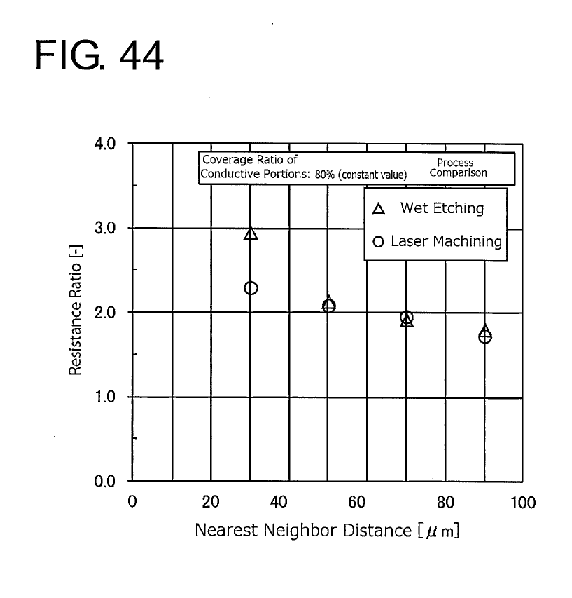

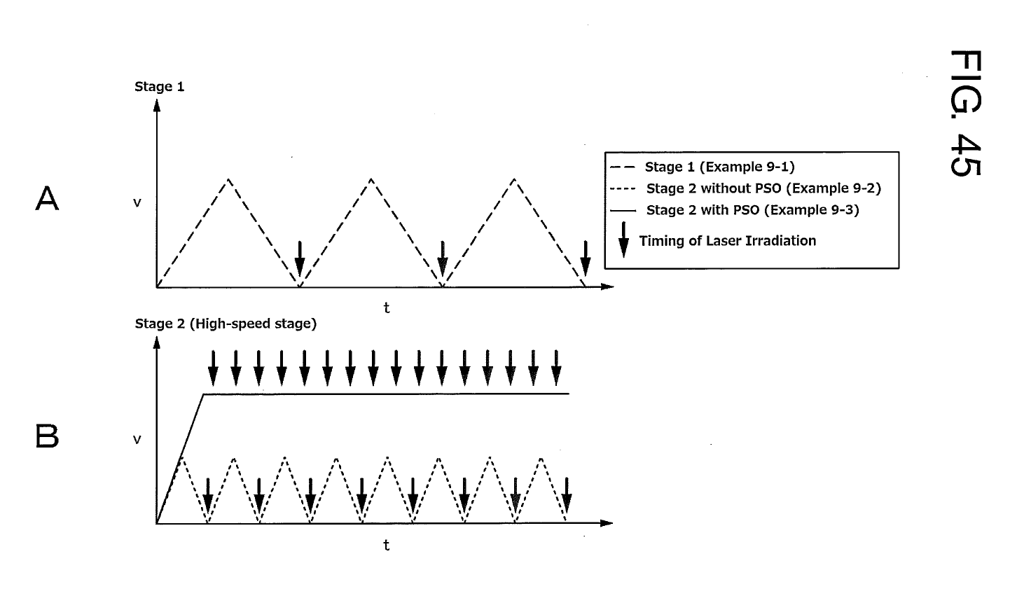

FIG. 43 shows the results of change of the sheet resistance [Ω/□] with respect to the nearest neighbor distance [μm] between the hole portions of the transparent conductive layer when the coverage ratio of the transparent conductive layer (transparent conductive material) was set to the constant value (80 [%]), concerning the machining processes of [1] wet etching and [2] laser ablation. FIG. 44 shows the results of change of the resistance ratio [-] with respect to the nearest neighbor distance [μm] between the hole portions of the transparent conductive layer when the coverage ratio of the transparent conductive layer (transparent conductive material) was set to the constant value (80 [%]), concerning the machining processes of [1] wet etching and [2] laser ablation. In FIGS. 43 and 44, the values of [1] wet etching are indicated by triangles, and the values of [2] laser ablation are indicated by circles.

Table 11 and FIGS. 43 and 44 show the following.

If the nearest neighbor distance between the hole portions of the transparent conductive layer was small, the resistance ratio Ra/Rb of the transparent conductive layer (transparent conductive material) obtained by the wet etching processing increased as compared to by the laser machining. From the viewpoint of the resistance ratio Ra/Rb, the laser machining is therefore preferable if the nearest neighbor distance between the hole portions of the transparent conductive layer is small. A possible reason for the increase of the resistance ratio Ra/Rb of the transparent conductive layer by the wet etching processing is side etching caused by the wet etching processing. It was found that to suppress an increase in the sheet resistance of the transparent conductive layer during wet etching, the machining process needs to be improved to suppress side etching etc.

Narrow pitches (for example, up to 10 [μm]) are difficult to machine by the wet etching process. In contrast, the laser machining process can stably produce a transparent conductive layer having narrow pitches (for example, up to 10 [μm]). The laser machining process also precludes unnecessary parameters due to side etching etc. The laser machining is thus effective for the verification of the principle of the pattern.

### Examples 9

### Examples of Speedup of Laser Patterning

### Example 9-1

FIG. 45A schematically shows a relationship between the laser machining speed of a typical stage (hereinafter, referred to as a stage 1, if needed) and the moving speed of the stage. In FIG. 45A, the horizontal axis indicates time t, and the vertical axis the moving speed v of the stage. Downward arrows in FIG. 45A indicate the timing of laser light irradiation.

As shown in FIG. 45A, the stage initially increases its moving speed to move to the next irradiation position of the laser light. The stage reaches the maximum speed and then reduces its speed as the stage approaches the irradiation position of the laser light. Reaching the irradiation position of the laser light, the stage stops.

When the stage stops, irradiation with the laser light is performed. Such a series of operations is repeated to perform laser patterning. For example, if the irradiation area of one shot of the laser light was 2×2 [mm²] and the machining area was 40×40 [mm²], the tact time of the stage 1 was 900 [s] (15 [min]).

### Example 9-2

FIG. 45B shows changes of the moving speed v of a high-speed stage (hereinafter, referred to as a stage 2, if needed). The dotted line in FIG. 45B indicates example 9-2. For example, a high-speed stage manufactured by Aerotech, Inc. is used as the stage 2. The operation of the stage 2 is the same as that of the stage 1. However, the acceleration of the stage 2 is higher than that of the stage 1. The more quickly the moving speed V of the stage increases, the shorter the time to reach an irradiation position of the laser light becomes and the higher the laser machining speed of the transparent conductive layer becomes. For example, if the irradiation area of one shot of the laser light was 2×2 [mm²] and the machining area was 40×40 [mm²], the tact time of the stage 2 was 60 [s] (1 [min]). According to catalog specifications, the stage 2 can perform machining at 300 [mm/s]. The introduction of the high-speed stage 2 enabled machining at speed 15 times that of the stage 1. To increase the laser machining speed of the transparent conductive layer, it was therefore effective to increase the moving speed of the stage to which the transparent conductive substrate was fixed.

### Example 9-3

The introduction of the stage of which the moving speed increases quickly increased the laser machining speed of the transparent conductive layer. However, the method according to the foregoing example 9-2 used a mechanism that temporarily stopped the stage during laser irradiation and still had room for further speedup of the laser machining (see the dotted lines in FIGS. 45A and 45B). More specifically, the stage does not need to be temporarily stopped during laser irradiation unless the number of shots of the laser light in the same position is more than one. As a method for further speedup of the laser machining, “position synchronized output (manufactured by Aerotech, Inc.; hereinafter, referred to as PSO, if needed)” which enables precise laser oscillation control may be introduced. A PSO program can be incorporated into the stage control to enable laser irradiation while the stage is moving.

The solid line in FIG. 45B schematically shows the relationship between the laser machining speed and the moving speed of the stage when the high-speed stage 2 is used and PSO is introduced. The positions (coordinates) to irradiate with the laser light are input in advance, and the input coordinates are irradiated with the laser light while the stage continues moving. This further increased the laser machining speed of the transparent conductive layer. The machining area can be increased to further enhance the effect. Note that even with a stage of insufficient acceleration like the stage 1, PSO can be introduced to perform laser irradiation while the stage is moving, whereby the laser machining speed of the transparent conductive layer can be increased.

The embodiments and examples of the present technique have been concretely described above. The present technique is not limited to the foregoing embodiments and examples, and various modifications may be made on the basis of the technical idea of the present technique.

For example, the configurations, methods, steps, shapes, materials, numerical values, and the like described in the foregoing embodiments and examples are just a few examples. Different configurations, methods, steps, shapes, materials, numerical values, and/or the like may be used if need.

Moreover, the configurations, methods, steps, shapes, materials, numerical values, and the like of the foregoing embodiments and examples may be combined with each other without departing from the gist of the present technique.

The foregoing embodiments and examples have been described by using an example where the present technique is used for laser machining. However, the present technique is not limited to such an example, and may be applied to a process capable of ultrafine machining. The present technique is also applicable to inkjet printing and the like.

The foregoing embodiments have dealt with the cases where the present technique is applied to the manufacture of transparent conductive elements of an information input device. However, the present technique is not limited to such cases, and may be applied to the manufacture of a fine shape pattern of a device substrate of a solar battery, an organic display, etc.

The present technique may also employ the following configurations.

(1) A transparent conductive element including:

a substrate having a surface; and

transparent conductive portions and transparent insulating portions that are alternately formed on the surface in a planar manner,

at least one type of unit section including a random pattern being repeated in at least either the transparent conductive portions or the transparent insulating portions.

(2) The transparent conductive element according to (1), wherein boundary portions between the transparent conductive portions and the transparent insulating portions include part of the random pattern.
(3) The transparent conductive element according to (2), wherein:

the unit section has a side which a pattern element of the random pattern is in contact with or cut by; and

the side is provided at boundaries between the transparent conductive portions and the transparent insulating portions.

(4) The transparent conductive element according to any one of (1) to (3), wherein a unit section including a boundary pattern is repeated in the boundary portions between the transparent conductive portions and the transparent insulating portions.
(5) The transparent conductive element according to any one of (1) to (4), wherein:

the random pattern of the transparent conductive portions is a pattern of a plurality of insulating elements that are provided apart from each other; and

the random pattern of the transparent insulating portions is a pattern of a plurality of conductive elements that are provided apart from each other.

(6) The transparent conductive element according to (5), wherein:

the insulating elements are hole portions; and

the conductive elements are island portions.

(7) The transparent conductive element according to (5), wherein the insulating elements and the conductive elements have a dot shape.
(8) The transparent conductive element according to (5), wherein the insulating elements have a dot shape, and a gap portion between the conductive elements has a mesh-like shape.
(9) The transparent conductive element according to (1) to (8), wherein the transparent conductive portions and the transparent insulating portions include a metal wire.
(10) The transparent conductive element according to (1), wherein:

the transparent conductive portions include a continuously-formed transparent conductive layer; and

at least one type of unit section including a random pattern is repeated in the transparent insulating portions.

(11) An input device including:

a substrate having a first surface and a second surface; and

transparent conductive portions and transparent insulating portions that are alternately provided in a planar manner on the first surface and the second surface,

at least one type of unit section including a random pattern being repeated in at least either the transparent conductive portions or the transparent insulating portions.

(12) An input device including:

a first transparent conductive element; and

a second transparent conductive element that is provided on a surface of the first transparent conductive element,

the first transparent conductive element and the second transparent conductive element including

a substrate having a surface, and

transparent conductive portions and transparent insulating portions that are alternately provided on the surface in a planar manner,

at least one type of unit section including a random pattern being repeated in at least either the transparent conductive portions or the transparent insulating portions.

(13) An electronic apparatus including a transparent conductive element that includes: a substrate having a first surface and a second surface; and transparent conductive portions and transparent insulating portions that are alternately provided in a planar manner on the first surface and the second surface,

at least one type of unit section including a random pattern being repeated in at least either the transparent conductive portions or the transparent insulating portions.

(14) An electronic apparatus including:

a first transparent conductive element; and

a second transparent conductive element that is provided on a surface of the first transparent conductive element,

the first transparent conductive element and the second transparent conductive element including

a substrate having a first surface and a second surface, and

transparent conductive portions and transparent insulating portions that are alternately provided in a planar manner on the first surface and the second surface,

at least one type of unit section including a random pattern being repeated in at least either the transparent conductive portions or the transparent insulating portions.

(15) A method for manufacturing a transparent conductive element, the method including irradiating a transparent conductive layer on a substrate surface with light via at least one type of mask including a random pattern to repeatedly form a unit section, whereby transparent conductive portions and transparent insulating portions are alternately formed on the substrate surface in a planar manner.
(16) The method for manufacturing a transparent conductive element according to (15), wherein the transparent conductive layer on the substrate surface is irradiated with light via at least one type of mask including a boundary pattern to repeatedly form a unit section, whereby boundary portions between the transparent conductive portions and the transparent insulating portions are formed.
(17) The method for manufacturing a transparent conductive element according to (15), wherein the transparent conductive portions and the transparent insulating portions are alternately formed on the substrate surface in a planar manner by switching two types of masks including a random pattern.
(18) The method for manufacturing a transparent conductive element according to (17), wherein the two types of masks including a random pattern are a first mask including a random pattern of a plurality of light-shielding elements and a second mask including a random pattern of a plurality of light transmitting elements.
(19) A method for machining a transparent conductive layer, the method including irradiating a transparent conductive layer on a substrate surface with light via at least one type of mask including a pattern to repeatedly form a unit section, whereby transparent conductive portions and transparent insulating portions are alternately formed on the substrate surface in a planar manner.
(20) A method for machining a workpiece, the method including irradiating a workpiece with light via a mask including a pattern, and moving an irradiation position of the mask with the light, whereby the workpiece is machined.
(21) The method for machining a workpiece according to (20), wherein the mask has an area larger than a machining region of the workpiece.
(22) A transparent conductive element including:

a substrate having a surface; and

transparent conductive portions and transparent insulating portions that are alternately provided on the surface in a planar manner,

the transparent insulating portions including a random pattern, hole portions of the random pattern having an average depth of 1 [μm] or more and 10 [μm] or less, a value obtained by dividing a maximum value of diameters of pattern elements of the random pattern by the average depth being less than or equal to 80.

(23) A transparent conductive element including:

a substrate having a surface; and

transparent conductive portions and transparent insulating portions that are alternately provided on the surface in a planar manner,

the transparent insulating portions including a random pattern, a hole portion of the random pattern having an average depth of 1 [μm] or more and 12 [μm] or less, a value obtained by dividing a maximum value of diameters of pattern elements of the random pattern by the average depth being less than or equal to 19.

(24) The transparent conductive element according to (1), wherein hole portions of the random pattern of the transparent insulating portions have an average depth of 1 [μm] or more and 12 [μm] or less, and a maximum value of diameters of pattern elements of the random pattern is less than or equal to 200 [μm].

### REFERENCE SIGNS LIST

1 First transparent conductive element
2 Second transparent conductive element
3 Optical layer
4 Display device
5, 32 Bonding layer
10 Information input device
11, 21 Substrate
12, 22 Transparent conductive layer
13, 23 Transparent electrode portion
14, 24 Transparent insulating portion
13a Hole portion
13b Transparent conductive portion
14a Island portion
14b Gap portion
13p, 14p, 15p Unit section
L Boundary
R₁ First region
R₂ Second region

1. A transparent conductive element comprising:
a substrate having a surface; and
transparent conductive portions and transparent insulating portions that are alternately formed on the surface in a planar manner,
at least one type of unit section including a random pattern being repeated in at least either the transparent conductive portions or the transparent insulating portions.

2. The transparent conductive element according to claim 1, wherein boundary portions between the transparent conductive portions and the transparent insulating portions include part of the random pattern.

3. The transparent conductive element according to claim 2, wherein:
the unit section has a side which a pattern element of the random pattern is in contact with or cut by; and
the side is provided at boundaries between the transparent conductive portions and the transparent insulating portions.

4. The transparent conductive element according to claim 1, wherein a unit section including a boundary pattern is repeated in the boundary portions between the transparent conductive portions and the transparent insulating portions.

5. The transparent conductive element according to claim 1, wherein:
the random pattern of the transparent conductive portions is a pattern of a plurality of insulating elements that are provided apart from each other; and
the random pattern of the transparent insulating portions is a pattern of a plurality of conductive elements that are provided apart from each other.

6. The transparent conductive element according to claim 5, wherein:
the insulating elements are hole portions; and
the conductive elements are island portions.

7. The transparent conductive element according to claim 5, wherein the insulating elements and the conductive elements have a dot shape.

8. The transparent conductive element according to claim 5, wherein the insulating elements have a dot shape, and a gap portion between the conductive elements has a mesh-like shape.

9. The transparent conductive element according to claim 1, wherein the transparent conductive portions and the transparent insulating portions include a metal wire.

10. The transparent conductive element according to claim 1, wherein:
the transparent conductive portions include a continuously-formed transparent conductive layer; and
at least one type of unit section including a random pattern is repeated in the transparent insulating portions.

11. An input device comprising:
a substrate having a first surface and a second surface; and
transparent conductive portions and transparent insulating portions that are alternately provided in a planar manner on the first surface and the second surface,
at least one type of unit section including a random pattern being repeated in at least either the transparent conductive portions or the transparent insulating portions.

12. An input device comprising:
a first transparent conductive element; and
a second transparent conductive element that is provided on a surface of the first transparent conductive element,
the first transparent conductive element and the second transparent conductive element including
a substrate having a surface, and
transparent conductive portions and transparent insulating portions that are alternately provided on the surface in a planar manner,
at least one type of unit section including a random pattern being repeated in at least either the transparent conductive portions or the transparent insulating portions.

13. An electronic apparatus comprising a transparent conductive element that includes: a substrate having a first surface and a second surface; and transparent conductive portions and transparent insulating portions that are alternately provided in a planar manner on the first surface and the second surface,
at least one type of unit section including a random pattern being repeated in at least either the transparent conductive portions or the transparent insulating portions.

14. An electronic apparatus comprising:
a first transparent conductive element; and
a second transparent conductive element that is provided on a surface of the first transparent conductive element,
the first transparent conductive element and the second transparent conductive element including
a substrate having a first surface and a second surface, and
transparent conductive portions and transparent insulating portions that are alternately provided in a planar manner on the first surface and the second surface,
at least one type of unit section including a random pattern being repeated in at least either the transparent conductive portions or the transparent insulating portions.

15. A method for manufacturing a transparent conductive element, the method comprising irradiating a transparent conductive layer on a substrate surface with light via at least one type of mask including a random pattern to repeatedly form a unit section, whereby transparent conductive portions and transparent insulating portions are alternately formed on the substrate surface in a planar manner.

16. The method for manufacturing a transparent conductive element according to claim 15, wherein the transparent conductive layer on the substrate surface is irradiated with light via at least one type of mask including a boundary pattern to repeatedly form a unit section, whereby boundary portions between the transparent conductive portions and the transparent insulating portions are formed.

17. The method for manufacturing a transparent conductive element according to claim 15, wherein the transparent conductive portions and the transparent insulating portions are alternately formed on the substrate surface in a planar manner by switching two types of masks including a random pattern.

18. The method for manufacturing a transparent conductive element according to claim 17, wherein the two types of masks including a random pattern are a first mask including a random pattern of a plurality of light-shielding elements and a second mask including a random pattern of a plurality of light transmitting elements.

19. A method for machining a transparent conductive layer, the method comprising irradiating a transparent conductive layer on a substrate surface with light via at least one type of mask including a pattern to repeatedly form a unit section, whereby transparent conductive portions and transparent insulating portions are alternately formed on the substrate surface in a planar manner.
